(19) United States
(12) Patent Application Publication
(10) Pub. No.: US 2024/0266687 A1
(43) Pub. Date: Aug. 8, 2024

(54) BATTERY, METHOD FOR MANUFACTURING BATTERY, AND CIRCUIT BOARD

(71) Applicant: Panasonic Intellectual Property Management Co., Ltd., Osaka (JP)

(72) Inventors: KAZUYOSHI HONDA, Osaka (JP); AKIRA KAWASE, Osaka (JP); KAZUHIRO MORIOKA, Osaka (JP); EIICHI KOGA, Hokkaido (JP); KOICHI HIRANO, Osaka (JP)

(21) Appl. No.: 18/638,744

(22) Filed: Apr. 18, 2024

Related U.S. Application Data
(63) Continuation of application No. PCT/JP2022/030061, filed on Aug. 5, 2022.

(30) Foreign Application Priority Data
Nov. 16, 2021 (JP) 2021-186467

(51) Int. Cl. H01M 50/529; H01M 50/509; H01M 50/514; H01M 50/588; H05K 1/18

(52) U.S. Cl. CPC H01M 50/529; H01M 50/509; H01M 50/514; H01M 50/588; H05K 1/18; H05K 2201/10037

(57) ABSTRACT

A battery includes: a power generation element including a plurality of battery cells each having an electrode layer, a counter electrode layer, and a solid electrolyte layer located between the electrode layer and the counter electrode layer, the plurality of battery cells being laminated; a first conductive member; and a second conductive member, in which at least a portion of the plurality of battery cells are electrically connected in parallel, the parallel connection is carried out by an insulating layer and a connecting portion provided on a side surface of the power generation element, at least a portion of the plurality of battery cells are electrically connected in series, the power generation element is provided with at least one through hole that penetrates at least a portion of the plurality of battery cells in a direction of lamination and is open on at least any of a first principal surface and a second principal surface located on an opposite side to the first principal surface of the power generation element, the first conductive member is electrically connected to a first battery cell among the plurality of battery cells, passes through the at least one through hole, and extends to an opening position of the at least one through hole located on a first surface being one of the first principal surface and the second principal surface, the second conductive member is electrically connected to a second battery cell among the plurality of battery cells being different from the first battery cell, passes through the at least one through hole, and extends to an opening position of the at least one through hole located on a second surface being one of the first principal surface and the second principal surface, and the first battery cell and the second battery cell are not connected in parallel.

### BACKGROUND

### 1. Technical Field

The present disclosure relates to a battery, a method for manufacturing a battery, and a circuit board.

### 2. Description of the Related Art

Japanese Unexamined Patent Application Publication No. 2005-235738 discloses a concept of forming through holes in a battery and providing a wiring pattern by using the through holes.

Japanese Unexamined Patent Application Publication No. 2007-207510 discloses a concept of forming through holes in a battery and fastening the battery by using the through holes.

### SUMMARY

The related art faces a demand for improving usability when a battery is used by being connected to a circuit. In a case of mounting a battery on a board, for example, there is a demand for improving usability by increasing more variations to mount the battery and other devices.

Meanwhile, an increase in capacity density of a battery is desirable. In the case of mounting a battery on a board, for example, it is an important point to reduce a mounting area of the battery in order to increase the capacity density. The reduction in mounting area of the battery is equivalent to reduction in projected area of a power generation element of the battery in plan view of the board, and of each terminal or the like for extracting an electric current from the power generation element of the battery, for example.

In the meantime, an electric circuit may come across a case of being used in a combination of batteries at different voltages such as a case of handling two or more power supply voltages. In this context, high-density mounting that can realize supply of different voltages is also an important technical field.

One non-limiting and exemplary embodiment provides a battery, a method for manufacturing a battery, and a circuit board, which can achieve a high capacity density and high usability at the same time.

In one general aspect, the techniques disclosed here feature a battery including: a power generation element including a plurality of battery cells each having an electrode layer, a counter electrode layer, and a solid electrolyte layer located between the electrode layer and the counter electrode layer, the plurality of battery cells being laminated; a first conductive member; and a second conductive member, in which at least a portion of the plurality of battery cells are electrically connected in parallel, the parallel connection is carried out by an insulating layer and a connecting portion provided on a side surface of the power generation element, at least a portion of the plurality of battery cells are electrically connected in series, the power generation element is provided with at least one through hole that penetrates at least a portion of the plurality of battery cells in a direction of lamination and is open on at least any of a first principal surface and a second principal surface located on an opposite side to the first principal surface of the power generation element, the first conductive member is electrically connected to a first battery cell among the plurality of battery cells, passes through the at least one through hole, and extends to an opening position of the at least one through hole located on a first surface being one of the first principal surface and the second principal surface, the second conductive member is electrically connected to a second battery cell among the plurality of battery cells being different from the first battery cell, passes through the at least one through hole, and extends to an opening position of the at least one through hole located on a second surface being one of the first principal surface and the second principal surface, and the first battery cell and the second battery cell are not connected in parallel.

According to the battery and the like of the present disclosure, a high capacity density and high usability can be achieved at the same time.

It should be noted that general or specific embodiments may be implemented as a system, a method, an integrated circuit, a computer program, a storage medium, or any selective combination thereof.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1 is a sectional view of a battery according to Embodiment 1;

FIG. 2 is a top plan view of the battery according to the Embodiment 1;

FIG. 3A is a sectional view of an example of a battery cell included in a power generation element according to the Embodiment 1;

FIG. 3B is a sectional view of another example of the battery cell included in the power generation element according to the Embodiment 1;

FIG. 3C is a sectional view of still another example of the battery cell included in the power generation element according to the Embodiment 1;

FIG. 4 is a sectional view of the power generation element according to the Embodiment 1;

FIG. 5 is a sectional view illustrating a usage example of the battery according to the Embodiment 1;

FIG. 6 is a sectional view of a battery according to Embodiment 2;

FIG. 7 is a sectional view of a battery according to Embodiment 3;

FIG. 8 is a sectional view of a battery according to Embodiment 4;

FIG. 9 is a sectional view of a battery according to another example of the Embodiment 4;

FIG. 10 is a sectional view of a battery according to Embodiment 5;

FIG. 11 is a top plan view of the battery according to the Embodiment 5;

FIG. 12 is a sectional view of a battery according to another example of the Embodiment 5;

FIG. 13 is a sectional view of a battery according to Embodiment 6;

FIG. 14 is a sectional view of a battery according to Embodiment 7;

FIG. 15 is a sectional view of a battery according to another example of the Embodiment 7;

FIG. 16 is a sectional view of a battery according to still another example of the Embodiment 7;

FIG. 17 is a sectional view of a battery according to Embodiment 8;

FIG. 18 is a sectional view of a battery according to Embodiment 9;

FIG. 19 is a sectional view of a battery according to Embodiment 10;

FIG. 20 is a top plan view of the battery according to the Embodiment 10;

FIG. 21 is a sectional view of a circuit board according to Embodiment 11;

FIG. 22 is a flowchart illustrating a first example of a method for manufacturing a battery according to an embodiment;

FIG. 23 is a flowchart illustrating a second example of the method for manufacturing a battery according to the embodiment;

FIG. 24 is a flowchart illustrating a third example of the method for manufacturing a battery according to the embodiment; and

FIG. 25 is a flowchart illustrating a fourth example of the method for manufacturing a battery according to the embodiment.

### DETAILED DESCRIPTIONS

### Summary of Present Disclosure

A battery according to an aspect of the present disclosure includes: a power generation element including a plurality of battery cells each having an electrode layer, a counter electrode layer, and a solid electrolyte layer located between the electrode layer and the counter electrode layer, the plurality of battery cells being laminated; a first conductive member; and a second conductive member, in which at least a portion of the plurality of battery cells are electrically connected in parallel, the parallel connection is carried out by an insulating layer and a connecting portion provided on a side surface of the power generation element, at least a portion of the plurality of battery cells are electrically connected in series, the power generation element is provided with at least one through hole that penetrates at least a portion of the plurality of battery cells in a direction of lamination and is open on at least any of a first principal surface and a second principal surface located on an opposite side to the first principal surface of the power generation element, the first conductive member is electrically connected to a first battery cell among the plurality of battery cells, passes through the at least one through hole, and extends to an opening position of the at least one through hole located on a first surface being one of the first principal surface and the second principal surface, the second conductive member is electrically connected to a second battery cell among the plurality of battery cells being different from the first battery cell, passes through the at least one through hole, and extends to an opening position of the at least one through hole located on a second surface being one of the first principal surface and the second principal surface, and the first battery cell and the second battery cell are not connected in parallel.

Thus, it is possible to realize a battery that achieves both a high capacity density and high reliability.

Meanwhile, according to this configuration, a portion of the battery cells are connected in parallel. Thus, it is possible to realize the high-capacity and high-voltage battery.

Specifically, voltages corresponding to two combinations of connection of the battery cells in the power generation element can be supplied by using the first conductive member connected to the first battery cell and the second conductive member connected to the second battery cell. Accordingly, two or more types of voltages can be supplied to an electronic device and the like by using one battery, so that usability of the battery can be enhanced.

In the meantime, the first conductive member and the second conductive member used for supplying the voltages corresponding to the two combinations of connection of the battery cells pass through the at least one through hole, namely, through the power generation element. Therefore, it is not necessary to form a structure required for supplying the two types of voltages on the outside of a side surface of the power generation element. Accordingly, the battery can be downsized so that the capacity density of the battery can be increased.

For example, the at least one through hole may include: a first through hole that the first conductive member passes through, the first through hole being open on the first surface; and a second through hole that the second conductive member passes through, the second through hole being open on the second surface.

As such, the first conductive member and the second conductive member pass through the through holes that are different from each other. Accordingly, it is possible to increase freedom of a layout of the first conductive member and the second conductive member.

For example, the battery may further include: a first insulating member located between the first conductive member and an inner wall of the first through hole; and a second insulating member located between the second conductive member and an inner wall of the second through hole.

As such, insulation between the conductive member and the power generation element is secured inside the through hole, so that reliability of the battery can be improved.

For example, the at least one through hole may be a single through hole that the first conductive member and the second conductive member pass through.

As such, the first conductive member and the second conductive member pass through the same through hole. Thus, it is possible to consolidate positions to extract electric currents from the first battery cell and the second battery cell.

For example, the battery may further include: an insulating member disposed between the first conductive member and an inner wall of the single through hole, between the second conductive member and the inner wall of the single through hole, and between the first conductive member and the second conductive member.

As such, insulation of the first conductive member and the second conductive member from the power generation element as well as insulation between the first conductive member and the second conductive member is secured inside the through hole, so that reliability of the battery can be improved.

For example, one of a voltage at the first conductive member based on the first surface and a voltage at the second conductive member based on the second surface may be a positive voltage, and another one of the voltages may be a negative voltage.

As such, one battery can supply the voltages having different polarities based on the principal surface of the power generation element.

For example, a portion of the battery cells including the first battery cell among the plurality of battery cells may constitute a first cell laminated body in the power generation element, a portion of the battery cells including the second battery cell among the plurality of battery cells may constitute a second cell laminated body laminated on the first cell laminated body in the power generation element, and the power generation element may further include an insulating layer located between the first cell laminated body and the second cell laminated body.

As mentioned above, in the power generation element, the first cell laminated body is insulated from the second cell laminated body while interposing the insulating layer therebetween. Moreover, the first conductive member is connected to the first battery cell included in the first cell laminated body while the second conductive member is connected to the second battery cell included in the second cell laminated body. For this reason, the magnitudes and the polarities of the voltages to be supplied by using the first conductive member and the second conductive member can easily be adjusted by changing the numbers of the battery cells included in the first cell laminated body and the second cell laminated body and by changing an orientation of lamination.

For example, the battery may further include: a third conductive member that electrically connects the first principal surface to the second principal surface, in which the first principal surface may constitutes a portion of the first cell laminated body, and the second principal surface may constitutes a portion of the second cell laminated body.

As such, the principal surfaces on both sides of the power generation element serving as a principal surface of the first cell laminated body and as a principal surface of the second cell laminated body, respectively, are electrically connected to each other. For this reason, each of the first conductive member and the second conductive member causes a potential difference from any of the first principal surface and the second principal surface attributed to the battery cells included in the power generation element. Thus, it is possible to improve freedom of positions to supply the voltages.

For example, a battery cell among the plurality of battery cells which is connected between the first surface and the first battery cell may not overlap a battery cell among the plurality of battery cells which is connected between the second surface and the second battery cell.

As such, it is more likely that the electric power of the respective battery cells in the battery is evenly consumed.

For example, the first surface may be the first principal surface, the second principal surface may constitute a portion of the first battery cell, and the first conductive member may be electrically connected to the second principal surface and may penetrate the power generation element while passing through the at least one through hole.

As such, it is possible to supply the voltage from the entire power generation element on the first principal surface side by using the first conductive member.

For example, a quantity of the battery cells among the plurality of battery cells involved in serial connection between the first surface and the first battery cell may be different from a quantity of the battery cells among the plurality of battery cells involved in serial connection between the second surface and the second battery cell.

As such, one battery can supply two types of voltages having different magnitudes.

For example, the first surface and the second surface may be the first principal surface.

As such, voltages can be supplied from the same principal surface side by using the first conductive member and the second conductive member. Accordingly, mountability of the battery onto a board is improved.

A method for manufacturing a battery according to another aspect includes: forming a laminated body by laminating a plurality of battery cells in such a way that at least a portion of the plurality of battery cells are connected in series; forming at least one through hole in the laminated body by in such a way as to penetrate at least a portion among the plurality of battery cells in a direction of lamination and to be open on at least any of a first principal surface and a second principal surface located on an opposite side to the first principal surface of the laminated body; forming a first conductive member inside the at least one through hole in such a way as to be electrically connected to a first battery cell among the plurality of battery cells, to pass through the at least one through hole, and to extend to an opening position of the at least one through hole located on any of the first principal surface and the second principal surface; and forming a second conductive member inside the at least one through hole in such a way as to be electrically connected to a second battery cell among the plurality of battery cells being different from the first battery cell, to pass through the at least one through hole, and to extend to the opening position of the at least one through hole located on any of the first principal surface and the second principal surface; in which at least a portion of the plurality of battery cells are electrically connected in parallel, the parallel connection is carried out by an insulating layer and a connecting portion provided on a side surface of the laminated body, and the first battery cell and the second battery cell are not connected in parallel.

In this way, it is possible to manufacture the battery that achieves a high capacity density and high usability as mentioned above.

For example, the method for manufacturing a battery may further include: forming an insulating member to be disposed between the first conductive member and an inner wall of the at least one through hole as well as between the second conductive member and the inner wall of the at least one through hole.

In this way, it is possible to form the highly reliable battery by providing the insulating member.

For example, the forming at least one through hole may be carried out after the forming a laminated body.

In this way, the laminated battery cells are provided with the at least one through hole in a lump. Thus, productivity of the battery is improved.

For example, the forming at least one through hole may include forming a through hole corresponding to the at least one through hole in at least a portion of the plurality of battery cells yet to be laminated before the forming a laminated body, and the method for manufacturing a battery may carry out the forming an insulating member, the forming a first conductive member, and the forming a second conductive member after the forming a laminated body.

In this way, it is possible to provide each battery cell with the through hole corresponding to the at least one through hole to be formed in the laminated body.

Accordingly, freedom of a shape of the at least one through hole to be formed in the laminated body is increased. Meanwhile, the laminated body formed by laminating the battery cells can be provided with the conductive member and the insulating member in a lump. Thus, productivity of the battery is improved.

For example, the forming at least one through hole may include forming a through hole corresponding to the at least one through hole in at least a portion of the plurality of battery cells yet to be laminated before the forming a laminated body, and the method for manufacturing a battery may carry out the forming an insulating member, the forming a first conductive member, and the forming a second conductive member before the forming a laminated body.

In this way, the insulating member and the conductive member can be formed before laminating the battery cells. Accordingly, it is easy to carry out an operation such as insertion of materials into the through hole, so that the insulating member and the conductive member can be formed easily and accurately.

For example, the forming at least one through hole may include forming a through hole corresponding to the at least one through hole in at least a portion of the plurality of battery cells yet to be laminated before the forming a laminated body, and the method for manufacturing a battery may carry out the forming an insulating member before the forming a laminated body, and may carry out the forming a first conductive member and the forming a second conductive member after the forming a laminated body.

In this way, it is possible to form the insulating member easily and accurately, which is required to be formed accurately in order to improve reliability of the battery. Meanwhile, the laminated body formed by laminating the battery cells can be provided with the conductive member in a lump. Thus, productivity of the battery is improved.

A circuit board according to still another aspect of the present disclosure includes: a power generation element including a plurality of battery cells each having an electrode layer, a counter electrode layer, and a solid electrolyte layer located between the electrode layer and the counter electrode layer, the plurality of battery cells being laminated; a first conductive member; a second conductive member; and a circuit pattern layer being laminated on the power generation element and including circuit wiring, in which at least a portion of the plurality of battery cells are electrically connected in series, the power generation element is provided with at least one through hole that penetrates at least a portion of the plurality of battery cells in a direction of lamination and is open on a first principal surface of the power generation element, the first conductive member is electrically connected inside the at least one through hole to a first battery cell among the plurality of battery cells, passes through the at least one through hole, extends to an opening position of the at least one through hole located on the first principal surface, and is electrically connected to a portion of the circuit wiring, the second conductive member is electrically connected inside the at least one through hole to a second battery cell among the plurality of battery cells being different from the first battery cell, passes through the at least one through hole, extends to the opening position of the at least one through hole located on the first principal surface, and is electrically connected to another portion of the circuit wiring, and the circuit pattern layer is located on the first principal surface side of the power generation element.

In this way, the circuit board including the battery that achieves the high capacity density and high usability as mentioned above, and the circuit pattern layer connected to the battery is realized. Meanwhile, since a wiring board and the battery are integrated together, it is possible to achieve downsizing and thin profiling of electronic equipment. In the meantime, electric power can be directly supplied from the power generation element to a required location on the circuit wiring. Thus, it is possible to reduce extension of wiring and to suppress radiation noise from the wiring.

For example, at least a portion of the plurality of battery cells may be electrically connected in parallel, the parallel connection may be carried out by an insulating layer and a connecting portion provided on a side surface of the power generation element, and the first battery cell and the second battery cell may be not connected in parallel.

In this way, the portion of the battery cells are connected in parallel. Thus, it is possible to realize the circuit board including the battery with a large capacity and a high voltage, and the circuit pattern layer connected to the battery.

Embodiments will be specifically described below with reference to the drawings.

Note that each embodiment described below represents a comprehensive or specific example. Numerical values, shapes, materials, constituents, layout positions and modes of connection of the constituents, steps, the order of the steps, and the like depicted in the following embodiments are examples and are not intended to restrict the present disclosure. Meanwhile, of the constituents in the following embodiments, a constituent not defined in an independent claim will be described as an optional constituent.

In the meantime, the respective drawings are schematic diagrams and are not always illustrated precisely. Accordingly, scales and other factors do not always coincide with one another in the respective drawings, for example. Moreover, in the respective drawings, the structures which are substantially the same are denoted by the same reference signs and overlapping explanations thereof may be omitted or simplified.

Meanwhile, in the present specification, terms that represent relations between elements such as parallelism and orthogonality, terms that represent shapes of the elements such as a rectangle and a rectangular parallelepiped, and numerical ranges are not expressions that only represent precise meanings but are rather expressions that encompass substantially equivalent ranges with allowances of several percent, for example.

In the meantime, in the present specification and the drawings, x axis, y axis, and z axis represent three axes of a three-dimensional orthogonal coordinate system. In a case where a shape in plan view of a power generation element of a battery is a rectangle, the x axis and the y axis coincide with directions parallel to a first side of the rectangle and to a second side being orthogonal to the first side, respectively. The z axis coincides with a direction of lamination of battery cells included in the power generation element and of respective layers of each battery cell.

Meanwhile, in the present specification, a “direction of lamination” coincides with a direction of a normal line to principal surfaces of current collectors and active material layers. Moreover, in the present specification, a “plan view” means a view in a direction perpendicular to a principal surface of the power generation element unless otherwise specifically stated such as a case where the term is used alone. Here, in a case of description of a “plan view of a certain surface” such as a “plan view of a first side surface”, the term means a view from the front of the “certain surface”.

In the meantime, in the present specification, terms “above” and “below” do not represent an upward direction (vertically upward) and a downward direction (vertically downward) in light of absolute spatial recognition, but are used as terms to be defined depending on a relative positional relationship based on the order of lamination in a laminated structure. Moreover, the terms “above” and “below” are used not only in a case where two constituents are disposed with an interval therebetween and another constituent is present between these two constituents, but also in a case where two constituents are disposed close to each other and the two constituents are in contact with each other. In the following description, a negative side of the z axis will be referred to as “below” or a “lower side” while a positive side of the z axis will be referred to as “above” or an “upper side”.

Meanwhile, in the present specification, an expression “to cover A” means to cover at least a portion of “A”. Specifically, the expression “to cover A” is the expression encompassing not only a case of “covering all of A” but also a case of “covering only a portion of A”. Here, “A” is a side surface, a principal surface, and the like of a layer or a certain member such as a terminal.

In the meantime, in the present specification, ordinal numbers such as “first” and “second” are not intended to represent the number or the order of the constituents but are used for the purpose of distinguishing the constituents while avoiding confusion of the constituents of the same type unless otherwise specifically stated.

### Embodiment 1

A configuration of a battery according to Embodiment 1 will be described below.

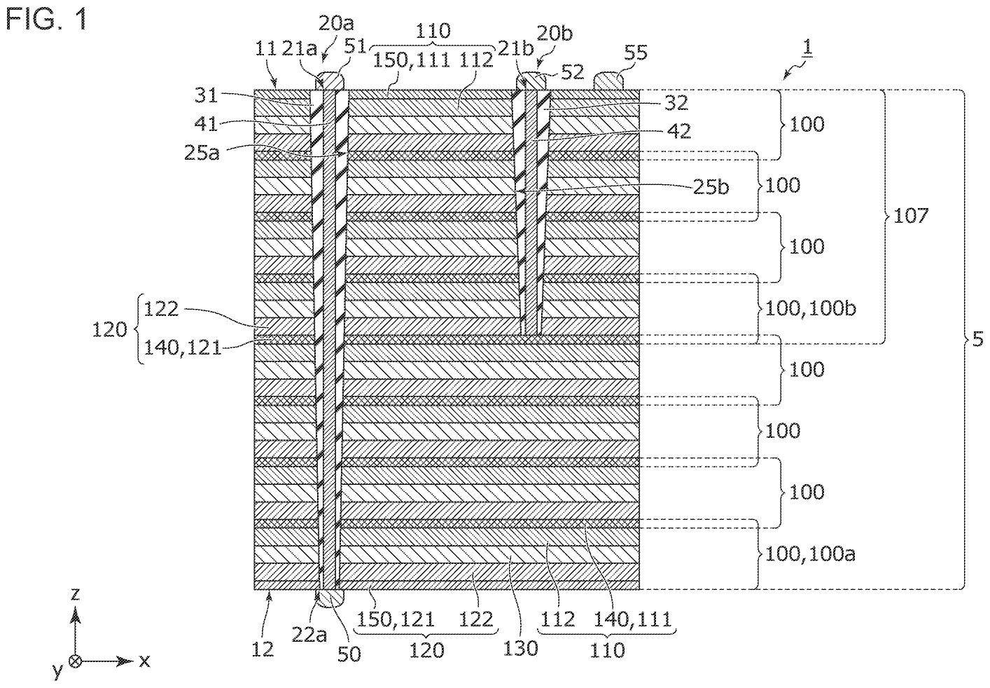

FIG. 1 is a sectional view of a battery 1 according to the present embodiment. As illustrated in FIG. 1, the battery 1 includes a power generation element 5, an insulating member 31, an insulating member 32, a conductive member 41, a conductive member 42, a connecting member 50, a current collecting terminal 51, a current collecting terminal 52, and a current collecting terminal 55. The battery 1 is an all-solid-state battery, for example.

### 1. Power Generation Element

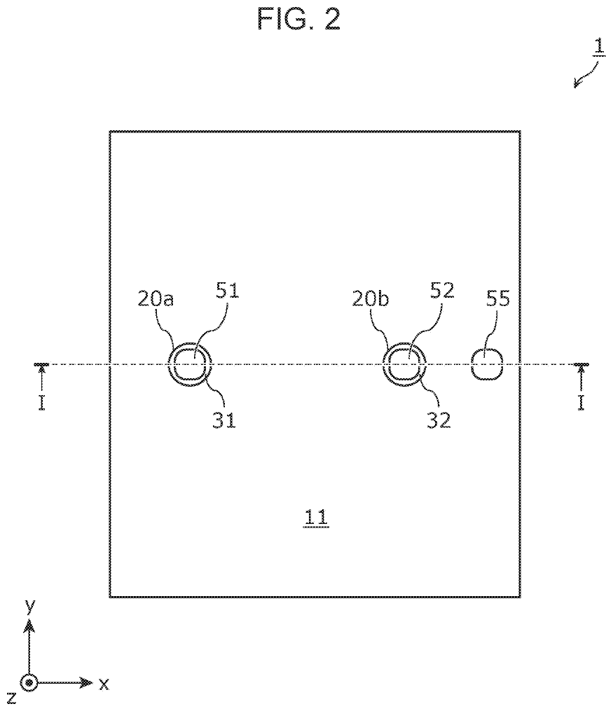

First, a specific configuration of the power generation element 5 will be described with reference to FIGS. 1 and 2. FIG. 2 is a top plan view of the battery 1 according to the present embodiment. Here, FIG. 1 illustrates a section taken along the I-I line in FIG. 2.

As illustrated in FIG. 2, a shape in plan view of the power generation element 5 is a rectangle, for example. In other words, the shape of the power generation element 5 is a flat rectangular parallelepiped. Here, flatness means that a thickness (namely, a length in z-axis direction) is shorter than respective sides (namely, respective lengths in x-axis direction and y-axis direction) or a maximum width of a principal surface. The shape in plan view of the power generation element 5 may be any of other polygons including a square, a hexagon, and an octagon, or may be any of a circle, an ellipse, and the like. It is to be noted that a thickness of each of layers is illustrated in an exaggerated manner in the sectional views such as FIG. 1 in order to clarify a layered structure of the power generation element 5.

As illustrated in FIGS. 1 and 2, the power generation element 5 includes a principal surface 11 and a principal surface 12 as two principal surfaces thereof. In the present embodiment, each of the principal surface 11 and the principal surface 12 is a flat surface.

The principal surface 11 is an example of a first principal surface. The principal surface 12 is an example of a second principal surface. The principal surface 11 and the principal surface 12 are back to back to each other and are parallel to each other. The principal surface 11 is the uppermost surface of the power generation element 5. The principal surface 12 is a surface on an opposite side to the principal surface 11 and is the lowermost surface of the power generation element 5. Each of the principal surface 11 and the principal surface 12 has a larger area than that of a side surface of the power generation element 5, for example.

Side surfaces of the power generation element 5 include two sets of two side surfaces being back to back to each other and parallel to each other. Each side surface of the power generation element 5 is a flat surface, for example. Each side surface of the power generation element 5 is a cut surface formed by cutting a laminated body of battery cells 100 in a lump, for example. The battery cells 100 having the same size can be formed by aligning a cutting direction with a direction of lamination.

As illustrated in FIG. 1, the power generation element 5 includes the battery cells 100. Each battery cell 100 is a battery of a minimum structure and is also referred to as a unit cell. The battery cells 100 are laminated while being electrically connected in series. Thus, it is possible to realize the high-voltage battery 1 without increasing the area in plan view. In the present embodiment, all of the battery cells 100 included in the power generation element 5 are electrically connected in series. The battery 1 is a laminated battery formed by integrating the battery cells 100 by means of adhesion, bonding, or the like. Although the number of the battery cells 100 included in the power generation element 5 is eight cells in the example illustrated in FIG. 1, the number of the battery cells is not limited to the foregoing. For example, the number of the battery cells 100 included in the power generation element 5 may be even cells such as two cells and four cells, or odd cells such as three cells and five cells.

The power generation element 5 is provided with at least one through hole that penetrates at least a portion of the battery cells 100 in the direction of lamination. In the present embodiment, the power generation element 5 is provided with two through holes, namely, a through hole 20a and a through hole 20b. The through hole 20a is an example of a first through hole and the through hole 20b is an example of a second through hole.

Each of the battery cells 100 includes an electrode layer 110, a counter electrode layer 120, and a solid electrolyte layer 130. The electrode layer 110 includes an electrode current collector 111 and an electrode active material layer 112. The counter electrode layer 120 includes a counter electrode current collector 121 and a counter electrode active material layer 122. In each of the battery cells 100, the electrode current collector 111, the electrode active material layer 112, the solid electrolyte layer 130, the counter electrode active material layer 122, and the counter electrode current collector 121 are laminated in this order along the z axis. In each battery cell 100, the electrode current collector 111, the electrode active material layer 112, the solid electrolyte layer 130, the counter electrode active material layer 122, and the counter electrode current collector 121 extend in a direction perpendicular to the z-axis direction (namely, in the x-axis direction and the y-axis direction), respectively.

Configurations of the respective battery cells 100 are substantially the same as one another, for example. In the power generation element 5, the battery cells 100 are laminated in an arrangement along the z axis such that the orders of arrangement of the respective layers constituting the battery cells 100 are the same. Accordingly, the battery cells 100 are laminated while being electrically connected in series. The battery cells 100 have the same size as one another, for example. This makes it easier to conform states of operation among the battery cells 100 so that the battery 1 achieving both a high capacity density and high reliability can be realized.

In the present embodiment, the principal surface 11 constitutes a portion of the electrode layer 110 of the battery cell 100 located uppermost. To be more precise, the principal surface 11 is a principal surface on the upper side of the electrode layer 110 of the battery cell 100 located uppermost.

Meanwhile, the principal surface 12 constitutes a portion of the counter electrode layer 120 of the battery cell 100 located lowermost. To be more precise, the principal surface 12 is a principal surface on the lower side of the counter electrode layer 120 of the battery cell 100 located lowermost.

Here, the electrode layer 110 is one of a positive electrode layer and a negative electrode layer of the battery cell 100. The counter electrode layer 120 is the other one of the positive electrode layer and the negative electrode layer of the battery cell 100. In the following, a description will be given of a case where the electrode layer 110 is the positive electrode layer and the counter electrode layer 120 is the negative electrode layer as an example.

In the present embodiment, a current collector is shared by two battery cells 100 located adjacent to each other in the direction of lamination among the multiple battery cells 100. Specifically, the electrode current collector 111 of one of the two battery cells 100 and the counter electrode current collector 121 of the other one of the two battery cells 100 form one intermediate layer current collector 140.

To be more precise, the electrode active material layer 112 is laminated on a lower surface of the intermediate layer current collector 140. The counter electrode active material layer 122 is laminated on an upper surface of the intermediate layer current collector 140. The intermediate layer current collector 140 is also referred to as a bipolar current collector.

End portion layer current collectors 150 illustrated in FIG. 1 are located on both ends in the direction of lamination of the power generation element 5. The end portion layer current collector 150 located on an upper end being one end in the direction of lamination is the electrode current collector 111. The electrode active material layer 112 is disposed at a lower surface of the electrode current collector 111. The end portion layer current collector 150 located on a lower end being another end in the direction of lamination is the counter electrode current collector 121. The counter electrode active material layer 122 is disposed at an upper surface of the counter electrode current collector 121.

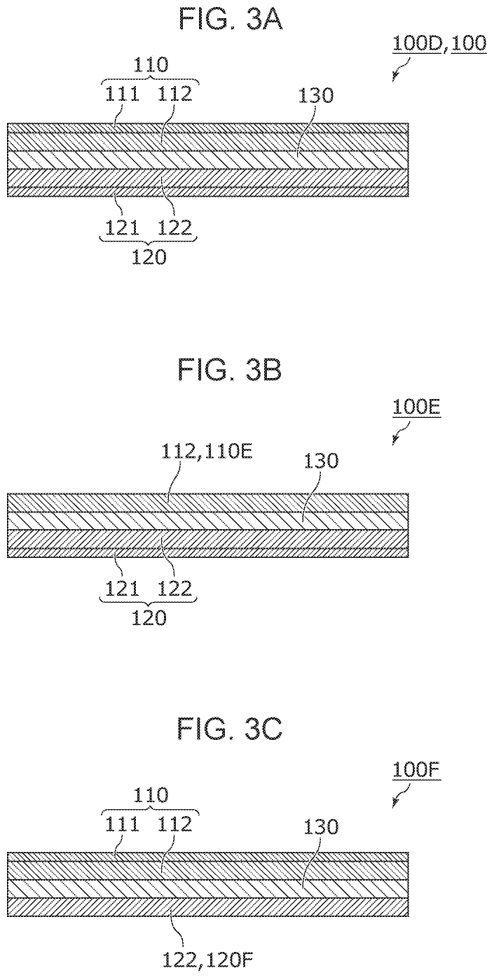

A description will be given below of the respective layers of the battery cell 100 with reference to FIG. 3A. FIG. 3A is a sectional view of the battery cell 100 included in the power generation element 5 according to the present embodiment.

Each of the electrode current collector 111 and the counter electrode current collector 121 illustrated in FIG. 3A is either the intermediate layer current collector 140 or the end portion layer current collector 150 illustrated in FIG. 1. Each of the electrode current collector 111 and the counter electrode current collector 121 is a conductive member in any of a foil form, a plate form, and a mesh form. Each of the electrode current collector 111 and the counter electrode current collector 121 may be a conductive thin film, for example. Examples of a material usable for constituting the electrode current collector 111 and the counter electrode current collector 121 include metals such as stainless steel (SUS), aluminum (Al), copper (Cu), and nickel (Ni). The electrode current collector 111 and the counter electrode current collector 121 may be formed by using different materials from each other.

A thickness of each of the electrode current collector 111 and the counter electrode current collector 121 is greater than or equal to 5 μm and less than or equal to 100 μm, for example. However, the thickness is not limited to this range. The electrode active material layer 112 is in contact with the principal surface of the electrode current collector 111. Here, the electrode current collector 111 may include a current collector layer which is a layer being provided at a portion in contact with the electrode active material layer 112 and containing a conductive material. The counter electrode active material layer 122 is in contact with the principal surface of the counter electrode current collector 121. Here, the counter electrode current collector 121 may include a current collector layer which is a layer being provided at a portion in contact with the counter electrode active material layer 122 and containing a conductive material.

In the meantime, the intermediate layer current collector 140 and the end portion layer current collector 150 may employ current collectors having the same thickness and being made of the same material or employ current collectors having different thicknesses and being made of different materials from each other depending on strengths, bonding performances, properties of the active material layers in contact therewith, and so forth.

The electrode active material layer 112 is disposed at the principal surface on the counter electrode layer 120 side of the electrode current collector 111. The electrode active material layer 112 is a layer including a positive electrode material such as an active material. The electrode active material layer 112 contains a positive electrode active material, for example.

A positive electrode active material such as lithium cobaltate composite oxide (LCO), lithium nickelate composite oxide (LNO), lithium manganate composite oxide (LMO), lithium-manganese-nickel composite oxide (LMNO), lithium-manganese-cobalt composite oxide (LMCO), lithium-nickel-cobalt composite oxide (LNCO), and lithium-nickel-manganese-cobalt composite oxide (LNMCO) can be used as the positive electrode active material contained in the electrode active material layer 112, for example. Various materials that can extract and insert ions such as Li and Mg can be used as the material of the positive electrode active material.

Meanwhile, a solid electrolyte such as an inorganic solid electrolyte may be used as a material contained in the electrode active material layer 112, for example. A sulfide solid electrolyte, an oxide solid electrode, and the like can be used as the inorganic solid electrolyte. A mixture of Li₂S and P₂S₅ can be used as the sulfide solid electrolyte, for example. A surface of the positive electrode active material may be coated with a solid electrolyte. In the meantime, a conducting agent such as acetylene black or a binder such as polyvinylidene fluoride may be used as the material contained in the electrode active material layer 112.

The electrode active material layer 112 is fabricated by applying a coating material in the form of a paste, which is prepared by kneading the materials contained in the electrode active material layer 112 together with a solvent, onto the principal surface of the electrode current collector 111 and drying the coating material. In order to increase a density of the electrode active material layer 112, the electrode layer 110 including the electrode active material layer 112 and the electrode current collector 111 (also referred to as an electrode plate) may be pressed after a drying process. A thickness of the electrode active material layer 112 is greater than or equal to 5 μm and less than or equal to 300 μm, for example. However, the thickness is not limited to this range.

The counter electrode active material layer 122 is disposed on the principal surface on the electrode layer 110 side of the counter electrode current collector 121. The counter electrode active material layer 122 is disposed opposite to the electrode active material layer 112. The counter electrode active material layer 122 is a layer including a negative electrode material such as an active material. The negative electrode material is a material constituting a counter electrode to the positive electrode material. The counter electrode active material layer 122 contains a negative electrode active material, for example.

A negative electrode active material such as graphite and metallic lithium can be used as the negative electrode active material to be contained in the counter electrode active material layer 122, for example. Various materials that can extract and insert ions as typified by lithium (Li) and magnesium (Mg) can be used as the material of the negative electrode active material.

Meanwhile, a solid electrolyte such as an inorganic solid electrolyte may be used as a material contained in the counter electrode active material layer 122, for example. A sulfide solid electrolyte, an oxide solid electrode, and the like can be used as the inorganic solid electrolyte, for example. A mixture of lithium sulfide (Li₂S) and phosphorus pentasulfide (P₂S₅) can be used as the sulfide solid electrolyte, for example. In the meantime, a conducting agent such as acetylene black or a binder such as polyvinylidene fluoride may be used as the material contained in the counter electrode active material layer 122.

The counter electrode active material layer 122 is fabricated by applying a coating material in the form of a paste, which is prepared by kneading the materials contained in the counter electrode active material layer 122 together with a solvent, onto the principal surface of the counter electrode current collector 121 and drying the coating material. In order to increase a density of the counter electrode active material layer 122, the counter electrode layer 120 including the counter electrode active material layer 122 and the counter electrode current collector 121 (also referred to as a counter electrode plate) may be pressed after a drying process. A thickness of the counter electrode active material layer 122 is greater than or equal to 5 μm and less than or equal to 300 μm, for example. However, the thickness is not limited to this range.

The solid electrolyte layer 130 is disposed between the electrode active material layer 112 and the counter electrode active material layer 122. The solid electrolyte layer 130 is in contact with the electrode active material layer 112 and with the counter electrode active material layer 122, respectively. The solid electrolyte layer 130 is a layer including an electrolyte material. Publicly known electrolytes designed for batteries can be used as such an electrolyte material. A thickness of the solid electrolyte layer 130 may be greater than or equal to 5 μm and less than or equal to 300 μm, or may be greater than or equal to 5 μm and less than or equal to 100 μm.

The solid electrolyte layer 130 contains a solid electrolyte. The solid electrolyte has lithium-ion conductivity, for example. A solid electrolyte such as an inorganic solid electrolyte can be used as the solid electrode, for example. A sulfide solid electrolyte, an oxide solid electrode, and the like can be used as the inorganic solid electrolyte. A mixture of Li₂S and P₂S₅ can be used as the sulfide solid electrolyte, for example. Here, the solid electrolyte layer 130 may contain a binder such as polyvinylidene fluoride in addition to the electrolyte material.

In the present embodiment, the electrode active material layer 112, the counter electrode active material layer 122, and the solid electrolyte layer 130 are maintained in a state of parallel flat plates. In this way, it is possible to suppress the occurrence of cracks or collapse due to flexure. Here, the electrode active material layer 112, the counter electrode active material layer 122, and the solid electrolyte layer 130 may be integrated and gently curved together.

Meanwhile, in the present embodiment, an end surface of the electrode current collector 111 and an end surface of the counter electrode current collector 121 coincide with each other when viewed in the z-axis direction.

To be more precise, in the battery cell 100, respective shapes and sizes of the electrode current collector 111, the electrode active material layer 112, the solid electrolyte layer 130, the counter electrode active material layer 122, and the counter electrode current collector 121 are the same and contours of the respective layers coincide with one another. In other words, the shape of the battery cell 100 is a flat plate shape in the form of a flat rectangular parallelepiped.

As described above, in the power generation element 5 according to the present embodiment, each intermediate layer current collector 140 is shared by the battery cells 100 as illustrated in FIG. 1. The above-mentioned power generation element 5 is formed by laminating not only the battery cells 100 illustrated in FIG. 3A but also battery cells 100E and 100F illustrated in FIGS. 3B and 3C in combination. Note that the battery cell 100 illustrated in FIG. 3A will be explained herein as a battery cell 100D.

The battery cell 100E illustrated in FIG. 3B has a configuration to exclude the electrode current collector 111 from the battery cell 100D illustrated in FIG. 3A. That is to say, an electrode layer 110E of the battery cell 100E consists of the electrode active material layer 112.

The battery cell 100F illustrated in FIG. 3C has a configuration to exclude the counter electrode current collector 121 from the battery cell 100D illustrated in FIG. 3A. That is to say, a counter electrode layer 120F of the battery cell 100F consists of the counter electrode active material layer 122.

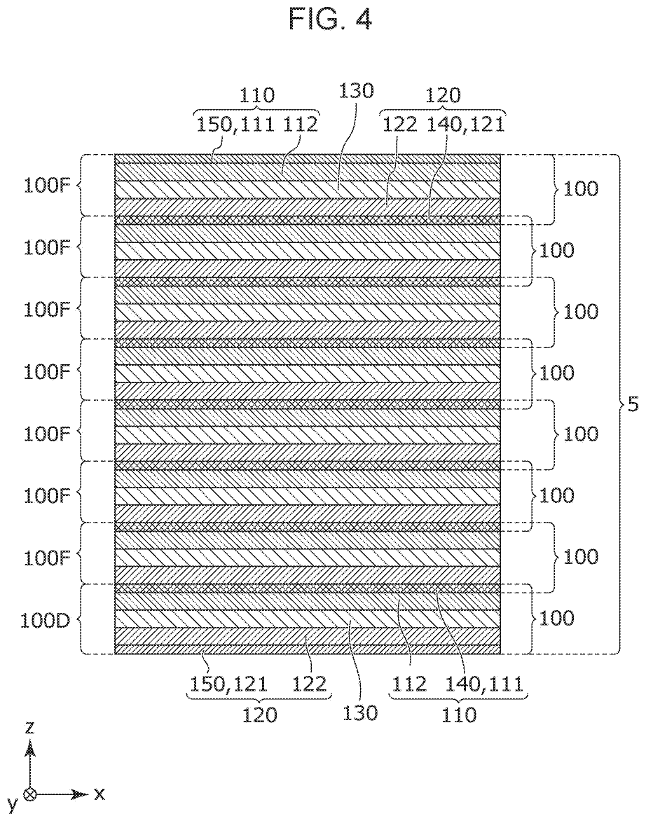

FIG. 4 is a sectional view illustrating the power generation element 5 according to the present embodiment. FIG. 4 is a view extracting only the power generation element 5 in FIG. 1 and illustrating a state before formation of the through hole 20a and the through hole 20b in the power generation element 5. As illustrated in FIG. 4, the battery cell 100D is disposed at the lowermost layer and the battery cells 100F in the same orientation are sequentially laminated upward. The power generation element 5 is formed in this way.

Note that the method of forming the power generation element 5 is not limited to this method. For example, the battery cells 100E in the same orientation may be sequentially laminated and then the battery cell 100D may be disposed at the uppermost layer. On the other hand, the battery cell 100D may be disposed at a position different from both the uppermost layer and the lowermost layer, for example. In the meantime, the battery cells 100D may be used instead. Otherwise, a unit of two battery cells 100 sharing a current collector may be formed by subjecting a single current collector to double-sided coating, and the units thus formed may be laminated.

As described above, in the power generation element 5 according to the present embodiment, all of the battery cells 100 are connected in series and no batteries connected in parallel are included therein. Thus, the high-voltage battery 1 can be realized.

### 2. Through Holes

Next, the through hole 20a and the through hole 20b will be described with reference to FIGS. 1 and 2 again.

The through hole 20a and the through hole 20b penetrate at least one battery cell 100 among the battery cells 100 in the direction of lamination. The through hole 20a and the through hole 20b are not connected to each other and are independent of each other. In the example illustrated in FIG. 1, the through hole 20a penetrates all of the battery cells 100 included in the power generation element 5. Meanwhile, the through hole 20b penetrates a portion of the battery cells 100 included in the power generation element 5.

The through hole 20a is open on the principal surface 11 and the principal surface 12. To be more precise, the through hole 20a is open at an opening position 21a located on the principal surface 11 and at an opening position 22a located on the principal surface 12.

The through hole 20a extends from the battery cell 100a located lowermost among the battery cells 100 to the principal surface 11. To be more precise, the through hole 20a penetrates from the principal surface 12 being the principal surface on the lower side of the battery cell 100a to the principal surface 11. Since the battery cell 100a is located lowermost in the present embodiment, the principal surface 12 constitutes a portion of the battery cell 100a. To be more precise, the principal surface 12 is the principal surface on the lower side of the battery cell 100a. The battery cell 100a is an example of a first battery cell. Note that the through hole 20a does not always have to be open on the principal surface 12, and may penetrate from a portion of the counter electrode layer 120 of the battery cell 100a to the principal surface 11, for example.

The through hole 20b is open on the principal surface 11 but is not open on the principal surface 12. The through hole 20b is open at an opening position 21b located on the principal surface 11.

The through hole 20b extends from a battery cell 100b among the battery cells 100, which is different from the battery cell 100a, to the principal surface 11. The battery cell 100b is an intermediate battery cell 100 where other battery cells 100 are laminated above and below the relevant battery cell 100, for example. To be more precise, the through hole 20b penetrates from the principal surface on the lower side of the counter electrode active material layer 122 (in other words, the principal surface on the upper side of the counter electrode current collector 121) of the battery cell 100b to the principal surface 11. The battery cell 100b is an example of a second battery cell.

In each battery cell 100 that the through hole 20a passes through, a sectional area of the through hole 20a in the electrode layer 110 in a direction perpendicular to the direction of lamination is larger than a sectional area of the through hole 20a in the counter electrode layer 120 in the direction perpendicular to the direction of lamination. The direction perpendicular to the direction of lamination is equivalent to a direction of extension of each layer. As a consequence, the sectional area of the through hole 20a becomes larger at the position of the principal surface on the counter electrode active material layer 122 side of the electrode active material layer 112 and the area of the relevant principal surface of the electrode active material layer 112 becomes smaller accordingly. In the present embodiment, the electrode layer 110 is the positive electrode layer and the counter electrode layer 120 is the negative electrode layer. Accordingly, it is possible to suppress precipitation and the like of a metal (so-called a dendrite) originating from metallic ions that are failed to be captured in the counter electrode layer 120, thereby enhancing reliability and safety of the battery 1. This also applies to the through hole 20b. In each battery cell 100 that the through hole 20b passes through, a sectional area of the through hole 20b in the electrode layer 110 in the direction perpendicular to the direction of lamination is larger than a sectional area of the through hole 20b in the counter electrode layer 120 in the direction perpendicular to the direction of lamination.

In the present embodiment, in each of the battery cells 100, the electrode layer 110 is disposed on the principal surface 11 side and the counter electrode layer 120 is disposed on the principal surface 12 side. The through hole 20a has such a shape that its sectional area on the principal surface 12 side is smaller than that on the principal surface 11 side in the direction of lamination. Accordingly, an opening area of the through hole 20a on the principal surface 11 side is larger than an opening are of the through hole 20a on the principal surface 12 side. As will be described later, the current collecting terminal 51 is located on an inner side of the through hole 20a in plan view of the principal surface 11. By increasing the opening area of the through hole 20a on the principal surface 11 side, it is easier to form the current collecting terminal 51 to be provided on the principal surface 11 side. The through hole 20b also has such a shape that its sectional area on the principal surface 12 side is smaller than that on the principal surface 11 side in the direction of lamination.

An inner wall 25a of the through hole 20a and an inner wall 25b of the through hole 20b are inclined with respect to the direction of lamination. That is to say, the through hole 20a includes the inner wall 25a of a tapered shape. Meanwhile, the through hole 20b includes the inner wall 25b of a tapered shape. Accordingly, it is possible to differentiate between the sectional areas of the through hole 20a and the through hole 20b in the electrode layer 110 and the counter electrode layer 120 easily. Moreover, since it is easier to put materials and the like into the through hole 20a and the through hole 20b, a conductive member and an insulating member can be formed easily inside the through hole 20a and inside the through hole 20b. The inner wall 25a is an inner side surface of the power generation element 5 constituting the through hole 20a, or more specifically, inner side surfaces of the electrode layer 110, the solid electrolyte layer 130, and the counter electrode layer 120 of each battery cell 100 that the through hole 20a passes through. The inner wall 25b is an inner side surface of the power generation element 5 constituting the through hole 20b, or more specifically, inner side surfaces of the electrode layer 110, the solid electrolyte layer 130, and the counter electrode layer 120 of each battery cell 100 that the through hole 20b passes through. In the present embodiment, the entire surfaces of the inner wall 25a and the inner wall 25b are inclined with respect to the direction of lamination. Note that there may be a portion on any of the inner wall 25a and the inner wall 25b, which is not inclined with respect to the direction of lamination. In the meantime, at least one of the inner wall 25a and the inner wall 25b may be kept from being inclined with respect to the direction of lamination, or in other words, may be parallel to the direction of lamination.

Meanwhile, each of the through hole 20a and the through hole 20b has a truncated cone shape, for example. Accordingly, no angles are formed on the inner wall 25a of the through hole 20a and on the inner wall 25b of the through hole 20b, so that electric field concentration can be suppressed inside the through hole 20a and inside the through hole 20b. Moreover, the through hole 20a and the through hole 20b can be formed easily with a drill having a tapered angle, for example. Note that the shape of the through hole 20a and the through hole 20b is not limited to the truncated cone shape but may be any other shapes including a truncated polygonal pyramid shape such as a truncated quadrangular pyramid shape and a truncated hexagonal pyramid shape, a columnar shape, a prism shape, and so forth.

Each of the through hole 20a and the through hole 20b extends in the direction of lamination. Here, at least one of the through hole 20a and the through hole 20b may extend in an inclined direction with respect to the direction of lamination.

The through hole 20a and the through hole 20b are arranged in the x-axis direction in plan view. A positional relationship between the through hole 20a and the through hole 20b in plan view is not limited to a particular relationship, and is designed depending on a wiring pattern on a board on which the battery 1 is mounted, for example.

### 3. Insulating Members

Next, the insulating member 31 and the insulating member 32 will be described.

The insulating member 31 is disposed inside the through hole 20a. The insulating member 31 is an example of a first insulating member. The insulating member 31 is located between the conductive member 41 and the inner wall 25a of the through hole 20a. The insulating member 31 can secure insulation between the conductive member 41 and the inner side surface of the power generation element 5 which is the inner wall 25a of the through hole 20a.

The insulating member 31 is disposed along the inner wall 25a of the through hole 20a. The insulating member 31 covers the inner wall 25a of the through hole 20a in a lump and is in contact with the inner wall 25a of the through hole 20a. This makes it possible to suppress collapse of the materials of the respective layers of the battery cell 100 on the inner wall 25a of the through hole 20a and to suppress a short circuit between the electrode layer 110 and the counter electrode layer 120. The insulating member 31 covers the entire inner wall 25a of the through hole 20a, for example. A clearance may be provided at a certain part between the insulating member 31 and the inner wall 25a.

The insulating member 31 surrounds an outer periphery of the conductive member 41 when viewed in the direction of lamination and is in contact with the conductive member 41. In the present embodiment, the conductive member 41 has a columnar shape, and the insulating member 31 covers the entire side surface of the columnar conductive member 41 and is in contact with the side surface of the conductive member 41. A clearance may be provided at a certain part between the insulating member 31 and the conductive member 41.

The insulating member 31 and the conductive member 41 are packed together so as to bury the through hole 20a. The insulating member 31 completely buries a space between the inner wall 25a of the through hole 20a and the conductive member 41, for example. For this reason, a shape of the insulating member 31 is the same as the shape of the through hole 20a except that a through hole to be penetrated by the conductive member 41 is formed at the center when viewed in the direction of lamination. In the present embodiment, the shape of the insulating member 31 is a tubular shape having a circular or polygonal circumference, for example. To be more precise, the shape of the insulating member 31 is an elongate truncated cone shape provided with the through hole to be penetrated by the conductive member 41 at the center when viewed in the direction of lamination. Note that the shape of the insulating member 31 is not limited to the aforementioned shape. The insulating member 31 is formed in conformity to the shapes of the through hole 20a and the conductive member 41, for example.

The insulating member 32 is disposed inside the through hole 20b. The insulating member 32 is an example of a second insulating member. The insulating member 32 is located between the conductive member 42 and the inner wall 25b of the through hole 20b. The insulating member 32 can secure insulation between the conductive member 42 and the inner side surface of the power generation element 5 which is the inner wall 25b of the through hole 20b.

The insulating member 32 is disposed along the inner wall 25b of the through hole 20b. The insulating member 32 covers the inner wall 25b of the through hole 20b in a lump and is in contact with the inner wall 25b of the through hole 20b. This makes it possible to suppress collapse of the materials of the respective layers of the battery cell 100 on the inner wall 25b of the through hole 20b and to suppress a short circuit between the electrode layer 110 and the counter electrode layer 120. The insulating member 32 covers the entire inner wall 25b of the through hole 20b, for example. A clearance may be provided at a certain part between the insulating member 32 and the inner wall 25b.

The insulating member 32 surrounds an outer periphery of the conductive member 42 when viewed in the direction of lamination and is in contact with the conductive member 42. In the present embodiment, the conductive member 42 has a columnar shape, and the insulating member 32 covers the entire side surface of the columnar conductive member 42 and is in contact with the side surface of the conductive member 42. A clearance may be provided at a certain part between the insulating member 32 and the conductive member 42.

The insulating member 32 and the conductive member 42 are packed together so as to bury the through hole 20b. The insulating member 32 completely buries a space between the inner wall 25b of the through hole 20b and the conductive member 42, for example. For this reason, a shape of the insulating member 32 is the same as the shape of the through hole 20b except that a through hole to be penetrated by the conductive member 42 is formed at the center when viewed in the direction of lamination. In the present embodiment, the shape of the insulating member 32 is a tubular shape having a circular or polygonal circumference, for example. To be more precise, the shape of the insulating member 32 is an elongate truncated cone shape provided with the through hole to be penetrated by the conductive member 42 at the center when viewed in the direction of lamination. Note that the shape of the insulating member 32 is not limited to the aforementioned shape. The insulating member 32 is formed in conformity to the shapes of the through hole 20b and the conductive member 42, for example.

A thickness of the insulating member 31 is gradually increased from an end portion on the principal surface 12 side of the insulating member 31 toward an end portion on the principal surface 11 side of the insulating member 31. Since the battery cells 100 are laminated while being connected in series, a potential difference between the conductive member 41 that passes through the through hole 20a and is electrically connected to the principal surface 12 and the battery cell 100 at the corresponding position grows larger as a location between the conductive member 41 and the battery cell 100 is closer to the principal surface 11. Accordingly, the thickness of the insulating member 31 is larger in a region where the potential difference between the conductive member 41 and the battery cell 100, in other words, a voltage insulated by the insulating member 31 is larger. As a consequence, insulation reliability is enhanced so that reliability of the battery 1 can be improved. In the present embodiment, the thickness of the insulating member 31 is equal to a distance between the conductive member 41 and the inner wall 25a. Details of the conductive member 41 will be described later. As with the insulating member 31, a thickness of the insulating member 32 is gradually increased from an end portion on the principal surface 12 side of the insulating member 32 toward an end portion on the principal surface 11 side of the insulating member 32. In the present embodiment, the thickness of the insulating member 32 is equal to a distance between the conductive member 42 and the inner wall 25b. Accordingly, the same effect as that of the insulating member 31 is available. Here, thickness distribution of each of the insulating member 31 and the insulating member 32 is not limited. The thickness of at least one of the insulating member 31 and the insulating member 32 may be constant.

Each of the insulating member 31 and the insulating member 32 is formed by using an insulating material having an electrical insulation property. For example, each of the insulating member 31 and the insulating member 32 contains a resin. The resin is an epoxy-based resin, for example. However, the resin is not limited thereto. Here, an inorganic material may be used as the insulating material. The insulating material usable therein is selected based on various characteristics including flexibility, gas barrier properties, shock resistance, heat resistance, and the like.

The insulating member 31 is formed by filling the through hole 20a with the insulating material, molding the insulating material into the shape of the through hole 20a, or coating the insulating material onto the inner wall 25a, for example. The insulating member 32 can also be formed in accordance with the same methods as those for the insulating member 31.

### 4. Conductive Members and Connecting Member

Next, the conductive member 41, the conductive member 42, and the connecting member 50 will be described.

The conductive member 41 is disposed inside the through hole 20a. The conductive member 41 is an example of a first conductive member. The conductive member 41 is electrically connected to the principal surface 12 of the power generation element 5 while interposing the connecting member 50 therebetween. For this reason, the conductive member 41 is electrically connected to the end portion layer current collector 150 on the counter electrode layer 120 of the lowermost battery cell 100a, that is, to the counter electrode current collector 121 without being connected to other battery cells 100. Since the principal surface 11 is the principal surface on the upper side of the electrode layer 110 located uppermost, the conductive member 41 is connected to the counter electrode layer 120 having the different polarity from that of the principal surface 11.

The conductive member 41 extends from the opening position 22a of the through hole 20a on the principal surface 12 to the opening position 21a of the through hole 20a located at the principal surface 11 while passing through the through hole 20a. The conductive member 41 penetrates from the principal surface 11 to the principal surface 12 of the power generation element 5 while passing through the through hole 20a. Accordingly, a potential at the counter electrode layer 120 of the battery cell 100a located lowermost is induced to the principal surface 11 side so that an electric current can be extracted from the lowermost battery cell 100a on the principal surface 11 side of the power generation element 5. In other words, in the present embodiment, the conductive member 41 functions as a penetrating electrode that penetrates all of the battery cells 100 included in the power generation element 5.

An end portion on the principal surface 11 side of the conductive member 41 is in contact with the current collecting terminal 51. An end portion on the principal surface 12 side of the conductive member 41 is in contact with the connecting member 50.

The insulating member 31 is disposed between the conductive member 41 and the inner wall 25a. The conductive member 41 is not in contact with the electrode active material layer 112, the solid electrolyte layer 130, the counter electrode active material layer 122, the intermediate layer current collector 140, and the end portion layer current collector 150 on an upper end on the inner wall 25a of the through hole 20a. In other words, the conductive member 41 extends from the opening position 22a to the opening position 21a inside the through hole 20a while retaining insulation from the battery cells 100.

In the present embodiment, the principal surface 11 is a first surface where the opening position 21a to which the potential at the battery cell 100a is induced by the conductive member 41 is disposed. Since the principal surface 11 is the principal surface on the upper side of the battery cell 100 located uppermost, the battery cells 100 laminated from the battery cell 100a to the uppermost battery cell 100 are the battery cells 100 involved in the connection between the principal surface 11 and the battery cell 100a. A voltage between the principal surface 11 and the conductive member 41 corresponds to the number of the battery cells 100 involved in the serial connection between the principal surface 11 and the battery cell 100a. In the present embodiment, the voltage between the principal surface 11 and the conductive member 41 corresponds to a voltage obtained by the serial connection of all of the battery cells 100 of the power generation element 5.

The conductive member 42 is disposed inside the through hole 20b. The conductive member 42 is an example of a second conductive member. The conductive member 42 is electrically connected to the counter electrode current collector 121 in the counter electrode layer 120 of the battery cell 100b without being connected to other battery cells 100. Since the principal surface 11 is the principal surface on the upper side of the electrode layer 110 located uppermost, the conductive member 42 is connected to the counter electrode layer 120 having the different polarity from that of the principal surface 11.

The conductive member 42 extends from the principal surface on the upper side of the counter electrode current collector 121 of the battery cell 100b to the opening position 21b of the through hole 20b located at the principal surface 11 while passing through the through hole 20b. The conductive member 42 penetrates from the principal surface 11 to the principal on the upper side of the counter electrode current collector 121 of the battery cell 100b while passing through the through hole 20b. Accordingly, a potential at the counter electrode layer 120 of the battery cell 100b among the battery cells 100, which is different from the battery cell 100a, is induced to the principal surface 11 side so that an electric current can be extracted from the battery cell 100b on the principal surface 11 side of the power generation element 5. In other words, in the present embodiment, the conductive member 42 functions as a penetrating electrode that penetrates a portion of the battery cells 100 included in the power generation element 5.

An end portion on the principal surface 11 side of the conductive member 42 is in contact with the current collecting terminal 52. An end portion on the principal surface 12 side of the conductive member 42 is in contact with the counter electrode current collector 121 of the battery cell 100b.

The insulating member 32 is disposed between the conductive member 42 and the inner wall 25b. The conductive member 42 is not in contact with the electrode active material layer 112, the solid electrolyte layer 130, the counter electrode active material layer 122, the intermediate layer current collector 140, and the end portion layer current collector 150 on the upper end on the inner wall 25b of the through hole 20b. In other words, the conductive member 42 extends from the principal surface on the upper side of the counter electrode current collector 121 of the battery cell 100b to the opening position 21b inside the through hole 20b while retaining insulation from the battery cells 100.

In the present embodiment, the principal surface 11 is a second surface where the opening position 21b to which the potential at the battery cell 100b is induced by the conductive member 42 is disposed. Accordingly, each of the first surface and the second surface is the same principal surface 11 in the present embodiment. Since the principal surface 11 is the principal surface on the upper side of the battery cell 100 located uppermost, the battery cells 100 laminated from the battery cell 100b to the uppermost battery cell 100 are the battery cells 100 involved in the connection between the principal surface 11 and the battery cell 100b. The battery cells 100 involved in the connection between the principal surface 11 and the battery cell 100a do not coincide with the battery cells 100 involved in the connection between the principal surface 11 and the battery cell 100b. A voltage between the principal surface 11 and the conductive member 42 corresponds to the number of the battery cells 100 involved in the serial connection between the principal surface 11 and the battery cell 100b. The battery cells 100 involved in the connection between the principal surface 11 and the conductive member 42 constitute a cell laminated body 107 being serially connected and laminated. In the present embodiment, the number of the battery cells 100 included in the cell laminated body 107 is half as many as the number of the battery cells included in the power generation element 5. Accordingly, the voltage between the principal surface 11 and the conductive member 42 corresponds to a voltage obtained by serially connecting the half of the battery cells 100 in the power generation element 5. In other words, the voltage between the principal surface 11 and the conductive member 42 is one-half of the voltage between the principal surface 11 and the conductive member 41.

In the present embodiment, the number of the battery cells 100 involved in the serial connection between the principal surface 11 and the battery cell 100a is different from the number of the battery cells 100 involved in the serial connection between the principal surface 11 and the battery cell 100b. Accordingly, the battery 1 can supply the two types of voltages that involve the different numbers of the battery cells 100 serially connected on the principal surface 11 side.

Each of the conductive member 41 and the conductive member 42 has a columnar shape, for example, but may have any other shapes including a prism shape, a truncated cone shape, a truncated pyramid shape, and the like. A diameter of each of the conductive member 41 and the conductive member 42 is constant, for example.

Each of the conductive member 41 and the conductive member 42 is formed by using a conductive resin material and the like. The conductive resin material contains metal particles and a resin, for example. Alternatively, each of the conductive member 41 and the conductive member 42 may be formed by using a metal material such as aluminum, copper, nickel, stainless steel, and solder. The conductive material usable therein is selected based on various characteristics including flexibility, gas barrier properties, shock resistance, heat resistance, solder wettability, and the like. For example, each of the conductive member 41 and the conductive member 42 can be formed in accordance with a method such as printing, plating, and molding. The conductive member 41 and the conductive member 42 are formed by using the same material. Instead, the conductive member 41 and the conductive member 42 may be formed by using different materials from each other.

The connecting member 50 is disposed on the principal surface 12 side of the power generation element 5. The connecting member 50 is connected to the conductive member 41 at the opening position 22a. The connecting member 50 covers the principal surface 12 in the vicinity of the opening position 22a and is also connected to the principal surface 12. The connecting member 50 establishes electric connection between the conductive member 41 and the principal surface 12, that is, the counter electrode layer 120 of the battery cell 100a located lowermost.

The connecting member 50 is formed by using a conductive material. For example, the connecting member 50 is formed by using a metal material such as aluminum, copper, nickel, stainless steel, and solder. Alternatively, the connecting member 50 may be formed by using a conductive resin material and the like. For example, the connecting member 50 can be formed in accordance with a method such as printing, plating, and soldering. Alternatively, the connecting member 50 may be formed by drawing the conductive member 41 from the through hole 20a to outside of the principal surface 12 and being connected to the principal surface 12. In other words, the connecting member 50 may be a portion of the conductive member 41.

### 5. Current Collecting Terminals

Next, the current collecting terminal 51, the current collecting terminal 52, and the current collecting terminal 55 will be described.

The current collecting terminal 51 is disposed on the principal surface 11 side of the power generation element 5. The current collecting terminal 51 is connected to the conductive member 41 at the opening position 21a. In this way, the current collecting terminal 51 is electrically connected to the counter electrode layer 120 of the battery cell 100a located lowermost while interposing the conductive member 41 and the connecting member 50 therebetween. The current collecting terminal 51 is one of external connection terminals of the battery 1, which is a negative extraction terminal in the present embodiment. A portion of the current collecting terminal 51 is in contact with the insulating member 31. Here, the current collecting terminal 51 does not always have to be in contact with the insulating member 31. Alternatively, the current collecting terminal 51 may be connected to the conductive member 41 while interposing another conductive connecting layer or the like therebetween.

As illustrated in FIG. 2, the current collecting terminal 51 is located on an inner side of the through hole 20a in plan view of the principal surface 11, which is located on an inner side relative to an outer periphery of the insulating member 31 in the present embodiment. As a consequence, the current collecting terminal 51 is not in contact with the principal surface 11, and is insulated from the principal surface 11, that is, the electrode layer 110 of the battery cell 100 located uppermost.

The current collecting terminal 52 is disposed on the principal surface 11 side of the power generation element 5. The current collecting terminal 52 is connected to the conductive member 42 at the opening position 21b. In this way, the current collecting terminal 52 is electrically connected to the counter electrode layer 120 of the battery cell 100b while interposing the conductive member 42 therebetween. The current collecting terminal 52 is one of the external connection terminals of the battery 1, which is a negative extraction terminal in the present embodiment. A portion of the current collecting terminal 52 is in contact with the insulating member 32. Here, the current collecting terminal 52 does not always have to be in contact with the insulating member 32. Alternatively, the current collecting terminal 52 may be connected to the conductive member 42 while interposing another conductive connecting layer or the like therebetween.

As illustrated in FIG. 2, the current collecting terminal 52 is located on an inner side of the through hole 20b in plan view of the principal surface 11, which is located on an inner side relative to an outer periphery of the insulating member 32 in the present embodiment. As a consequence, the current collecting terminal 52 is not in contact with the principal surface 11, and is insulated from the principal surface 11, that is, the electrode layer 110 of the battery cell 100 located uppermost.

The current collecting terminal 55 is disposed on the principal surface 11 side of the power generation element 5. As a consequence, the current collecting terminal 51, the current collecting terminal 52, and the current collecting terminal 55 are provided on the same principal surface 11 side of the power generation element 5. The current collecting terminal 55 is disposed on the principal surface 11 and is connected to the principal surface 11. That is to say, the current collecting terminal 55 is electrically connected to the end portion layer current collector 150 at the electrode layer 110 of the uppermost battery cell 100, namely, to the electrode current collector 111. The current collecting terminal 55 is one of the external connection terminals of the battery 1, which is a positive extraction terminal in the present embodiment. Here, the current collecting terminal 55 may be connected to the principal surface 11 while interposing another conductive connecting layer or the like therebetween.

The current collecting terminal 51, the current collecting terminal 52, and the current collecting terminal 55 are arranged in the x-axis direction in plan view, for example. Meanwhile, the current collecting terminal 55 is disposed outside of at least one of the current collecting terminal 51 and the current collecting terminal 52, that is, at a position close to the outer periphery of the principal surface 11, for example. Note that the positional relationship among the current collecting terminal 51, the current collecting terminal 52, and the current collecting terminal 55 is not limited to a particular relationship, and is designed depending on the wiring pattern of the board on which the battery 1 is mounted, for example. The current collecting terminal 55 may be disposed between the current collecting terminal 51 and the current collecting terminal 52 in plan view, for instance.

Each of the current collecting terminal 51, the current collecting terminal 52, and the current collecting terminal 55 is a projecting terminal provided on the principal surface 11 side of the power generation element 5. However, shapes of the current collecting terminal 51, the current collecting terminal 52, and the current collecting terminal 55 are not limited to particular shapes. The current collecting terminal 51, the current collecting terminal 52, and the current collecting terminal 55 may undergo a required insulation treatment and then spread in a plate-like fashion along the principal surface 11.

Each of the current collecting terminal 51, the current collecting terminal 52, and the current collecting terminal 55 is formed by using a conductive material. For example, each of the current collecting terminal 51, the current collecting terminal 52, and the current collecting terminal 55 is formed by using a metal material such as aluminum, copper, nickel, stainless steel, and solder. Alternatively, each of the current collecting terminal 51, the current collecting terminal 52, and the current collecting terminal 55 may be formed by using a conductive resin material and the like. For example, each of the current collecting terminal 51, the current collecting terminal 52, and the current collecting terminal 55 can be formed in accordance with a method such as printing, plating, and soldering. Alternatively, the current collecting terminal 51 may be formed by causing the conductive member 41 to project from the through hole 20a to the outside of the principal surface 11. In other words, the current collecting terminal 51 may be a portion of the conductive member 41. Likewise, the current collecting terminal 52 may be formed by causing the conductive member 42 to project from the through hole 20b to the outside of the principal surface 11. In other words, the current collecting terminal 52 may be a portion of the conductive member 42.

### 6. Usage Example

Next, a usage example of the battery 1 will be described. Note that the following usage example is a mere example and a mode of using the battery 1 is not limited to a particular method.

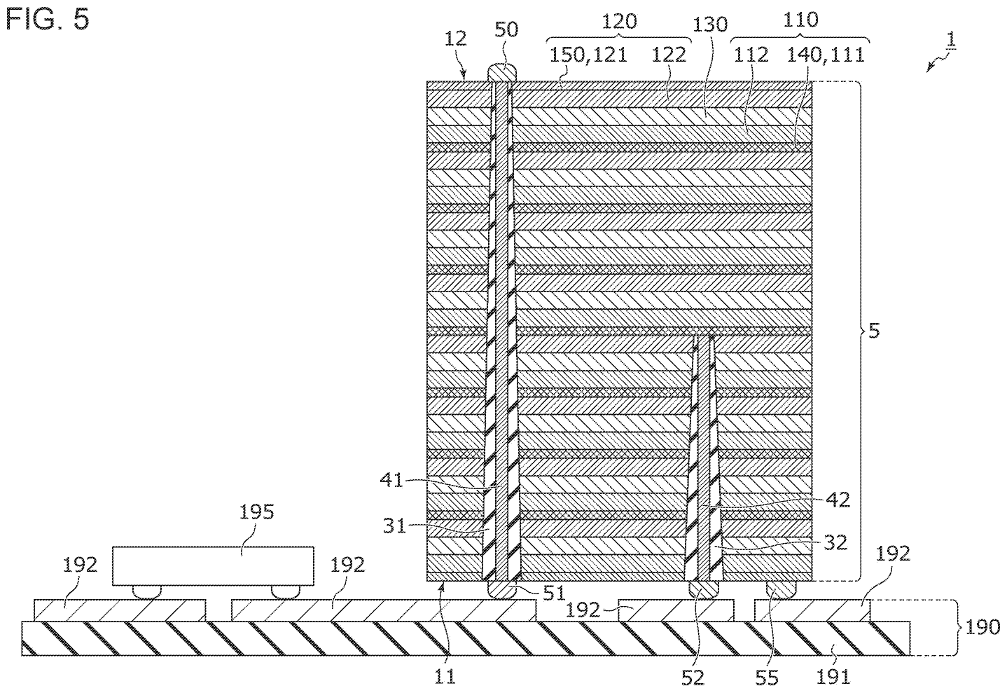

The battery 1 according to the present embodiment is used by being mounted on a circuit board, for example. FIG. 5 is a sectional view illustrating a usage example of the battery 1. FIG. 5 illustrates the battery 1 mounted on a circuit board 190, which is in a state of turning the battery 1 illustrated in FIG. 1 upside down.

As illustrated in FIG. 5, the circuit board 190 for mounting the battery 1 includes an insulative plate-like base body 191 and circuit wiring 192. The circuit wiring 192 is a circuit pattern formed on the base body 191.

The current collecting terminal 51 of the battery 1 is connected to a portion of the circuit wiring 192, for example. Meanwhile, the current collecting terminal 52 of the battery 1 is connected to a different portion of the circuit wiring 192, for example. In the meantime, the current collecting terminal 55 of the battery 1 is connected to another different portion of the circuit wiring 192, for example. Thus, electric power is supplied from the battery 1 to an electronic device 195 mounted on the circuit board 190 and connected to the circuit wiring 192. In the example illustrated in FIG. 5, the conductive member 41 is electrically connected to the electronic device 195 while interposing the circuit wiring 192 therebetween. In the battery 1, another electronic device is electrically connected to the conductive member 42 while interposing the circuit wiring 192 therebetween, so that a voltage different from a voltage from the conductive member 41 can be supplied to the different electronic device.

In the battery 1, the current collecting terminal 51, the current collecting terminal 52, and the current collecting terminal 55 being the extraction terminals of the positive and negative electrodes are provided at the same principal surface 11. Since the current collecting terminal 51, the current collecting terminal 52, and the current collecting terminal 55 are disposed on the inner side of the outer periphery of the power generation element 5 in plan view, the battery 1 can be mounted on the circuit board 190 with a minimum mounting area and a low profile. Particularly, in the case of mounting on the board provided with circuits to which different voltages are to be supplied, such different voltage can be supplied by using the battery 1 instead of using two or more batteries. Thus, it is possible to realize downsizing of a circuit system.

Moreover, provision of the current collecting terminal 51, the current collecting terminal 52, and the current collecting terminal 55 at the principal surface 11 can also shorten a wiring length of the circuit wiring 192 easily, so that wiring resistance and noise attributed to a current flowing on the wiring can be reduced.

Note that any of batteries according to respective embodiments to be described below may be mounted on the circuit board 190 instead.

### 7. Summary

As described above, according to the battery 1 of the present embodiment, the battery cells 100 are laminated while being connected in series. Thus, it is possible to realize the battery 1 that achieves the high capacity density and the high voltage.

Meanwhile, the conductive member 41 that passes through the through hole 20a and the conductive member 42 that passes through the through hole 20b can induce the potentials at the respective counter electrode layers 120 of both the battery cell 100a and the battery cell 100b to the principal surface 11 side. In other words, the voltages corresponding to two combinations of connection of the battery cells 100 in the power generation element 5 can be supplied on the principal surface 11 side. In the present embodiment, the battery 1 can supply the voltage corresponding to the serial connection of all of the battery cells 100 of the power generation element 5 and the voltage corresponding to the serial connection of all of the battery cell 100 of the cell laminated body 107 being a portion of the power generation element 5. Thus, more than one type of the voltage can be supplied to the electronic devices and the like by using the single battery 1, so that the battery 1 can enhance usability.

In the meantime, both of the voltages corresponding to the two combinations of connection of the battery cells 100 can be supplied on the principal surface 11 side. Accordingly, it is possible to assemble compact mounting of the battery 1. For example, a pattern of connection terminals (also referred to as footprints) to be formed on the board can be reduced in size. Moreover, it is possible to carry out mounting in a state of arranging the principal surface 11 of the battery 1 and the board in parallel, so that low profile mounting on the board can be realized. Reflow soldering and the like can be used for the mounting. As described above, it is possible to realize the battery 1 that is highly usable and excellent in mountability.

Meanwhile, the conductive member 41 and the conductive member 42 used for supplying the voltages corresponding to the two combinations of connection of the battery cells 100 pass through the power generation element 5. Therefore, it is not necessary to form a structure required for supplying the two types of voltages on the outside of a side surface of the power generation element 5. Accordingly, the battery 1 can be downsized so that the capacity density of the battery 1 can be increased. It is possible to reduce the mounting area when the battery 1 is mounted on the board, for example.

In the meantime, a terminal for extracting the current need not be formed as a consequence of a process such as causing the current collector to project in the form of a tab from a portion on the side surface of the power generation element 5. Accordingly, the side surface of the power generation element 5 of the battery 1 can be formed into a flat side surface by cutting the laminated battery cells 100 in a lump, for example. Adoption of the lump cutting accurately determines the respective areas of the electrode layer 110, the counter electrode layer 120, and the solid electrolyte layer 130 while avoiding a gradual increase and a gradual decrease in film thickness at starting and terminating ends when coating each layer. Thus, a variation in capacity among the battery cells 100 is reduced so that accuracy of a battery capacity can be enhanced.

Meanwhile, in the battery 1, the conductive member 41 and the conductive member 42 pass through the through holes that are different from each other. Accordingly, it is possible to increase freedom of a layout of the conductive member 41 and the conductive member 42.

In the meantime, a conductive member such as the conductive member 42 connected to the intermediate battery cell 100b can be used for monitoring the voltage at the battery cell 100 at an intermediate portion of the battery cells 100 connected in series, that is, for measuring an intermediate voltage. For example, the conductive member 42 can be used for monitoring the voltage at the cell laminated body 107. Meanwhile, in the battery 1, the electric power is supplied from a portion of the battery cells 100 in the power generation element 5 by using the conductive member 42. Accordingly, there may a case where a quantity of electricity of the battery cells 100 does not evenly change. In this case, an operation to equalize the quantity of electricity of the battery cells 100 may be carried out by monitoring the voltage at the cell laminated body 107 with the conductive member 42 and charging or discharging certain battery cell or cells 100 depending on the variation in quantity of electricity of the battery cells 100. This operation makes it possible to retain the capacity and reliability of the battery 1 for a long time.

### Embodiment 2

Next, a description will be given of Embodiment 2. The following description will be focused on different features from those of the Embodiment 1 while omitting or simplifying explanations of features in common.

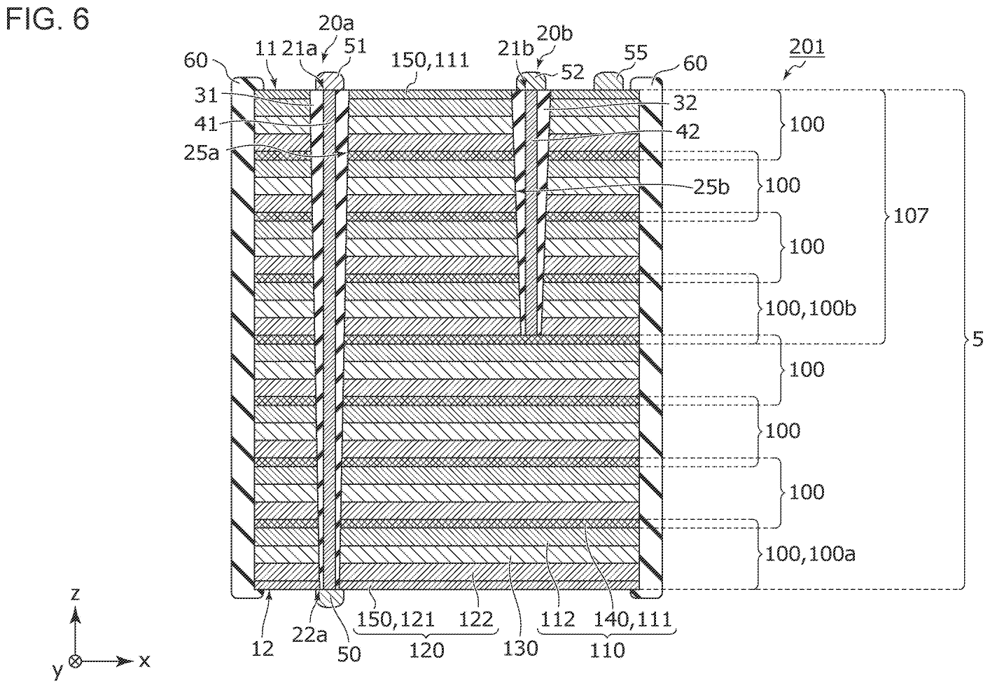

FIG. 6 is a sectional view of a battery 201 according to the present embodiment. As illustrated in FIG. 6, in comparison with the battery 1 according to the Embodiment 1, the battery 201 is different in that the battery 201 further includes a side surface insulating layer 60.

The side surface insulating layer 60 covers a side surface of the power generation element 5. The side surface insulating layer 60 covers all of the side surfaces of the power generation element 5, for example. This configuration can achieve suppression of collapse of the materials of the respective layers on the side surface of the power generation element 5, enhancement of weather resistance, enhancement of shock resistance, and the like, thereby improving reliability of the battery 201.

Alternatively, the side surface insulating layer 60 may cover respective end portions of the principal surface 11 and the principal surface 12. In this way, it is possible to suppress detachment of the end portion layer current collectors 150 disposed at the principal surface 11 and the principal surface 12, thereby further improving the reliability of the battery 201.

The side surface insulating layer 60 is formed by using an insulating material having an electrical insulation property. For example, the side surface insulating layer 60 contains a resin. The resin is an epoxy-based resin, for example. However, the resin is not limited thereto. Here, an inorganic material may be used as the insulating material. The insulating material usable therein is selected based on various characteristics including flexibility, gas barrier properties, shock resistance, heat resistance, and the like.

Note that the side surface insulating layer 60 may be provided to a battery according to each of the embodiments to be described later.

### Embodiment 3

Next, a description will be given of Embodiment 3. The following description will be focused on different features from those of the Embodiments 1 and 2 while omitting or simplifying explanations of features in common.

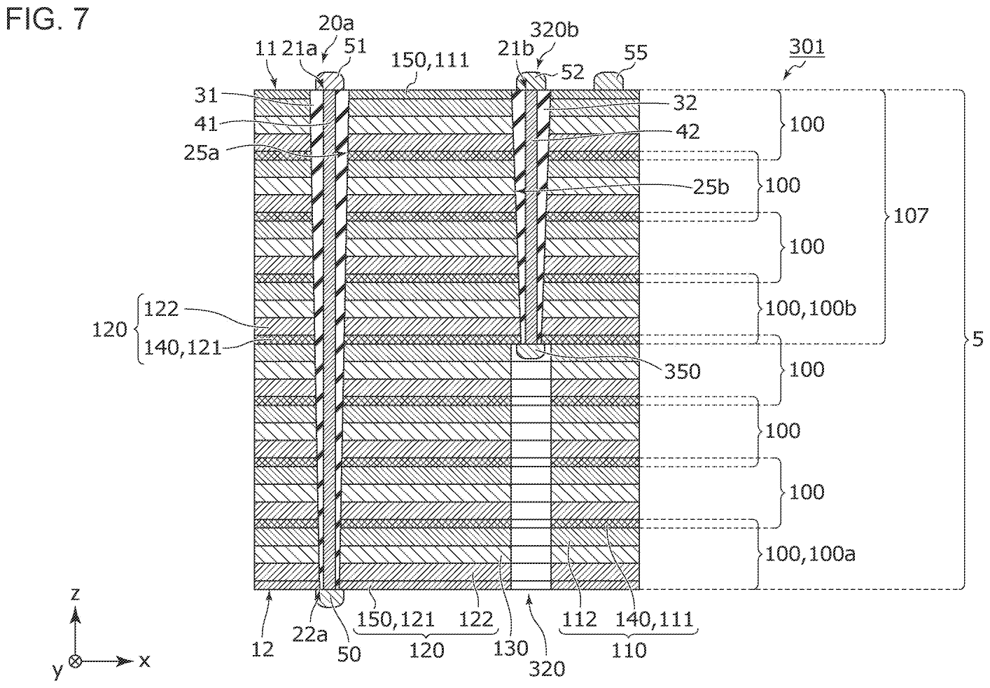

FIG. 7 is a sectional view of a battery 301 according to the present embodiment. As illustrated in FIG. 7, in comparison with the battery 1 according to the Embodiment 1, the battery 301 is different in that the power generation element 5 is provided with a through hole 320b instead of providing the power generation element 5 with the through hole 20b, and that the power generation element 5 is further provided with a through hole 320. Moreover, in comparison with the battery 1 according to the Embodiment 1, the battery 301 is also different in that the battery 301 further includes a connecting member 350.

The through hole 320b has the same characteristics as those of the through hole 20b except that the through hole 320b penetrates from a principal surface on the lower side of the counter electrode current collector 121 of the battery cell 100b, that is, the principal surface on the lower side of the battery cell 100b to the principal surface 11. The through hole 320b is an example of the second through hole. The through hole 20a and the through hole 320b are not connected to each other and are independent of each other.

The through hole 320 penetrates a portion of the battery cells 100 of the power generation element 5 in the direction of lamination. To be more precise, the through hole 320 penetrates from the principal surface 12 to the principal surface on the lower side of the counter electrode current collector 121 of the battery cell 100b, that is to say, to the principal surface on the lower side of the battery cell 100b. Moreover, the through hole 320 is continuous with the through hole 320b. Accordingly, the through hole 320b and the through hole 320 collectively constitute a single through hole that penetrates the entire power generation element 5, that is to say, from the principal surface 12 to the principal surface 11.

A shape of the through hole 320 is a columnar shape, for example, but may be any other shapes such as a prism shape.

At the principal surface on the lower side of the battery cell 100b, the through hole 320 is larger than the through hole 320b. For this reason, the through hole 320 exposes the vicinity of the through hole 320b at the principal surface on the lower side of the battery cell 100b.

The connecting member 350 is provided at a portion of the principal surface on the lower side of the battery cell 100b exposed by the through hole 320. The connecting member 350 is located at an end portion on the through hole 320b side in the through hole 320. The connecting member 350 is connected in contact with the conductive member 42 and with the principal surface on the lower side of the counter electrode current collector 121 of the battery cell 100b, thereby electrically connecting the conductive member 42 to the counter electrode layer 120 of the battery cell 100b. Thus, the potential at the counter electrode layer 120 of the battery cell 100b is induced to the principal surface 11 side by the conductive member 42 as with the battery 1.

The connecting member 350 can be formed by using the same material as that of the connecting member 50. Alternatively, the connecting member 350 may be formed by causing the conductive member 42 to project from the through hole 320b to the through hole 320 side. In other words, the connecting member 350 may be a portion of the conductive member 42.

As described above, in the battery 301, the conductive member 42 is electrically connected to the counter electrode current collector 121 of the battery cell 100b by using the connecting member 350. Thus, it is possible to establish the electrical connection between the conductive member 42 and the battery cell 100b more firmly. Moreover, by arranging the through hole 320b continuously with the through hole 320, the through hole 320b for allowing passage of the conductive member 42 can be formed easily without having to form the through hole 320b into such a shape that penetrates into the middle of the battery cell 100b.

### Embodiment 4

Next, a description will be given of Embodiment 4. The following description will be focused on different features from those of the Embodiments 1 to 3 while omitting or simplifying explanations of features in common.

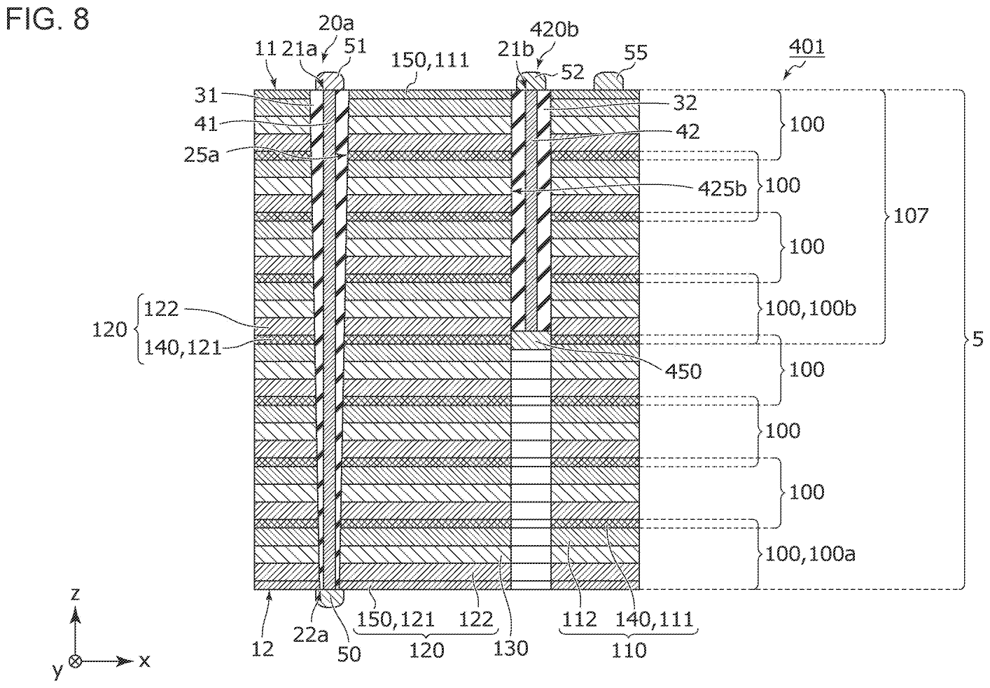

FIG. 8 is a sectional view of a battery 401 according to the present embodiment. As illustrated in FIG. 8, in comparison with the battery 1 according to the Embodiment 1, the battery 401 is different in that the power generation element 5 is provided with a through hole 420b instead of providing the power generation element 5 with the through hole 20b. Moreover, in comparison with the battery 1 according to the Embodiment 1, the battery 401 is also different in that the battery 401 further includes a connecting member 450.

The through hole 420b penetrates the entire power generation element 5, that is to say, from the principal surface 12 to the principal surface 11 in the direction of lamination. The through hole 20a and the through hole 420b are not connected to each other and are independent of each other. In the through hole 420b, the insulating member 32 and the conductive member 42 are packed in a location corresponding to a range from the battery cell 100b to the principal surface 11.

A shape of the through hole 420b is a columnar shape, for example, but may be any other shapes such as a prism shape. Alternatively, the shape of the through hole 420b may be the same shape as the through hole 20a.

The connecting member 450 is disposed inside the through hole 420b. At an inner wall 425b of the through hole 420b, the connecting member 450 is in contact with and connected to an inner side surface of the counter electrode current collector 121 of the battery cell 100b. The connecting member 450 is also in contact with and connected to the conductive member 42, thereby electrically connecting the conductive member 42 to the counter electrode layer 120 of the battery cell 100b. The connecting member 450 is not in contact with the respective electrode layers 110 of the battery cells 100. In the through hole 420b, a portion on an opposite side to the conductive member 42 side of the connecting member 450, that is to say, a portion on the principal surface 12 side of the connecting member 450 is hollow.

The connecting member 450 can be formed by using the same material as that of the connecting member 50. Alternatively, the connecting member 450 may be formed by causing an end portion on the principal surface 12 side of the conductive member 42 to spread toward the inner wall 425b of the through hole 420b. In other words, the connecting member 450 may be a portion of the conductive member 42.

As described above, in the battery 401, the conductive member 42 is formed inside the through hole 420b that penetrates the entire power generation element 5. Thus, it is possible to form the through hole 420b and the conductive member 42 easily.

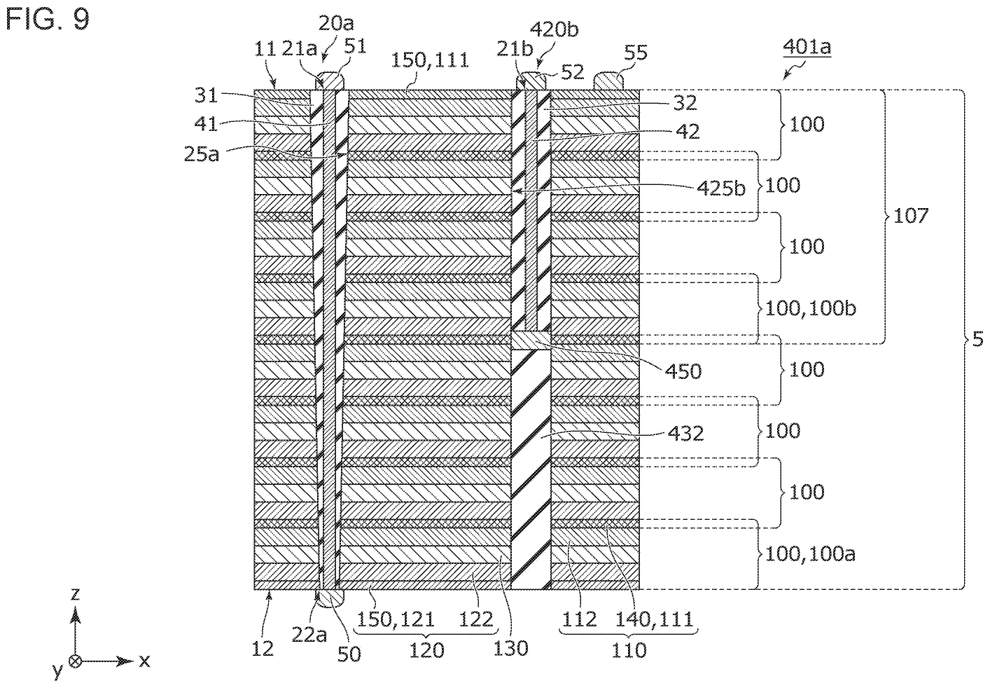

Although the principal surface 12 side of the connecting member 450 in the through hole 420b is hollow in the battery 401, the present disclosure is not limited to this configuration. FIG. 9 is a sectional view of a battery 401a according to another example of the present embodiment.

As illustrated in FIG. 9, in addition to the configuration of the battery 401, the battery 401a includes an insulating member 432 which is packed into the principal surface 12 side of the connecting member 450 in the through hole 420b. The insulating member 432 covers the inner wall 425b of the through hole 420b, and completely buries the principal surface 12 side of the connecting member 450 in the through hole 420b.

As described above, the inner side surfaces of the respective battery cells 100 on the inner wall 425b are protected by providing the insulating member 432 at positions inside the through hole 420b where none of the insulating member 32 and the conductive member 42 are provided. This configuration can improve reliability of the battery 401a.

### Embodiment 5

Next, a description will be given of Embodiment 5. The following description will be focused on different features from those of the Embodiments 1 to 4 while omitting or simplifying explanations of features in common.

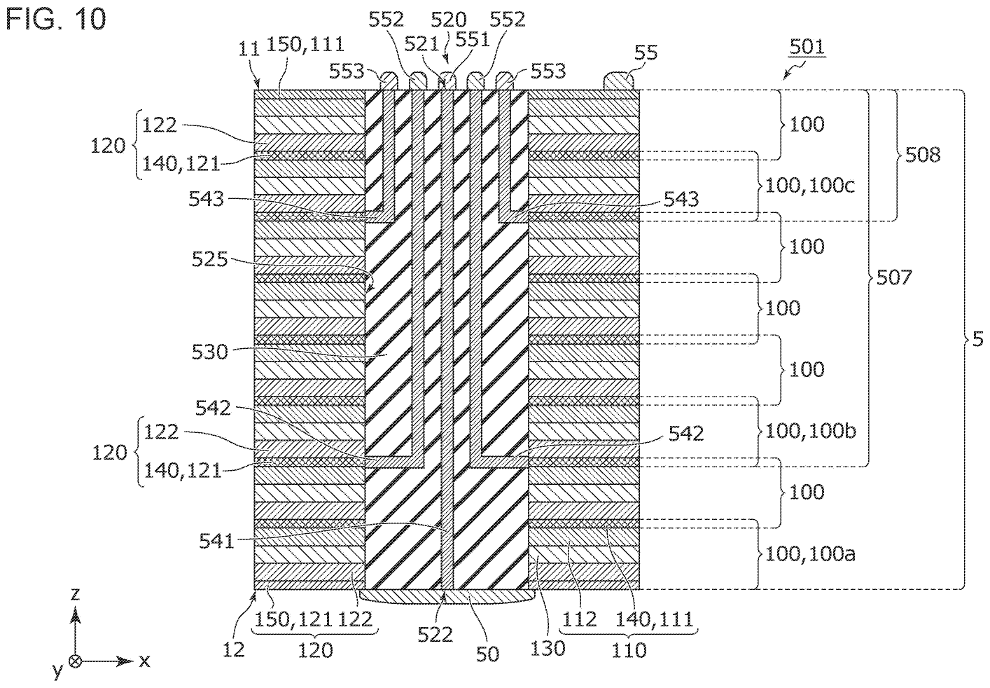

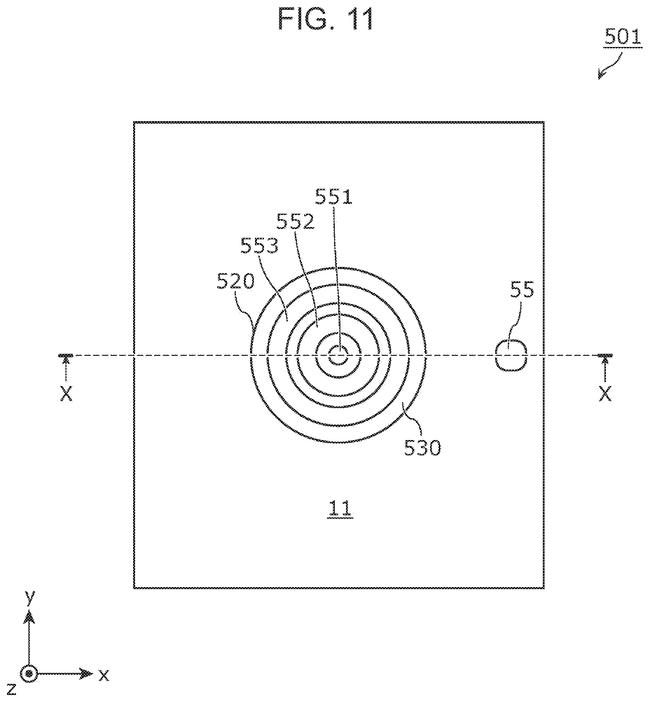

FIG. 10 is a sectional view of a battery 501 according to the present embodiment. FIG. 11 is a top plan view of the battery 501 according to the present embodiment. Here, FIG. 10 illustrates a section taken along the X-X line in FIG. 11. As illustrated in FIGS. 10 and 11, in comparison with the battery 1 according to the Embodiment 1, the battery 501 is different in that the power generation element 5 is provided with a single through hole 520 instead of providing the power generation element 5 with the two through holes of the through hole 20a and the through hole 20b. Moreover, in comparison with the battery 1 according to the Embodiment 1, the battery 501 is also different in that the battery 501 includes an insulating member 530, a conductive member 541, a conductive member 542, a conductive member 543, a current collecting terminal 551, a current collecting terminal 552, and a current collecting terminal 553 instead of the insulating member 31, the insulating member 32, the conductive member 41, the conductive member 42, the current collecting terminal 51, and the current collecting terminal 52.

The through hole 520 penetrates the entire power generation element 5, or in other words, from the principal surface 12 to the principal surface 11 in the direction of lamination. The through hole 520 is open on the principal surface 11 and the principal surface 12. To be more precise, the through hole 520 is open at an opening position 521 located on the principal surface 11 and at an opening position 522 located on the principal surface 12.

The through hole 520 has a columnar shape, for example, but may have any other shapes including a prism shape, a truncated cone shape, a truncated pyramid shape, and the like.

The insulating member 530 is disposed inside the through hole 520. The insulating member 530 is disposed between the conductive member 541 and an inner wall 525 of the through hole 520, between the conductive member 542 and the inner wall 525, as well as between the conductive member 543 and the inner wall 525. Thus, insulation among the respective conductive members can be secured. Moreover, the insulating member 530 is also disposed between the conductive member 541 and the conductive member 542 as well as between the conductive member 542 and the conductive member 543. Thus, insulation of each of the conductive member 541, the conductive member 542 and the conductive member 543 from the inner side surface of the power generation element 5 being the inner wall 525 of the through hole 520 can be ensured.

The insulating member 530 is packed in such a way as to fill the through hole 520 in conjunction with the conductive member 541, the conductive member 542, and the conductive member 543. The insulating member 530 completely buries a space in the through hole 520 except the conductive member 541, the conductive member 542, and the conductive member 543, for example.

The conductive member 541 is disposed inside the through hole 520. The conductive member 541 is an example of the first conductive member. The conductive member 541 is electrically connected to the principal surface 12 of the power generation element 5 while interposing the connecting member 50 therebetween. Accordingly, the conductive member 541 is electrically connected to the end portion layer current collector 150 of the counter electrode layer 120 of the lowermost battery cell 100a, namely, to the counter electrode current collector 121 without being connected to other battery cells 100.

The conductive member 541 originates from the opening position 522 of the through hole 520 at the principal surface 12, passes through the through hole 520, and extends to the opening position 521 of the through hole 520 located at the principal surface 11. The conductive member 541 passes through the through hole 520 and penetrates from the principal surface 11 to the principal surface 12 of the power generation element 5. Accordingly, the potential at the counter electrode layer 120 of the battery cell 100a located lowermost is induced to the principal surface 11 side so that the electric current can be extracted from the lowermost battery cell 100a on the principal surface 11 side of the power generation element 5.

An end portion on the principal surface 11 side of the conductive member 541 is in contact with the current collecting terminal 551. An end portion on the principal surface 12 side of the conductive member 541 is in contact with the connecting member 50.

The conductive member 541 is not in contact with the electrode active material layer 112, the solid electrolyte layer 130, the counter electrode active material layer 122, the intermediate layer current collector 140, and the end portion layer current collector 150 on the upper end on the inner wall 525 of the through hole 520.

In the present embodiment, the principal surface 11 is the first surface where the opening position 521 to which the potential at the battery cell 100a is induced by the conductive member 541 is disposed. A voltage between the principal surface 11 and the conductive member 541 corresponds to the number of the battery cells 100 involved in the serial connection between the principal surface 11 and the battery cell 100a. In the present embodiment, the voltage between the principal surface 11 and the conductive member 541 corresponds to the voltage obtained by the serial connection of all of the battery cells 100 of the power generation element 5.

A shape of the conductive member 541 is a columnar shape, for example, but may be any other shapes such as a prism shape.

The conductive member 542 is disposed inside the through hole 520. The conductive member 542 is an example of the second conductive member. The conductive member 542 is electrically connected to the counter electrode current collector 121 in the counter electrode layer 120 of the battery cell 100b that is different from the battery cell 100a without being connected to other battery cells 100.

The conductive member 542 originates from a position corresponding to the counter electrode current collector 121 of the battery cell 100b, passes through the through hole 520, and extends to the opening position 521 of the through hole 520 located at the principal surface 11. The conductive member 542 has a tubular shape provided with a flange to be connected to the counter electrode current collector 121 of the battery cell 100b, for example. The flange of the conductive member 542 spreads from an end portion on the principal surface 12 side of the tubular portion of the conductive member 542, which extends in the direction of lamination, toward the inner wall 525 and is in contact with the counter electrode current collector 121 of the battery cell 100b. Accordingly, the potential at the counter electrode layer 120 of the battery cell 100b among the battery cells 100, which is different from the battery cell 100a, is induced to the principal surface 11 side so that the electric current from the battery cell 100b can be extracted on the principal surface 11 side of the power generation element 5. Meanwhile, the conductive member 541 passes through the tubular conductive member 542.

An end portion on the principal surface 11 side of the conductive member 542 is in contact with the current collecting terminal 552. An end portion on the principal surface 12 side of the conductive member 542 is in contact with the counter electrode current collector 121 of the battery cell 100b.

The insulating member 530 is disposed between the conductive member 542 and the inner wall 525. The conductive member 542 is not in contact with the electrode active material layer 112, the solid electrolyte layer 130, the counter electrode active material layer 122, the intermediate layer current collector 140, and the end portion layer current collector 150 on the inner wall 525 of the through hole 520.

In the present embodiment, the principal surface 11 is the second surface where the opening position 521 to which the potential at the battery cell 100b is induced by the conductive member 542 is disposed. A voltage between the principal surface 11 and the conductive member 542 corresponds to the number of the battery cells 100 involved in the serial connection between the principal surface 11 and the battery cell 100b. The battery cells 100 involved in the connection between the principal surface 11 and the conductive member 542 constitute a cell laminated body 507 being serially connected and laminated. Accordingly, the voltage between the principal surface 11 and the conductive member 542 corresponds to a voltage obtained by serially connecting all of the battery cells 100 in the cell laminated body 507.

The conductive member 543 is disposed inside the through hole 520. The conductive member 543 is electrically connected to the counter electrode current collector 121 in the counter electrode layer 120 of a battery cell 100c that is different from the battery cell 100a and the battery cell 100b without being connected to other battery cells 100. The battery cell 100c is the intermediate battery cell 100 in the power generation element 5 which is located above the battery cell 100b.

The conductive member 543 originates from a position corresponding to the counter electrode current collector 121 of the battery cell 100c, passes through the through hole 520, and extends to the opening position 521 of the through hole 520 located at the principal surface 11. The conductive member 543 has a tubular shape provided with a flange to be connected to the counter electrode current collector 121 of the battery cell 100c, for example. The flange of the conductive member 543 spreads from an end portion on the principal surface 12 side of the tubular portion of the conductive member 543, which extends in the direction of lamination, toward the inner wall 525 and is in contact with the counter electrode current collector 121 of the battery cell 100c. Accordingly, the potential at the counter electrode layer 120 of the battery cell 100c among the battery cells 100, which is different from the battery cell 100a and the battery cell 100b, is induced to the principal surface 11 side so that the electric current from the battery cell 100c can be extracted on the principal surface 11 side of the power generation element 5. Meanwhile, the conductive member 541 and the conductive member 542 pass through the tubular conductive member 543.

An end portion on the principal surface 11 side of the conductive member 543 is in contact with the current collecting terminal 553. An end portion on the principal surface 12 side of the conductive member 543 is in contact with the counter electrode current collector 121 of the battery cell 100c.

The insulating member 530 is disposed between the conductive member 543 and the inner wall 525. The conductive member 543 is not in contact with the electrode active material layer 112, the solid electrolyte layer 130, the counter electrode active material layer 122, the intermediate layer current collector 140, and the end portion layer current collector 150 on the inner wall 525 of the through hole 520.

A potential at the battery cell 100c is induced by the conductive member 543 to the opening position 521 disposed at the principal surface 11. A voltage between the principal surface 11 and the conductive member 543 corresponds to the number of the battery cells 100 involved in the serial connection between the principal surface 11 and the battery cell 100c. The battery cells 100 involved in the connection between the principal surface 11 and the conductive member 543 constitute a cell laminated body 508 being serially connected and laminated. Accordingly, the voltage between the principal surface 11 and the conductive member 543 corresponds to a voltage obtained by serially connecting all of the battery cells 100 in the cell laminated body 508.

In the present embodiment, the number of the battery cells 100 involved in the serial connection between the principal surface 11 and the battery cell 100a, the number of the battery cells 100 involved in the serial connection between the principal surface 11 and the battery cell 100b, and the number of the battery cells 100 involved in the serial connection between the principal surface 11 and the battery cell 100c are different from one another. For this reason, the battery 501 can supply three types of voltages having different magnitudes on the principal surface 11 side.

Moreover, in the battery 501, the conductive member 541, the conductive member 542, and the conductive member 543 are disposed in the same through hole 520. Thus, it is possible to consolidate positions to extract the currents from the battery cell 100a, the battery cell 100b, and the battery cell 100c.

Meanwhile, the conductive member 541, the conductive member 542, and the conductive member 543 can also be used for measuring intermediate voltages of the power generation element 5 in which the battery cells 100 are laminated instead of supplying multiple types of the voltages. In this way, the battery 501 can be used while monitoring the voltages at the intermediate battery cells 100, thereby suppressing the occurrence of overcharge or overdischarge of a certain battery cell 100 and improving reliability of the battery 501.

The current collecting terminal 551 is disposed on the principal surface 11 side of the power generation element 5. The current collecting terminal 551 is connected to the conductive member 541 at the opening position 521. Thus, the current collecting terminal 551 is electrically connected to the counter electrode layer 120 of the battery cell 100a located lowermost while interposing the conductive member 541 and the connecting member 50 therebetween. The current collecting terminal 551 is one of the external connection terminals of the battery 1, which is a negative extraction terminal in the present embodiment.

The current collecting terminal 552 is disposed on the principal surface 11 side of the power generation element 5. The current collecting terminal 552 is connected to the conductive member 542 at the opening position 521. Thus, the current collecting terminal 552 is electrically connected to the counter electrode layer 120 of the battery cell 100b while interposing the conductive member 542 therebetween. The current collecting terminal 552 is one of the external connection terminals of the battery 1, which is a negative extraction terminal in the present embodiment.

The current collecting terminal 553 is disposed on the principal surface 11 side of the power generation element 5. The current collecting terminal 553 is connected to the conductive member 543 at the opening position 521. Thus, the current collecting terminal 553 is electrically connected to the counter electrode layer 120 of the battery cell 100c while interposing the conductive member 543 therebetween. The current collecting terminal 553 is one of the external connection terminals of the battery 1, which is a negative extraction terminal in the present embodiment.

As illustrated in FIG. 11, each of the current collecting terminal 551, the current collecting terminal 552, and the current collecting terminal 553 is disposed inside the through hole 520 in plan view and is not in contact with the principal surface 11.

Moreover, the current collecting terminal 551 is disposed at a central part of the through hole 520 in plan view. Meanwhile, the current collecting terminal 552 is of an annular shape and disposed in such a way as to surround the current collecting terminal 551 in plan view. In the meantime, the current collecting terminal 553 is of an annular shape and disposed in such a way as to surround the current collecting terminal 552 in plan view. The current collecting terminal 552 and the current collecting terminal 553 concentrically spread around the current collecting terminal 551 in plan view. The above-described consolidation of the current collecting terminal 551, the current collecting terminal 552, and the current collecting terminal 553 on the through hole 520 makes it possible to establish terminal connection easily by using a connecting component in a socket shape. Moreover, since the shapes in plan view of the current collecting terminal 551, the current collecting terminal 552, and the current collecting terminal 553 are different from one another, it is easy to distinguish the external terminals to be connected.

Note that the shapes and the layout of the current collecting terminal 551, the current collecting terminal 552, and the current collecting terminal 553 in plan view are not limited. These terminals only need to be disposed in such a way to secure insulation from the principal surface 11 and insulation among the respective current collecting terminals.

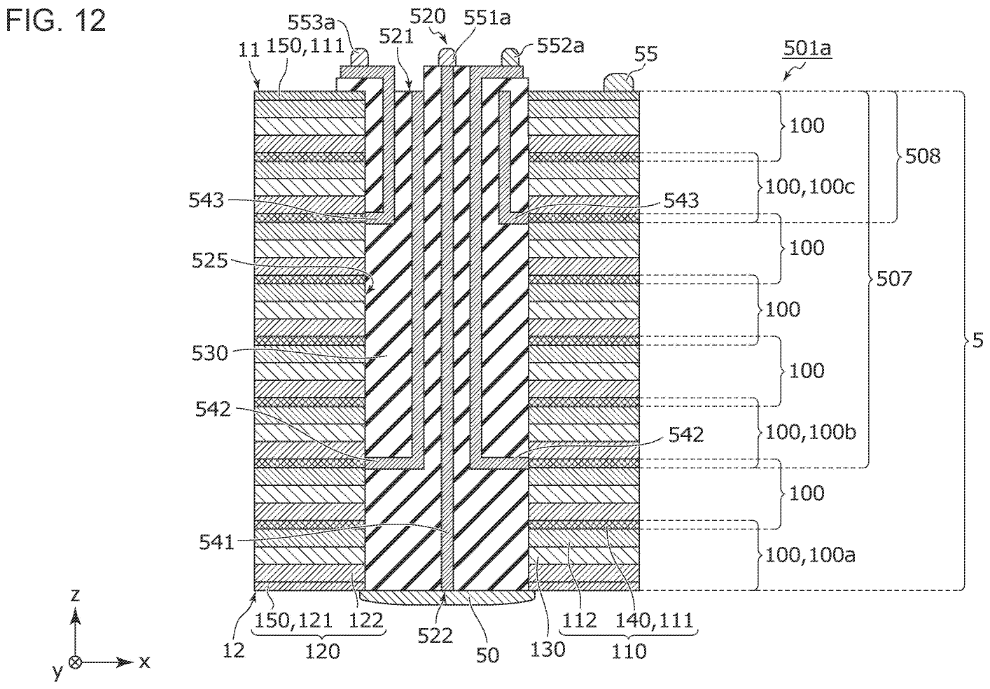

In the meantime, the shape in plan view of each of the current collecting terminal 552 and the current collecting terminal 553 does not always have to be the annular shape. For example, the current collecting terminal 551, the current collecting terminal 552, and the current collecting terminal 553 may be projecting terminals like the current collecting terminal 51 and the current collecting terminal 52 according to the Embodiment 1, and may be arranged in the x-axis direction. FIG. 12 is a sectional view of a battery 501a according to another example of the present embodiment. As illustrated in FIG. 12, in the battery 501a, the insulating member 530, the conductive member 541, the conductive member 542, and the conductive member 543 are extended above the principal surface 11. Meanwhile, the conductive member 541, the conductive member 542, and the conductive member 543 are connected to a current collecting terminal 551a, a current collecting terminal 552a, and a current collecting terminal 553a above the principal surface 11, respectively. Each of the current collecting terminal 551a, the current collecting terminal 552a, and the current collecting terminal 553a is a projecting terminal as with the current collecting terminal 51 and the current collecting terminal 52 according to the Embodiment 1 without being provided with a hollow portion, for example. Thus, the battery 501a being excellent in mountability onto a board and the like can be realized as with the battery 1.

### Embodiment 6

Next, a description will be given of Embodiment 6. The following description will be focused on different features from those of the Embodiments 1 to 5 while omitting or simplifying explanations of features in common.

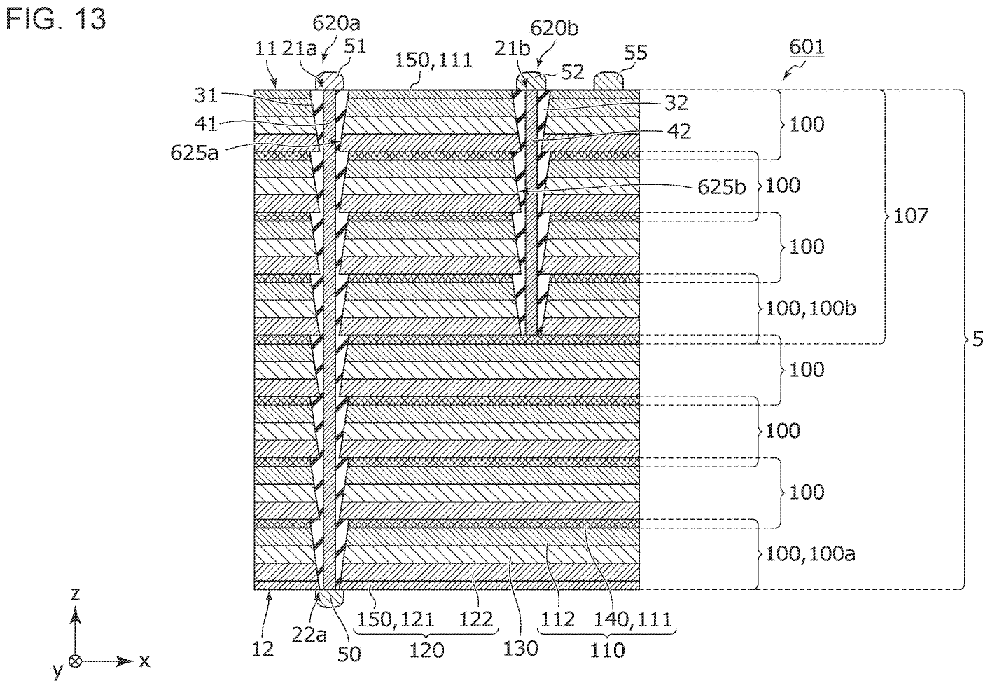

FIG. 13 is a sectional view of a battery 601 according to the present embodiment. As illustrated in FIG. 13, in comparison with the battery 1 according to the Embodiment 1, the battery 601 is different in that the power generation element 5 is provided with a through hole 620a and a through hole 620b instead of the through hole 20a and the through hole 20b.

The through hole 620a and the through hole 620b have the same characteristics as those of the through hole 20a and the through hole 20b, respectively, except that shapes of an inner wall 625a and an inner wall 625b are different. The through hole 620a is an example of the first through hole. The through hole 620b is an example of the second through hole. The through hole 620a and the through hole 620b are not connected to each other and are independent of each other.

The inner wall 625a of the through hole 620a has a zigzag shape instead of the shape formed by the single continuous surface being inclined with respect to the direction of lamination and extending from the principal surface 11 to the principal surface 12 as in the case of the inner wall 25a.

In each of battery cells 100 that the through hole 620a passes through, a sectional area of the through hole 620a in the direction perpendicular to the direction of lamination at the electrode layer 110 is larger than a sectional area of the through hole 620a in the direction perpendicular to the direction of lamination at the counter electrode layer 120. In each of battery cells 100 that the through hole 620b passes through, a sectional area of the through hole 620b in the direction perpendicular to the direction of lamination at the electrode layer 110 is larger than a sectional area of the through hole 620b in the direction perpendicular to the direction of lamination at the counter electrode layer 120. Accordingly, the same effects as those of the through hole 20a and the through hole 20b described above are available.

Meanwhile, a volume and a shape of the through hole 620a are substantially equal among the respective battery cells 100 that the through hole 620a passes through. Sectional areas of the through hole 620a in the direction perpendicular to the direction of lamination at the electrode layers 110 of the respective battery cells 100 that the through hole 620a passes through are substantially equal. In the meantime, sectional areas of the through hole 620a in the direction perpendicular to the direction of lamination at the counter electrode layers 120 of the respective battery cells 100 that the through hole 620a passes through are substantially equal. In the respective battery cells 100 that the through hole 620a passes through, the volumes occupied by the through hole 620a are equal. Accordingly, the volumes of the respective battery cells 100 that the through hole 620a passes through are likely to conform with one another, so that a variation in volume among the respective battery cells 100 that the through hole 620a passes through can be suppressed. For this reason, in charging or discharging of the battery 601, it is easier to equalize operating voltages for the battery cells 100 that are laminated while being connected in series, and the occurrence of overcharge or overdischarge of a certain battery cell 100 is suppressed. Thus, reliability of the battery 601 is improved. Particularly, in the case of a battery having a small size and a small area, the volume of the through hole 620a has a large impact. Accordingly, it is effective to equalize the volumes occupied by the through hole 620a in the respective battery cells 100 that the through hole 620a passes through. In the meantime, as with the through hole 620a, volume and shapes of the through hole 620b are substantially equal among the respective battery cells 100 that the through hole 620b passes through.

The shape of the through hole 620a in each of the battery cells 100 that the through hole 620a passes through and the shape of the through hole 620b in each of the battery cells 100 that the through hole 620b passes through are each a truncated cone shape, for example, but may be any other shapes such as a truncated pyramid shape. The shape of each of the through hole 620a and the through hole 620b is a shape obtained by continuously arranging the truncated cone shapes in the respective battery cells 100 in the direction of lamination, for example.

In the battery 601 as well, the insulating member 31 and the conductive member 41 are provided in the through hole 620a while the insulating member 32 and the conductive member 42 are provided in the through hole 620b as with the battery 1. Thus, it is possible to induce the potentials at the respective counter electrode layers 120 of the battery cell 100a and the battery cell 100b to the principal surface 11 side.

According to the above-described battery 601, it is possible to supply the voltages corresponding to the multiple combinations of the battery cells 100 from the single battery 601 by providing the conductive member 41 and the conductive member 42 in the through hole 620a and the through hole 620b, thereby enhancing the capacity density and usability as with the battery 1 according to the Embodiment 1.

### Embodiment 7

Next, a description will be given of Embodiment 7. The following description will be focused on different features from those of the Embodiments 1 to 6 while omitting or simplifying explanations of features in common.

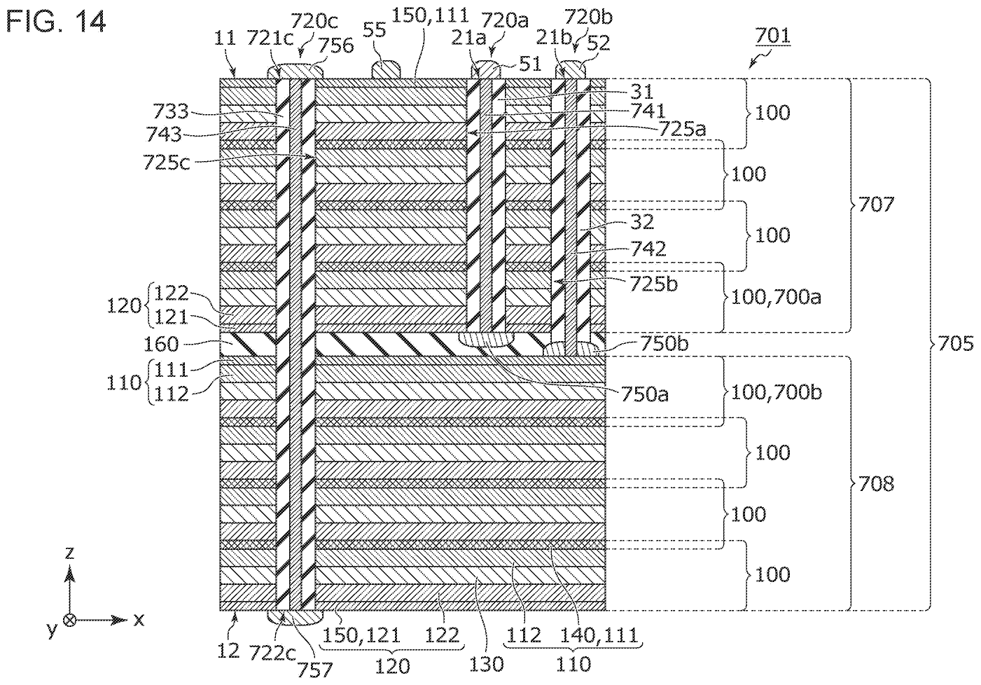

FIG. 14 is a sectional view of a battery 701 according to the present embodiment. As illustrated in FIG. 14, in comparison with the battery 1 according to the Embodiment 1, the battery 701 is mainly different in that the battery 701 includes a power generation element 705 instead of the power generation element 5, and that the battery cells 100 included in the power generation element 705 constitute two cell laminated bodies of a cell laminated body 707 and a cell laminated body 708. In the battery 701, electric potentials of the battery cells 100 included in the cell laminated body 707 and the cell laminated body 708, respectively, are guided to the principal surface 11 side of the power generation element 705 by conductive members.

The battery 701 includes the power generation element 705, the insulating member 31, the insulating member 32, an insulating member 733, a conductive member 741, a conductive member 742, a conductive member 743, a connecting member 750a, a connecting member 750b, a connecting member 756, a connecting member 757, the current collecting terminal 51, the current collecting terminal 52, and the current collecting terminal 55.

The power generation element 705 includes the battery cells 100 and an insulating layer 160. In the power generation element 705, a portion of the battery cells 100 constitute the cell laminated body 707 while another portion of the battery cells 100 constitute the cell laminated body 708. The battery cells 100 constituting the cell laminated body 707 and the battery cells 100 constituting the cell laminated body 708 do not overlap one another. It is also possible to say that the power generation element 705 includes the cell laminated body 707 and the cell laminated body 708. The cell laminated body 707 is an example of a first cell laminated body. The cell laminated body 708 is an example of a second cell laminated body. In the example illustrated in FIG. 14, the cell laminated body 707 and the cell laminated body 708 each include multiple, namely, four battery cells 100. In other words, the number of the battery cells 100 included in the cell laminated body 707 is equal to the number of the battery cells 100 included in the cell laminated body 708. Here, each of the number of the cell laminated body in included in the power generation element 705, the number of the battery cells 100 included in the cell laminated body 707, and the number of the battery cells 100 included in the cell laminated body 708 is not limited to a particular number. In the meantime, the number of the battery cells 100 included in the cell laminated body 707 may be different from the number of the battery cells 100 included in the cell laminated body 708.

The battery cells 100 included in each of the cell laminated body 707 and the cell laminated body 708 are electrically connected in series. Here, at least a portion of the battery cells 100 included in each of the cell laminated body 707 and the cell laminated body 708 may be electrically connected in parallel.

The battery cells 100 in the cell laminated body 707 and the battery cells 100 in the cell laminated body 708 are disposed in such a way that the orders of arrangement of the respective layers constituting these battery cells 100 are the same.

The cell laminated body 707 is disposed on the principal surface 11 side of the cell laminated body 708. Meanwhile, the cell laminated body 707 is laminated on the cell laminated body 708 while interposing the insulating layer 160 therebetween. The cell laminated body 707 is not electrically connected to the cell laminated body 708.

In the present embodiment, the principal surface 11 constitutes a portion of the cell laminated body 707 located on the upper side. To be more precise, the principal surface 11 is a principal surface on the upper side of the cell laminated body 707. On the other hand, the principal surface 12 constitutes a portion of the cell laminated body 708 located on the lower side. To be more precise, the principal surface 12 is a principal surface on the lower side of the cell laminated body 708.

The insulating layer 160 is disposed between the cell laminated body 707 and the cell laminated body 708. The insulating layer 160 is formed from an insulating material and insulates the cell laminated body 707 from the cell laminated body 708. The insulating layer 160 is also disposed between the connecting member 750a and the connecting member 750b.

The power generation element 705 is provided with a through hole 720a, a through hole 720b, and a through hole 720c. The through hole 720a penetrates the cell laminated body 707 in the direction of lamination. The through hole 720b penetrates the cell laminated body 707 and the insulating layer 160 in the direction of lamination. The through hole 720c penetrates the entire power generation element 705 in the direction of lamination. The through hole 720a is an example of the first through hole. The through hole 720b is an example of the second through hole. The through hole 720a, the through hole 720b, and the through hole 720c are not connected to one another and are independent of one another.

The through hole 720a is open on the principal surface 11. To be more precise, the through hole 720a is open at the opening position 21a located on the principal surface 11.

The through hole 720a extends from a battery cell 700a, which is located lowermost among the battery cells 100 included in the cell laminated body 707, to the principal surface 11. The through hole 720a penetrates from a principal surface on the lower side of the cell laminated body 707 to the principal surface on the upper side of the cell laminated body 707 being the principal surface 11. The battery cell 700a is an example of the first battery cell. Here, the through hole 720a does not always have to penetrate the entire cell laminated body 707. The through hole 720a may penetrate from a portion of the counter electrode layer 120 of the battery cell 700a to the principal surface 11, for example.

The through hole 720b is open on the principal surface 11. To be more precise, the through hole 720b is open at the opening position 21b located on the principal surface 11.

The through hole 720b extends from the insulating layer 160 to the principal surface 11. The through hole 720b penetrates from a principal surface on the upper side of a battery cell 700b, which is located uppermost among the battery cells 100 included in the cell laminated body 708, to the principal surface 11. The battery cell 700b is an example of the second battery cell.

The through hole 720c is open on the principal surface 11 and the principal surface 12. To be more precise, the through hole 720c is open at an opening position 721c located on the principal surface 11 and at an opening position 722c located on the principal surface 12.

An inner wall 725a of the through hole 720a, an inner wall 725b of the through hole 720b, and an inner wall 725c of the through hole 720c are parallel to the direction of lamination. Accordingly, the volume and the shape of the through hole 720a can easily be equalized among the respective battery cells 100 that the through hole 720a passes through. The same effect can be obtained from the inner wall 725b of the through hole 720b and the inner wall 725c of the through hole 720c.

Each of the through hole 720a, the through hole 720b, and the through hole 720c has a columnar shape, for example, but may have any other shapes including a prism shape, a truncated cone shape, a truncated pyramid shape, and the like.

In the battery 701 as well, the insulating member 31 is disposed between the conductive member 741 and the inner wall 725a of the through hole 720a, so that insulation can be secured between the conductive member 741 and an inner side surface of the power generation element 705 which is the inner wall 725a of the through hole 720a as with the battery 1. Likewise, the insulating member 32 is disposed between the conductive member 742 and the inner wall 725b of the through hole 720b, so that insulation can be secured between the conductive member 742 and an inner side surface of the power generation element 705 which is the inner wall 725b of the through hole 720b.

The insulating member 733 is disposed inside the through hole 720c. The insulating member 733 is located between the conductive member 743 and the inner wall 725c of the through hole 720c. The insulating member 733 can secure insulation between the conductive member 743 and the inner side surface of the power generation element 705 which is the inner wall 725c of the through hole 720c.

The insulating member 733 is disposed along the inner wall 725c of the through hole 720c. The insulating member 733 covers the inner wall 725c of the through hole 720c in a lump and is in contact with the inner wall 725c of the through hole 720c. This makes it possible to suppress collapse of the materials of the respective layers of the battery cell 100 on the inner wall 725c of the through hole 720c and to suppress a short circuit between the electrode layer 110 and the counter electrode layer 120. The insulating member 733 covers the entire inner wall 725c of the through hole 720c, for example. A clearance may be provided at a certain part between the insulating member 733 and the inner wall 725c.

The insulating member 733 surrounds an outer periphery of the conductive member 743 when viewed in the direction of lamination and is in contact with the conductive member 743. In the present embodiment, the conductive member 743 has a columnar shape, and the insulating member 733 covers the entire side surface of the columnar conductive member 743 and is in contact with the side surface of the conductive member 743. A clearance may be provided at a certain part between the insulating member 733 and the conductive member 743.

The insulating member 733 and the conductive member 743 are packed together so as to bury the through hole 720c. The insulating member 733 completely buries a space between the inner wall 725c of the through hole 720c and the conductive member 743, for example. Accordingly, a shape of the insulating member 733 is the same as the shape of the through hole 720c except that a through hole to be penetrated by the conductive member 743 is formed at the center when viewed in the direction of lamination. In the present embodiment, the shape of the insulating member 733 is a tubular shape having a circular or polygonal circumference, for example. To be more precise, the shape of the insulating member 733 is an elongate columnar shape provided with the through hole to be penetrated by the conductive member 743 at the center when viewed in the direction of lamination. Note that the shape of the insulating member 733 is not limited to the aforementioned shape. The insulating member 733 is formed in conformity to the shapes of the through hole 720c and the conductive member 743, for example.

The conductive member 741 is disposed inside the through hole 720a. The conductive member 741 is an example of the first conductive member. The conductive member 741 is electrically connected to a principal surface on the lower side of the cell laminated body 707 while interposing the connecting member 750a therebetween. For this reason, the conductive member 741 is electrically connected to the counter electrode current collector 121 in the counter electrode layer 120 of the lowermost battery cell 700a without being connected to other battery cells 100.

The conductive member 741 extends from a principal surface on the lower side of the counter electrode current collector 121 of the battery cell 700a to the opening position 21a of the through hole 720a located at the principal surface 11 while passing through the through hole 720a. The conductive member 741 penetrates from the principal surface 11 to the principal surface on the lower side of the counter electrode current collector 121 of the battery cell 700a while passing through the through hole 720a. Accordingly, a potential at the counter electrode layer 120 of the battery cell 700a located lowermost of the cell laminated body 707 is induced to the principal surface 11 side so that an electric current can be extracted from the lowermost battery cell 700a on the principal surface 11 side of the power generation element 705.

An end portion on the principal surface 11 side of the conductive member 741 is in contact with the current collecting terminal 51. An end portion on the principal surface 12 side of the conductive member 741 is in contact with the connecting member 750a.

The conductive member 742 is disposed inside the through hole 720b. The conductive member 742 is an example of the second conductive member. The conductive member 742 is electrically connected to the electrode current collector 111 in the electrode layer 110 of the battery cell 700b without being connected to other battery cells 100.

The conductive member 742 extends from a principal surface on the upper side of the electrode current collector 111 of the battery cell 700b to the opening position 21b of the through hole 720b located at the principal surface 11 while passing through the through hole 720b. The conductive member 742 penetrates from the principal surface 11 to the principal surface on the upper side of the electrode current collector 111 of the battery cell 700b while passing through the through hole 720b. Accordingly, a potential at the electrode layer 110 of the battery cell 700b included in the cell laminated body 708, which is different from the cell laminated body 707 including the battery cell 700a among the battery cells 100, to the principal surface 11 side so that an electric current can be extracted from the battery cell 700b on the principal surface 11 side of the power generation element 705.

An end portion on the principal surface 11 side of the conductive member 742 is in contact with the current collecting terminal 52. An end portion on the principal surface 12 side of the conductive member 742 is in contact with the electrode current collector 111 of the battery cell 700b and with the connecting member 750b.

The conductive member 743 is disposed inside the through hole 720c. The conductive member 743 is an example of a third conductive member. The conductive member 743 extends from the opening position 722c of the through hole 720c at the principal surface 12 to the opening position 721c of the through hole 720c located at the principal surface 11 through the through hole 720c. The conductive member 743 penetrates from the principal surface 11 of the principal surface 12 of the power generation element 705 while passing through the through hole 720c.

The conductive member 743 is electrically connected to the principal surface 11 of the power generation element 705 while interposing the connecting member 756 therebetween. Moreover, the conductive member 743 is electrically connected to the principal surface 12 of the power generation element 705 while interposing the connecting member 757 therebetween. Thus, the principal surface 11 and the principal surface 12 of the power generation element 705 are electrically connected to each other whereby the principal surface 11 and the principal surface 12 are set to the same potential. The end portion layer current collector 150 being the uppermost layer of the power generation element 705 is connected to the end portion layer current collector 150 being the lowermost layer thereof at the same potential by using the conductive member 743. In this way, the principal surface 12 located at the cell laminated body 708 is connected to the principal surface 11 whereby a potential difference attributable to the battery cells 100 included in the cell laminated body 708 occurs between the conductive member 742 and the principal surface 11. That is to say, the electric power from the battery cells 100 of the cell laminated body 708 can be supplied on the principal surface 11 side. Here, the conductive member 743 may electrically connect the principal surface 11 to the principal surface 12 while passing through the outside of the power generation element 705 instead of passing through the through hole 720c.

Each of the conductive member 741, the conductive member 742, and the conductive member 743 has a columnar shape, for example, but may have any other shapes including a prism shape, a truncated cone shape, a truncated pyramid shape, and the like. A diameter of each of the conductive member 741, the conductive member 742, and the conductive member 743 is constant, for example.

Each of the conductive member 741, the conductive member 742, and the conductive member 743 can be formed by using the same material as that of the conductive member 41 and the conductive member 42.

In the present embodiment, the principal surface 11 is the first surface where the opening position 21a to which the potential at the battery cell 700a is induced by the conductive member 741 is disposed. The principal surface 11 is the principal surface on the upper side of the battery cell 100 located uppermost in the cell laminated body 707. Accordingly, the battery cells 100 laminated from the battery cell 700a in the cell laminated body 707 to the uppermost battery cell 100 are the battery cells 100 involved in the connection between the principal surface 11 and the battery cell 700a. A voltage between the principal surface 11 and the conductive member 741 corresponds to the number of the battery cells 100 involved in the serial connection between the principal surface 11 and the battery cell 700a. In the present embodiment, the voltage between the principal surface 11 and the conductive member 741 corresponds to a voltage obtained by the serial connection of all of the battery cells 100 of the cell laminated body 707.

Meanwhile, in the present embodiment, the principal surface 11 is the second surface where the opening position 21b to which the potential at the battery cell 700b is induced by the conductive member 742 is disposed. The principal surface 11 is electrically connected to the principal surface 12 by using the conductive member 743. The principal surface 12 is the principal surface on the lower side of the battery cell 100 located lowermost in the cell laminated body 708. Accordingly, the battery cells 100 laminated from the lowermost battery cell in the cell laminated body 708 to the battery cell 700b are the battery cells 100 involved in the connection between the principal surface 12 and the battery cell 700b, or in other words, the connection between the principal surface 11 and the battery cell 700b. A voltage between the principal surface 11 and the conductive member 742 corresponds to the number of the battery cells 100 involved in the serial connection between the principal surface 11 and the battery cell 700b. In the present embodiment, the voltage between the principal surface 11 and the conductive member 742 corresponds to a voltage obtained by the serial connection of all of the battery cells 100 of the cell laminated body 708.

In the battery 701, the number of the battery cells 100 included in the cell laminated body 707 is equal to the number of the battery cells 100 included in the cell laminated body 708. Accordingly, the voltage between the principal surface 11 and the conductive member 741 and the voltage between the principal surface 11 and the conductive member 742 have the same absolute value.

Meanwhile, the conductive member 741 is electrically connected to the counter electrode layer 120 (which is the negative electrode layer in the present embodiment) of the battery cell 700a. Accordingly, the voltage at the conductive member 741 based on the principal surface 11 is a negative voltage. On the other hand, the conductive member 742 is electrically connected to the electrode layer 110 (which is the positive electrode layer in the present embodiment) of the battery cell 700b. Accordingly, the voltage at the conductive member 742 based on the principal surface 11 is a positive voltage. As described above, the battery 701 can supply both the positive voltage and the negative voltage in the case of being based on the principal surface 11 by using the conductive member 741 and the conductive member 742. For example, it is possible to form a low-noise circuit by forming a circuit pattern above the principal surface 11 by using the positive voltage and the negative voltage while employing the end portion layer current collector 150 on the uppermost layer as a shield layer at a potential equal to 0 V.

The battery cells 100 involved in the connection between the principal surface 11 and the battery cell 700a and the battery cells 100 involved in the connection between the principal surface 11 and the battery cell 700b do not overlap one another. For this reason, it is more likely that the electric power of the respective battery cells 100 in the battery 701 is evenly consumed.

The connecting member 750a is disposed on the lower side of the cell laminated body 707. The connecting member 750a is buried in the insulating layer 160. The connecting member 750a is connected to the conductive member 741 at a lower end portion of the conductive member 741. The connecting member 750a covers the principal surface on the lower side of the battery cell 700a and is connected to the counter electrode current collector 121 of the battery cell 700a. The connecting member 750a electrically connects the conductive member 741 to the counter electrode layer 120 of the battery cell 700a. Here, the connecting member 750a may be a portion of the conductive member 741.

The connecting member 750b is disposed on the upper side of the cell laminated body 708. The connecting member 750b is buried in the insulating layer 160. The connecting member 750b is connected to the conductive member 742 at a lower end portion of the conductive member 742. The connecting member 750b covers the principal surface on the upper side of the battery cell 700b and is connected to the electrode current collector 111 of the battery cell 700b. The connecting member 750b electrically connects the conductive member 742 to the electrode layer 110 of the battery cell 700b. Here, the connecting member 750b may be a portion of the conductive member 742. Meanwhile, the battery 701 does not always have to include the connecting member 750b.

The connecting member 756 is disposed on the principal surface 11 side of the power generation element 705. The connecting member 756 is connected to the conductive member 743 at the opening position 721c. The connecting member 756 covers the principal surface 11 in the vicinity of the opening position 721c and is connected to the principal surface 11 as well. The connecting member 756 electrically connects the conductive member 743 to the principal surface 11. Here, the connecting member 756 may be a portion of the conductive member 743.

The connecting member 757 is disposed on the principal surface 12 side of the power generation element 705. The connecting member 757 is connected to the conductive member 743 at the opening position 722c. The connecting member 757 covers the principal surface 12 in the vicinity of the opening position 722c and is connected to the principal surface 12 as well. The connecting member 757 electrically connects the conductive member 743 to the principal surface 12. Here, the connecting member 757 may be a portion of the conductive member 743.

Each of the connecting member 750a, the connecting member 750b, the connecting member 756, and the connecting member 757 can be formed by using the same material as that of the connecting member 50, for example.

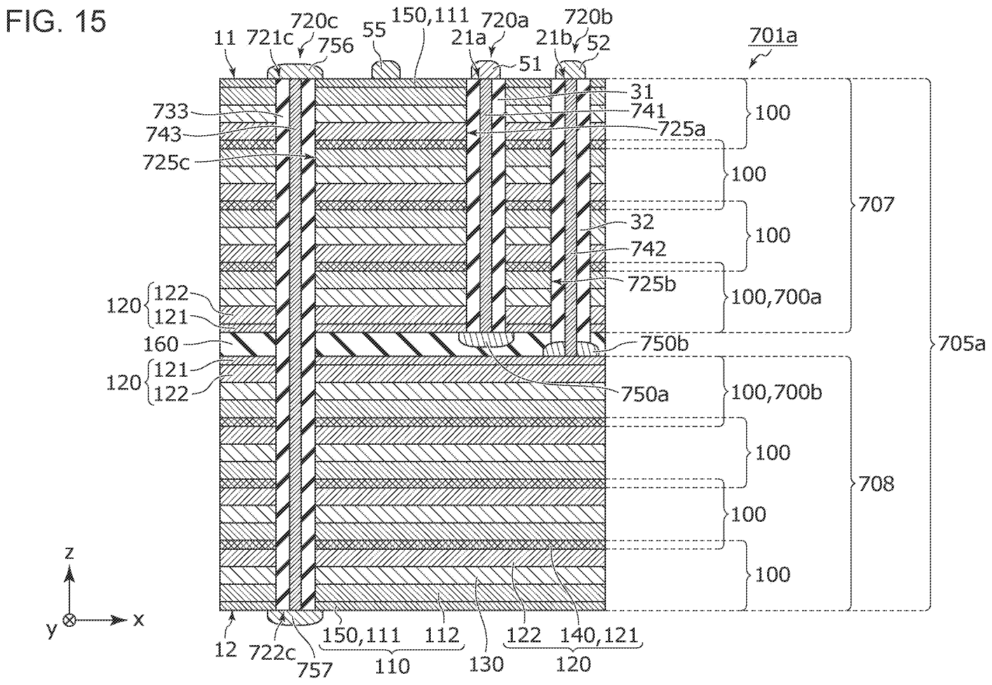

In the power generation element 705, the battery cells 100 in the cell laminated body 707 and the battery cells 100 in the cell laminated body 708 are disposed in such a way that the orders of arrangement of the respective layers constituting these battery cells 100 are the same. However, the present disclosure is not limited to this configuration. For example, as in a power generation element 705a illustrated in FIG. 15, the battery cells 100 in the cell laminated body 707 and the battery cells 100 in the cell laminated body 708 may have the orders of arrangement of the respective layers constituting these battery cells 100 which are reverse to each other. FIG. 15 is a sectional view of a battery 701a according to another example of the present embodiment.

As illustrated in FIG. 15, the battery 701a includes the power generation element 705a instead of the power generation element 705 of the battery 701.

In the power generation element 705a, the order of arrangement of the respective layers constituting the battery cells 100 in the cell laminated body 707 is reverse to the order of arrangement of the respective layers constituting the battery cells 100 in the cell laminated body 708. Specifically, in the cell laminated body 707, the electrode layer 110 is disposed above the counter electrode layer 120 in each battery cell 100. Meanwhile, in the cell laminated body 708, the counter electrode layer 120 is disposed above the electrode layer 110 in each battery cell 100. Accordingly, in the battery 701a, the conductive member 742 is connected to the principal surface on the upper side of the counter electrode current collector 121 of the battery cell 700b. In this case, the conductive member 742 is electrically connected to the counter electrode layer 120 (which is the negative electrode layer in the present embodiment) of the battery cell 700b, and the voltage at the conductive member 742 based on the principal surface 11 is therefore the negative voltage. As described above, the battery 701a can supply the voltages of the same polarity in the case of being based on the principal surface 11 by using the conductive member 741 and the conductive member 742. Thus, the polarity of the voltage at the conductive member 742 based on the principal surface 11 can be changed by altering the order of arrangement of the respective layers constituting the battery cells 100 in the cell laminated body 708.

Meanwhile, the number of the battery cells 100 involved in the serial connection between the principal surface 11 and the battery cell 700a is equal to the number of the battery cells 100 involved in the serial connection between the principal surface 12 and the battery cell 700b. In other words, each of the cell laminated body 707 and the cell laminated body 708 in which the battery cells 100 are laminated while being connected in series includes the same number of the battery cells 100. Accordingly, the battery 701a can supply the equivalent serial voltages from both the cell laminated body 707 and the cell laminated body 708 in which the battery cells 100 included therein do not overlap one another. Thus, it is possible to supply the equal voltages from two terminals to one electronic device in order to reduce an effect of noise, for example.

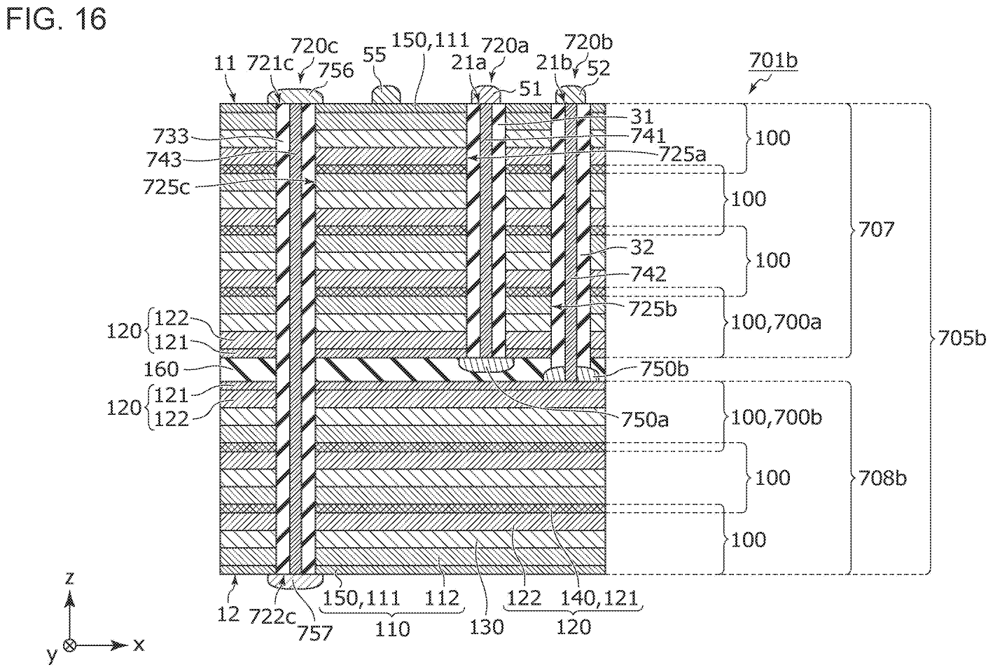

In the meantime, in the power generation element 705 and the power generation element 705a, the number of the battery cells 100 included in the cell laminated body 707 is equal to the number of the battery cells 100 included in the cell laminated body 708. However, the present disclosure is not limited to this configuration. For example, as in a power generation element 705b illustrated in FIG. 16, the number of the battery cells 100 in the cell laminated body 707 may be different from the number of the battery cells 100 in the cell laminated body 708b. FIG. 16 is a sectional view of a battery 701b according to still another example of the present embodiment.

As illustrated in FIG. 16, the battery 701b includes a power generation element 705b instead of the power generation element 705a provided with a cell laminated body 708b including a fewer number of the battery cells 100 than that of the cell laminated body 708 in the power generation element 705a.

In the battery 701b as well, the conductive member 742 is connected to the battery cell 700b located uppermost in the cell laminated body 708b. Accordingly, a voltage between the principal surface 11 and the conductive member 742 corresponds to a voltage obtained by serial connection of all of the battery cells 100 of the cell laminated body 708b. Since the number of the battery cells 100 in the cell laminated body 707 is different from the number of the battery cells 100 in the cell laminated body 708b, the battery 701b can supply two types of voltages corresponding to the different numbers of the battery cells 100 connected in series. As described above, it is possible to adjust the voltages to be supplied by adjusting the numbers of the battery cells 100 included in the cell laminated body 707 and the cell laminated body 708b, respectively.

In the battery 701b, the order of arrangement of the respective layers constituting the battery cells 100 in the cell laminated body 707 is reverse to that of the battery cells 100 in the cell laminated body 708b as with the battery 701a. Here, as with the battery 701, the battery 701b may also be configured such that the battery cells 100 in the cell laminated body 707 and the battery cells 100 in the cell laminated body 708b include the respective layers constituting the battery cells 100 that are arranged in the same order by inverting the orientation of the cell laminated body 708b.

As described above, each of the battery 701, the battery 701a, and the battery 701b according to the present embodiment includes the power generation element in which the two cell laminated bodies are laminated while interposing the insulating layer 160 therebetween. For this reason, the magnitudes and the polarities of the voltages to be supplied by using the conductive member 741 and the conductive member 742 can easily be adjusted by changing the numbers of the battery cells 100 included in the two cell laminated bodies, which are laminated while interposing the insulating layer 160 therebetween and are not electrically connected to each other, and by changing the orientation of lamination thereof.

### Embodiment 8

Next, a description will be given of Embodiment 8. The following description will be focused on different features from those of the Embodiments 1 to 7 while omitting or simplifying explanations of features in common.

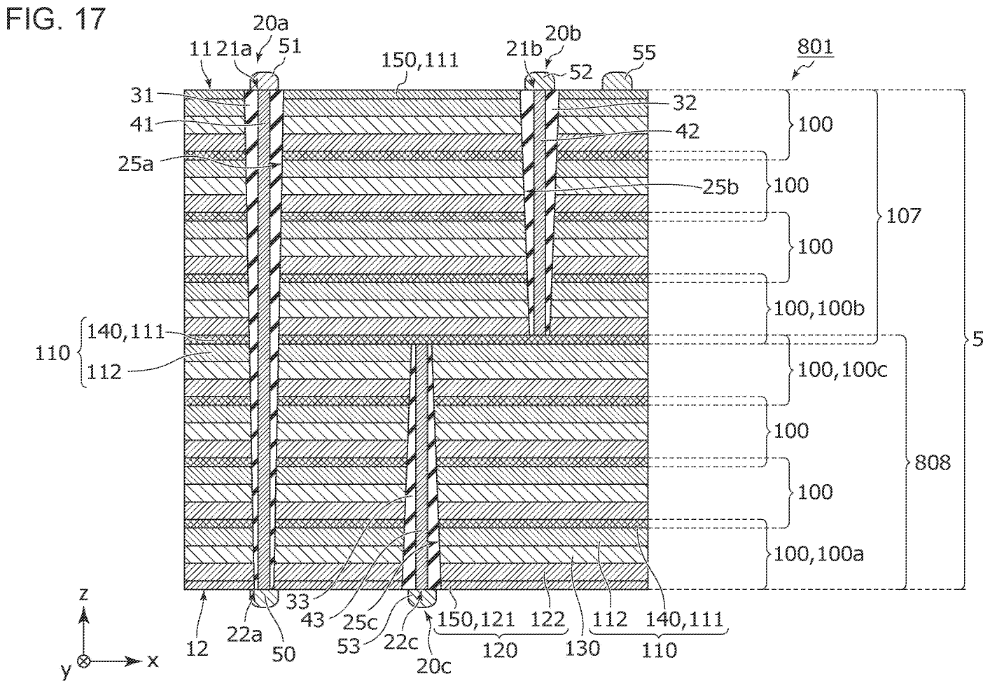

FIG. 17 is a sectional view of a battery 801 according to the present embodiment. As illustrated in FIG. 17, in comparison with the battery 1 according to the Embodiment 1, the battery 801 is mainly different in that the power generation element 5 is further provided with a through hole 20c, and that the battery 801 further includes an insulating member 33, a conductive member 43, and a current collecting terminal 53.

The through hole 20c is open on the principal surface 12 but is not open on the principal surface 11. The through hole 20c is open at an opening position 22c located on the principal surface 12.

The through hole 20c extends from the battery cell 100c among the battery cells 100, which is different from the battery cell 100a and the battery cell 100b, to the principal surface 12. The battery cell 100c is the intermediate battery cell 100 where other battery cells 100 are laminated above and below the relevant battery cell 100, for example. Moreover, in the present embodiment, the battery cell 100c is adjacent to the battery cell 100b and is disposed on the principal surface 12 side of the battery cell 100b. To be more precise, the through hole 20c penetrates from the principal surface on the upper side of the electrode active material layer 112 (in other words, the principal surface on the lower side of the electrode current collector 111) of the battery cell 100c to the principal surface 12.

The through hole 20c has a truncated cone shape, for example, but may have any other shapes including a truncated pyramid shape, a columnar shape, a prism shape, and the like.

The insulating member 33 is disposed inside the through hole 20c. The insulating member 33 is located between the conductive member 43 and an inner wall 25c of the through hole 20c. The insulating member 33 can secure insulation between the conductive member 43 and the inner side surface of the power generation element 5 which is the inner wall 25c of the through hole 20c.

The insulating member 33 is disposed along the inner wall 25c of the through hole 20c. The insulating member 33 covers the inner wall 25c of the through hole 20c in a lump and is in contact with the inner wall 25c of the through hole 20c. This makes it possible to suppress collapse of the materials of the respective layers of the battery cell 100 on the inner wall 25c of the through hole 20c and to suppress a short circuit between the electrode layer 110 and the counter electrode layer 120. The insulating member 33 covers the entire inner wall 25c of the through hole 20c, for example. A clearance may be provided at a certain part between the insulating member 33 and the inner wall 25c.

The insulating member 33 surrounds an outer periphery of the conductive member 43 when viewed in the direction of lamination and is in contact with the conductive member 43. In the present embodiment, the conductive member 43 has a columnar shape, and the insulating member 33 covers the entire side surface of the columnar conductive member 43 and is in contact with the side surface of the conductive member 43. A clearance may be provided at a certain part between the insulating member 33 and the conductive member 43.

The insulating member 33 and the conductive member 43 are packed together so as to bury the through hole 20c. The insulating member 33 completely buries a space between the inner wall 25c of the through hole 20c and the conductive member 43, for example. For this reason, a shape of the insulating member 33 is the same as the shape of the through hole 20c except that a through hole to be penetrated by the conductive member 43 is formed at the center when viewed in the direction of lamination. In the present embodiment, the shape of the insulating member 33 is a tubular shape having a circular or polygonal circumference, for example. To be more precise, the shape of the insulating member 33 is an elongate truncated cone shape provided with the through hole to be penetrated by the conductive member 43 at the center when viewed in the direction of lamination. Note that the shape of the insulating member 33 is not limited to the aforementioned shape. The insulating member 33 is formed in conformity to the shapes of the through hole 20c and the conductive member 43, for example.

The conductive member 43 is disposed inside the through hole 20c. The conductive member 43 is electrically connected to the electrode current collector 111 in the electrode layer 110 of the battery cell 100c without being connected to other battery cells 100. Since the principal surface 12 is the principal surface on the lower side of the counter electrode layer 120 located lowermost, the conductive member 43 is connected to the electrode layer 110 having the different polarity from that of the principal surface 12.

The conductive member 43 extends from the principal surface on the upper side of the electrode current collector 111 of the battery cell 100c to the opening position 22c of the through hole 20c located at the principal surface 12 while passing through the through hole 20c. The conductive member 43 penetrates from the principal surface 12 to the principal surface on the lower side of the electrode current collector 111 of the battery cell 100c while passing through the through hole 20c. Accordingly, a potential at the electrode layer 110 of the battery cell 100c among the battery cells 100, which is different from the battery cell 100a and the battery cell 100b, is induced to the principal surface 12 side so that an electric current can be extracted from the battery cell 100c on the principal surface 12 side of the power generation element 5. In other words, in the present embodiment, the conductive member 43 functions as a penetrating electrode that penetrates a portion of the battery cells 100 included in the power generation element 5.

An end portion on the principal surface 12 side of the conductive member 43 is in contact with the current collecting terminal 53. An end portion on the principal surface 11 side of the conductive member 43 is in contact with the electrode current collector 111 of the battery cell 100c.

A potential at the battery cell 100c is induced by the conductive member 43 to the opening position 22c disposed at the principal surface 12. Since the principal surface 12 is the principal surface on the lower side of the battery cell 100 located lowermost, the battery cells 100 laminated from the battery cell 100c to the uppermost battery cell 100 are the battery cells 100 involved in the connection between the principal surface 12 and the battery cell 100c. A voltage between the principal surface 12 and the conductive member 43 corresponds to the number of the battery cells 100 involved in the serial connection between the principal surface 12 and the battery cell 100c. The battery cells 100 involved in the connection between the principal surface 12 and the conductive member 43 constitute a cell laminated body 808 being serially connected and laminated. In the present embodiment, the number of the battery cells 100 included in the cell laminated body 808 is half as many as the number of the battery cells included in the power generation element 5. Accordingly, the voltage between the principal surface 12 and the conductive member 43 corresponds to a voltage obtained by serially connecting the half of the battery cells 100 in the power generation element 5. In other words, the voltage between the principal surface 12 and the conductive member 43 is one-half of the voltage between the principal surface 11 and the conductive member 41. Meanwhile, the voltage between the principal surface 12 and the conductive member 43 is equal to the voltage between the principal surface 11 and the conductive member 42.

Meanwhile, the battery cells 100 constituting the cell laminated body 107 and the battery cells 100 constituting the cell laminated body 808 do not overlap one another. In other words, the battery cells 100 involved in the connection between the principal surface 11 and the battery cell 100b and the battery cells 100 involved in the connection between the principal surface 12 and the battery cell 100c do not overlap one another. For this reason, it is more likely that the electric power of the respective battery cells 100 in the battery 801 is evenly consumed by using an electronic device and the like by means of connecting the conductive member 42 and the conductive member 43 thereto in the case where the voltage being half as large as the voltage between the principal surface 11 and the conductive member 41 is supposed to be supplied thereto. Thus, it is possible to suppress intensive consumption of the electric power of a portion of the battery cells 100, so that operating time of the battery 801 can be extended. In the meantime, a variation in potential among the battery cells 100 can be reduced. The battery 801 is particularly effective in the case where a voltage obtained by serially connecting a portion of the battery cells 100 among the multiple battery cells 100 is frequently used.

Meanwhile, the number of the battery cells 100 involved in the serial connection between the principal surface 11 and the battery cell 100b is equal to the number of the battery cells 100 involved in the serial connection between the principal surface 12 and the battery cell 100c. In other words, the cell laminated body 107 and the cell laminated body 808 formed by serially connecting and laminating the battery cells 100 include the same number of the battery cells 100, respectively. Accordingly, the battery 801 can supply the equivalent serial voltages from the cell laminated body 107 and the cell laminated body 808 in which no battery cells 100 included therein overlap one another. This configuration makes it possible to supply the same voltage from two terminals to a single electronic device or the like in order to reduce an effect of noise, for example. Note that the number of the battery cells 100 included in the cell laminated body 107 may be different from the number of the battery cells 100 included in the cell laminated body 808.

In the meantime, the battery cells 100 that form the cell laminated body 107 and the battery cells 100 that form the cell laminated body 808 collectively constitute the power generation element 5. The power generation element 5 does not include any battery cells 100 other than the battery cells 100 that form the cell laminated body 107 and the battery cells 100 that form the cell laminated body 808. In this way, the electric power from the respective battery cells 100 in the battery 801 is more likely to be consumed evenly. Note that the power generation element 5 may include battery cells 100 besides the battery cells 100 that form the cell laminated body 107 and the battery cells 100 that constitute the cell laminated body 808.

The current collecting terminal 53 is disposed on the principal surface 12 side of the power generation element 5. The current collecting terminal 53 is connected to the conductive member 43 at the opening position 22c. Accordingly, the current collecting terminal 53 is electrically connected to the electrode layer 110 of the battery cell 100c while interposing the conductive member 43 therebetween. The current collecting terminal 53 is one of the external connection terminals of the battery 801, which is a positive extraction terminal in the present embodiment. A portion of the current collecting terminal 53 is in contact with the insulating member 33. In the meantime, the current collecting terminal 53 is not in contact with the principal surface 12 and is insulated from the principal surface 12, that is, from the counter electrode layer 120 of the battery cell 100 located lowermost. Here, the current collecting terminal 53 does not always have to be in contact with the insulating member 33. Meanwhile, the current collecting terminal 53 may be in contact with the conductive member 43 while interposing another conductive connection layer or the like therebetween.

The current collecting terminal 53 can be formed by using the same material as that of the current collecting terminal 51, the current collecting terminal 52, and the current collecting terminal 55, for example.

As described above, the battery 801 can supply the voltage obtained by serially connecting all of the battery cells 100 of the power generation element 5 and the voltage obtained by serially connecting a portion of the battery cells 100 of the power generation element 5. Moreover, the battery 801 realizes the voltages obtained by serially connecting the portion of the battery cells 100 of the power generation element 5 by the two combinations of the serial connection of the battery cells 100 that do not overlap one another. Accordingly, the electric power of the respective battery cells 100 included in the power generation element 5 is more likely to be consumed evenly in the case of usage that frequently employs the voltage obtained by serially connecting the portion of the battery cells 100.

In the present embodiment, the battery cell 100c, the through hole 20c, the insulating member 33, and the conductive member 43 may be the first battery cell, the first through hole, the first insulating member, and the first conductive member, respectively. In this case, the principal surface 12 is the first surface where the opening position 22c to which the potential at the battery cell 100c is induced by the conductive member 43 is disposed. Moreover, in this case, the battery cell 100a, the through hole 20a, the insulating member 31, and the conductive member 41 may be the second battery cell, the second through hole, the second insulating member, and the second conductive member, respectively.

Meanwhile, in the battery 801, the power generation element 5 need not be provided with the through hole 20a and the battery 801 need not include the insulating member 31, the conductive member 41, the connecting member 50, and the current collecting terminal 51. Alternatively, in the battery 801, the power generation element 5 need not be provided with the through hole 20b and the battery 801 need not include the insulating member 32, the conductive member 42, and the current collecting terminal 52.

### Embodiment 9

Next, a description will be given of Embodiment 9. The following description will be focused on different features from those of the Embodiments 1 to 8 while omitting or simplifying explanations of features in common.

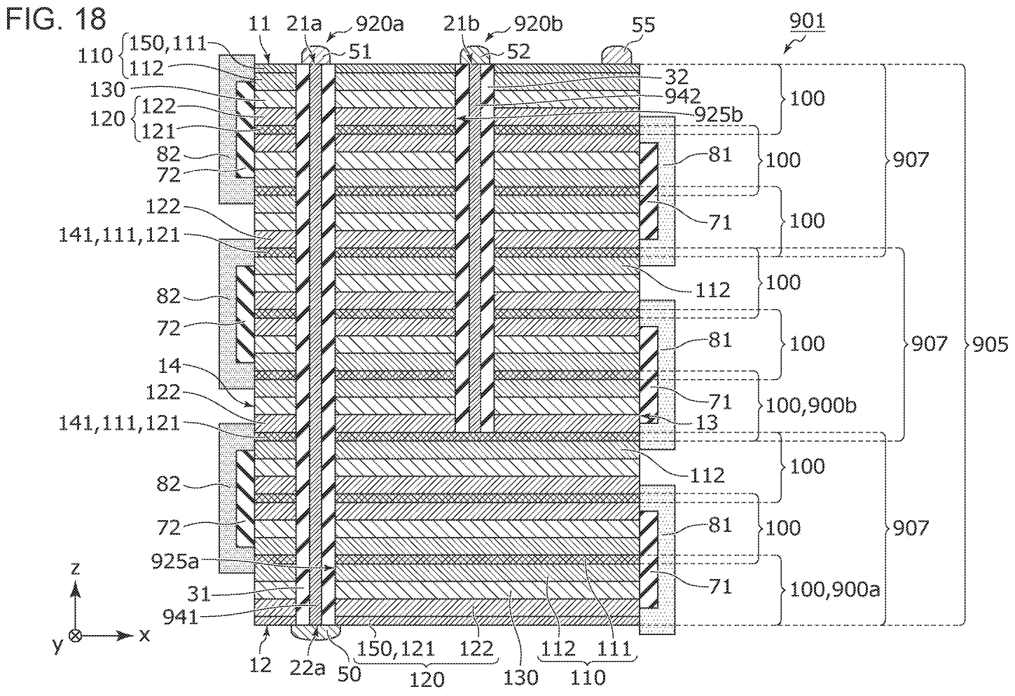

FIG. 18 is a sectional view of a battery 901 according to the present embodiment. As illustrated in FIG. 18, in comparison with the battery 1 according to the Embodiment 1, the battery 901 is mainly different in that the battery 901 includes a power generation element 905 instead of the power generation element 5.

The battery 901 includes the power generation element 905, the insulating member 31, the insulating member 32, a conductive member 941, a conductive member 942, the connecting member 50, the current collecting terminal 51, the current collecting terminal 52, the current collecting terminal 55, an electrode insulating layer 71, a counter electrode insulating layer 72, a counter electrode connecting portion 81, and an electrode connecting portion 82.

The power generation element 905 includes the battery cells 100. A portion of the battery cells 100 are laminated by being electrically connected in parallel. The power generation element 905 includes both the parallel connection and the serial connection of the battery cells 100.

To be more precise, the power generation element 905 includes parallel-laminated bodies 907. In the example illustrated in FIG. 18, the parallel-laminated bodies 907 each include odd, namely, three battery cells 100. The odd battery cells 100 included in each parallel-laminated body 907 are electrically connected in parallel. The parallel connection is carried out by the counter electrode connecting portion 81 and the electrode connecting portion 82. The parallel-laminated bodies 907 are electrically connected in series. The serial connection is carried out by laminating the parallel-laminated bodies 907 in the direction of lamination (that is, the z-axis direction) of the battery cells 100. A specific mode of connection will be described later. Here, the number of the parallel-laminated bodies 907 included in the power generation element 905 and the number of the battery cells 100 included in each parallel-laminated body 907 are not limited to particular numbers, which may each be an odd number or an even number. Alternatively, laminated bodies each including the battery cells 100 connected in series may be connected in parallel.

The power generation element 905 includes a side surface 13 and a side surface 14. The side surface 13 and the side surface 14 are back to back to each other and are parallel to each other. Each of the side surface 13 and the side surface 14 is a flat surface. The side surface 13 of the power generation element 905 is formed by connecting respective first side surfaces of the parallel-laminated bodies 907 in such a way as to be flush with one another. Likewise, the side surface 14 of the power generation element 905 is formed by connecting respective second side surfaces of the parallel-laminated bodies 907 in such a way as to be flush with one another.

As described above, in the battery 901, a large capacity is realized by forming the parallel-laminated bodies 907 each including the battery cells 100 that are laminated while being connected in parallel. Moreover, a large voltage is realized by connecting the parallel-laminated bodies 907 in series.

As illustrated in FIG. 18, regarding two battery cells 100 located adjacent to each other in the parallel-laminated body 907, the orders of arrangement of the respective layers constituting the battery cells 100 are reverse to each other. That is to say, the battery cells 100 are laminated along the z axis while alternately reversing the orders of arrangement of the respective layers constituting the battery cells 100. In the present embodiment, the number of lamination of the battery cells 100 included in each parallel-laminated body 907 is an odd number. As a consequence, the lowermost layer and the uppermost layer of the parallel-laminated body 907 are the current collectors having different polarities from each other. In the example illustrated in FIG. 18, the lowermost layer of the parallel-laminated body 907 is the counter electrode current collector 121 of the counter electrode layer 120 and the uppermost layer thereof is the electrode current collector 111 of the electrode layer 110. Each of the three parallel-laminated bodies 907 has the same configuration.

As a consequence, it is possible to achieve the serial connection by laminating the parallel-laminated bodies 907 in the z-axis direction. Specifically, two parallel-laminated body 907 can be directly laminated in such a way that the current collectors having the different polarities are opposed to each other. That is to say, an insulating layer is not disposed between the parallel-laminated bodies 907 that are adjacent to each other in the direction of lamination. To be more precise, regarding the two parallel-laminated bodies 907 adjacent to each other the electrode layer 110 being the uppermost layer of the parallel-laminated body 907 located below and the counter electrode layer 120 being the lowermost layer of the parallel-laminated body 907 located above share the current collector.

Each intermediate layer current collector 141 illustrated in FIG. 18 is a current collector shared by two parallel-laminated bodies 907. The intermediate layer current collector 141 functions as the electrode current collector 111 of one of the parallel-laminated body 907 and functions as the counter electrode current collector 121 of the other parallel-laminated body 907. To be more precise, the electrode active material layer 112 is disposed on the lower surface of the intermediate layer current collector 141 and the counter electrode active material layer 122 is disposed on the upper surface thereof.

Meanwhile, regarding two battery cells 100 adjacent to each other in each parallel-laminated body 907, two electrode layers 110 located adjacent to each other share one electrode current collector 111. That is to say, the electrode active material layers 112 are disposed on the upper surface and the lower surface of the single electrode current collector 111, respectively. Likewise, two counter electrode layers 120 located adjacent to each other share one counter electrode current collector 121. That is to say, the counter electrode active material layers 122 are disposed on the upper surface and the lower surface of the single counter electrode current collector 121, respectively.

The above-described power generation element 905 can be formed by using the battery cells 100D. 100E, and 100F illustrated in FIGS. 3A to 3C, for example.

Next, the electrode insulating layer 71 and the counter electrode insulating layer 72 will be described.

The electrode insulating layer 71 covers the electrode layer 110 on the first side surface of each of the parallel-laminated bodies 907. To be more precise, on the side surface 13 of the power generation element 905, the electrode insulating layer 71 covers the electrode layers 110, the solid electrolyte layers 130, and portions of the counter electrode active material layers 122 included in the respective parallel-laminated bodies 907. On the side surface 13, the electrode insulating layer 71 does not cover any of the counter electrode current collectors 121 included in the respective parallel-laminated bodies 907.

In each parallel-laminated body 907, the electrode layers 110 of the two adjacent battery cells 100 share the single electrode current collector 111. Accordingly, the electrode insulating layer 71 covers the two adjacent electrode layers 110 in a lump. Specifically, the electrode insulating layer 71 continuously covers a range from the counter electrode active material layer 122, the solid electrolyte layer 130, and the electrode active material layer 112 of one battery cell 100, the shared electrode current collector 111, the electrode active material layer 112, the solid electrolyte layer 130, and the counter electrode active material layer 122 of the other battery cell 100 regarding the two adjacent battery cells 100. As described above, since the electrode insulating layer 71 covers the solid electrolyte layers 130 and the counter electrode active material layers 122 in addition to the electrode layers 110, it is less likely to expose the electrode layers 110 to the side surface 13 even in case of a variation in width (a length in the z-axis direction) due to production tolerance of the electrode insulating layer 71. Accordingly, it is less likely that the electrode layer 110 comes into contact with the counter electrode connecting portion 81 on the side surface 13 to cause a short circuit, so that reliability of the battery 901 can be improved. Note that the electrode insulating layer 71 does not always have to cover the counter electrode active material layers 122. Meanwhile, the electrode insulating layer 71 does not always have to cover the solid electrolyte layers 130, either.

The counter electrode insulating layer 72 covers the counter electrode layer 120 on the second side surface of each of the parallel-laminated bodies 907. To be more precise, on the side surface 14 of the power generation element 905, the counter electrode insulating layer 72 covers the counter electrode layers 120, the solid electrolyte layers 130, and portions of the electrode active material layers 112 included in the respective parallel-laminated bodies 907. On the side surface 14, the counter electrode insulating layer 72 does not cover any of the electrode current collectors 111 included in the respective parallel-laminated bodies 907.

The electrode insulating layers 71 and the counter electrode insulating layers 72 penetrate into asperities on respective end surfaces of the electrode active material layers 112, the counter electrode active material layers 122, and the solid electrolyte layers 130, thereby increasing adhesion strength and improving reliability of the battery 901. Here, each of the electrode active material layers 112, the counter electrode active material layers 122, and the solid electrolyte layers 130 can be formed by using a powder material. In this case, very fine asperities are present on an end surface of each of the layers.

The electrode insulating layers 71 and the counter electrode insulating layers 72 form a stripe shape, respectively, when viewing the side surface 13 or the side surface 14 from the front, for example.

Each of the electrode insulating layer 71 and the counter electrode insulating layer 72 is formed by using an insulating material having an electrical insulation property. For example, each of the electrode insulating layer 71 and the counter electrode insulating layer 72 contains a resin. The resin is an epoxy-based resin, for example. However, the resin is not limited thereto. Here, an inorganic material may be used as the insulating material. The insulating material usable therein is selected based on various characteristics including flexibility, gas barrier properties, shock resistance, heat resistance, and the like. The electrode insulating layer 71 and the counter electrode insulating layer 72 are formed by using the same material. Instead, the electrode insulating layer 71 and the counter electrode insulating layer 72 may be formed by using different materials from each other.

In the present embodiment, of all the current collectors included in the power generation element 905, the intermediate layer current collectors 141, the uppermost electrode current collector 111 of the power generation element 905, and the lowermost counter electrode current collector 121 of the power generation element 905 are not covered with an insulating member on the side surface 13 and the side surface 14, respectively. The remaining current collectors included in the power generation element 905 are covered with the insulating member on any one of the side surface 13 and the side surface 14. The parallel-laminated bodies 907 can be connected in series by connecting the intermediate layer current collectors 141 to the counter electrode connecting portions 81 on the side surface 13 and to the electrode connecting portions 82 on the side surface 14.

Next, the counter electrode connecting portion 81 and the electrode connecting portion 82 will be described.

The counter electrode connecting portion 81 is a conductive portion which covers the first side surface and the electrode insulating layer 71 and is connected to the counter electrode layers 120 in each of the parallel-laminated bodies 907. In other words, the counter electrode connecting portion 81 is provided to each parallel-laminated body 907. As illustrated in FIG. 18, three counter electrode connecting portions 81 are provided in such a way as to cover the side surface 13. The three counter electrode connecting portions 81 are disposed with predetermined intervals so as not to come into contact with one another.

Specifically, the counter electrode connecting portions 81 come into contact with and cover the respective end surfaces of the counter electrode current collectors 121 on the side surface 13. In the present embodiment, each counter electrode connecting portion 81 comes into contact with and covers at least a portion of each of the end surfaces of the counter electrode active material layers 122. The counter electrode connecting portions 81 penetrate into asperities on the end surfaces of the counter electrode active material layers 122, thereby increasing the adhesion strength and improving reliability of the battery 901.

The electrode connecting portion 82 is a conductive portion which covers the second side surface and the counter electrode insulating layer 72 and is connected to the electrode layers 110 in each of the parallel-laminated bodies 907. In other words, the electrode connecting portion 82 is provided to each parallel-laminated body 907. As illustrated in FIG. 18, three electrode connecting portions 82 are provided in such a way as to cover the side surface 14. The three electrode connecting portions 82 are disposed with predetermined intervals so as not to come into contact with one another.

Specifically, the electrode connecting portions 82 come into contact with and cover the respective end surfaces of the electrode current collectors 111 on the side surface 14. In the present embodiment, each electrode connecting portion 82 comes into contact with and covers at least a portion of each of the end surfaces of the electrode active material layers 112. The electrode connecting portions 82 penetrate into asperities on the end surfaces of the electrode active material layers 112, thereby increasing the adhesion strength and improving reliability of the battery 901.

Here, each intermediate layer current collector 141 serves as the electrode current collector 111 and as the counter electrode current collector 121. The intermediate layer current collector 141 is in contact and covered with the counter electrode connecting portion 81 on the side surface 13, and is in contact and covered with the electrode connecting portion 82 on the side surface 14. In this instance, the counter electrode connecting portion 81 in contact with the intermediate layer current collector 141 is the counter electrode connecting portion 81 of the parallel-laminated body 907 that includes the intermediate layer current collector 141 as the counter electrode current collector 121 (that is to say, the parallel-laminated body 907 on the upper side in the example of FIG. 18). In this case, the counter electrode connecting portion 81 of the parallel-laminated body 907 on the upper side may be in contact with the electrode active material layer 112 of the parallel-laminated body 907 on the lower side. Likewise, the electrode connecting portion 82 in contact with the intermediate layer current collector 141 is the electrode connecting portion 82 of the parallel-laminated body 907 that includes the intermediate layer current collector 141 as the electrode current collector 111 (that is to say, the parallel-laminated body 907 on the lower side in the example of FIG. 18). In this case, the electrode connecting portion 82 of the parallel-laminated body 907 on the lower side may be in contact with the counter electrode active material layer 122 of the parallel-laminated body 907 on the upper side.

The counter electrode connecting portions 81 and the electrode connecting portions 82 form a stripe shape, respectively, when viewing the side surface 13 or the side surface 14 from the front, for example.

Each of the counter electrode connecting portion 81 and the electrode connecting portion 82 is formed by using a conductive resin material and the like. Alternatively, each of the counter electrode connecting portion 81 and the electrode connecting portion 82 may be formed by using a metal material such as solder. The conductive material usable therein is selected based on various characteristics including flexibility, gas barrier properties, shock resistance, heat resistance, solder wettability, and the like. The counter electrode connecting portion 81 and the electrode connecting portion 82 are formed by using the same material. Instead, counter electrode connecting portion 81 and the electrode connecting portion 82 may be formed by using different materials from each other.

When drawing attention to a certain parallel-laminated body 907, the parallel connection of all of the battery cells 100 included in the certain parallel-laminated body 907 is carried out by the counter electrode connecting portion 81 provided on the first side surface of the certain parallel-laminated body 907 and the electrode connecting portion 82 provided on the second side surface of the certain parallel-laminated body 907. The parallel connection of the three battery cells 100 is carried out by the counter electrode connecting portion 81 and the electrode connecting portion 82 in each parallel-laminated body 907. Each of the counter electrode connecting portion 81 and the electrode connecting portion 82 can be realized with a small volume along the side surface 13 or the side surface 14 of the parallel-laminated body 907, so that the capacity density of the battery 901 can be increased. Moreover, since the power generation element 905 includes the serial connection and the parallel connection of the battery cells 100, it is possible to realize the high-capacity and high-voltage battery 901.

The power generation element 905 is provided with a through hole 920a and a through hole 920b. In the example illustrated in FIG. 18, the through hole 920a penetrates all of the battery cells 100 included in the power generation element 905 in the direction of lamination. Meanwhile, the through hole 920b penetrates a portion of the battery cells 100 included in the power generation element 905 in the direction of lamination. The through hole 920a is an example of the first through hole. The through hole 920b is an example of the second through hole. The through hole 920a and the through hole 920b are not connected to each other and are independent of each other.

The through hole 920a is open on the principal surface 11 and the principal surface 12. To be more precise, the through hole 920a is open at the opening position 21a located on the principal surface 11 and at the opening position 22a located on the principal surface 12.

The through hole 920a extends from a battery cell 900a located lowermost among the battery cells 100 to the principal surface 11. To be more precise, the through hole 920a penetrates from the principal surface 12 being the principal surface on the lower side of the battery cell 900a to the principal surface 11. The battery cell 900a is the battery cell 100 located lowermost of the parallel-laminated body 907 that is located lowermost. Since the battery cell 900a is located lowermost in the present embodiment, the principal surface 12 constitutes a portion of the battery cell 900a. To be more precise, the principal surface 12 is the principal surface on the lower side of the battery cell 900a. The battery cell 900a is an example of the first battery cell. Note that the through hole 920a does not always have to be open on the principal surface 12, and may penetrate from a portion of the counter electrode layer 120 of the battery cell 900a to the principal surface 11, for example.

The through hole 920b is open on the principal surface 11 but is not open on the principal surface 12. To be more precise, the through hole 920b is open at the opening position 21b located on the principal surface 11.

The through hole 920b extends from a battery cell 900b among the battery cells 100, which is different from the battery cell 900a, to the principal surface 11. To be more precise, the through hole 920b penetrates from the principal surface on the lower side of the counter electrode active material layer 122 (in other words, the principal surface on the upper side of the counter electrode current collector 121) of the battery cell 900b to the principal surface 11. The battery cell 900b is also the battery cell 100 located lowermost of the intermediate parallel-laminated body 907 where other parallel-laminated bodies 907 are laminated above and below the relevant parallel-laminated body 907. Accordingly, the battery cell 900a and the battery cell 900b are included in the parallel-laminated bodies 907 different from each other. The battery cell 900b is an example of the second battery cell.

An inner wall 925a of the through hole 920a and an inner wall 925b of the through hole 920b are parallel to the direction of lamination. Accordingly, the volume and the shape of the through hole 920a can easily be equalized among the respective battery cells 100 that the through hole 920a passes through. The same effect can be obtained regarding the inner wall 925b of the through hole 920b.

Each of the through hole 920a and the through hole 920b has a columnar shape, for example, but may have any other shapes including a prism shape, a truncated cone shape, a truncated pyramid shape, and the like.

In the battery 901 as well, the insulating member 31 is disposed between the conductive member 941 and the inner wall 925a of the through hole 920a, so that insulation can be secured between the conductive member 941 and an inner side surface of the power generation element 905 which is the inner wall 925a of the through hole 920a as with the battery 1. Likewise, the insulating member 32 is disposed between the conductive member 942 and the inner wall 925b of the through hole 920b, so that insulation can be secured between the conductive member 942 and an inner side surface of the power generation element 905 which is the inner wall 925b of the through hole 920b.

The conductive member 941 is disposed inside the through hole 920a. The conductive member 941 is an example of the first conductive member. The conductive member 941 is electrically connected to the principal surface 12 of the power generation element 905 while interposing the connecting member 50 therebetween. For this reason, the conductive member 941 is electrically connected to the counter electrode current collector 121 in the counter electrode layer 120 of the lowermost battery cell 900a of the power generation element 905 without being connected to other battery cells 100. Since the principal surface 11 is the principal surface on the upper side of the electrode layer 110 located uppermost, the conductive member 941 is connected to the counter electrode layer 120 having the different polarity from that of the principal surface 11.

The conductive member 941 extends from the opening position 22a of the through hole 920a at the principal surface 12 to the opening position 21a of the through hole 920a located at the principal surface 11 while passing through the through hole 920a. The conductive member 941 penetrates from the principal surface 11 to the principal surface 12 of the power generation element 905 while passing through the through hole 920a. Accordingly, a potential at the counter electrode layer 120 of the battery cell 900a located lowermost of the power generation element 905 is induced to the principal surface 11 side so that an electric current can be extracted from the lowermost battery cell 900a on the principal surface 11 side of the power generation element 905.

An end portion on the principal surface 11 side of the conductive member 941 is in contact with the current collecting terminal 51. An end portion on the principal surface 12 side of the conductive member 941 is in contact with the connecting member 50.

In the present embodiment, the principal surface 11 is the first surface where the opening position 21a to which the potential at the battery cell 900a is induced by the conductive member 941 is disposed. The principal surface 11 is the principal surface on the upper side of the uppermost battery cell 100. Accordingly, the battery cells 100 laminated from the battery cell 900a to the uppermost battery cell 100 are the battery cells 100 involved in the connection between the principal surface 11 and the battery cell 900a. A voltage between the principal surface 11 and the conductive member 941 corresponds to the number of the battery cells 100 involved in the serial connection between the principal surface 11 and the battery cell 900a. In the present embodiment, the parallel-laminated bodies 907 in which the battery cells 100 are connected in parallel are connected in series. Accordingly, it is also possible to say that the voltage between the principal surface 11 and the conductive member 941 corresponds to the number of the parallel-laminated bodies 907 involved in the serial connection between the principal surface 11 and the battery cell 900a. The principal surface 11 is the principal surface on the upper side of the parallel-laminated body 907 on the upper side, and the battery cell 900a is the battery cell 100 included in the parallel-laminated body 907 on the lower side. Accordingly, in the present embodiment, the voltage between the principal surface 11 and the conductive member 941 corresponds to a voltage obtained by the serial connection of all of the parallel-laminated bodies 907 of the power generation element 905.

The conductive member 942 is disposed inside the through hole 920b. The conductive member 942 is an example of the second conductive member. The conductive member 942 is electrically connected to the counter electrode current collector 121 in the counter electrode layer 120 of the battery cell 900b without being connected to other battery cells 100. Since the principal surface 11 is the principal surface on the upper side of the electrode layer 110 located uppermost, the conductive member 942 is connected to the counter electrode layer 120 having the different polarity from that of the principal surface 11.

The conductive member 942 extends from a principal surface on the upper side of the counter electrode current collector 121 of the battery cell 900b to the opening position 21b of the through hole 920b located at the principal surface 11 while passing through the through hole 920b. The conductive member 942 penetrates from the principal surface 11 to the principal surface on the upper side of the counter electrode current collector 121 of the battery cell 900b while passing through the through hole 920b. Accordingly, a potential at the counter electrode layer 120 of the battery cell 900b included in the parallel-laminated bodies 907, which is different from the parallel-laminated bodies 907 including the battery cell 900a among the battery cells 100, to the principal surface 11 side so that an electric current can be extracted from the battery cell 900b on the principal surface 11 side of the power generation element 905.

An end portion on the principal surface 11 side of the conductive member 942 is in contact with the current collecting terminal 52. An end portion on the principal surface 12 side of the conductive member 942 is in contact with the counter electrode current collector 121 of the battery cell 900b.

In the present embodiment, the principal surface 11 is the second surface where the opening position 21b to which the potential at the battery cell 900b is induced by the conductive member 942 is disposed. Accordingly, each of the first surface and the second surface is the same principal surface 11 in the present embodiment. The principal surface 11 is the principal surface on the upper side of the uppermost battery cell 100. Accordingly, the battery cells 100 laminated from the battery cell 900b to the uppermost battery cell 100 are the battery cells 100 involved in the connection between the principal surface 11 and the battery cell 900b. A voltage between the principal surface 11 and the conductive member 942 corresponds to the number of the battery cells 100 involved in the serial connection between the principal surface 11 and the battery cell 900b. In the present embodiment, it is also possible to say that the voltage between the principal surface 11 and the conductive member 942 corresponds to the number of the parallel-laminated bodies 907 involved in the serial connection between the principal surface 11 and the battery cell 900b. The principal surface 11 is the principal surface on the upper side of the parallel-laminated body 907 on the upper side, and the battery cell 900b is the battery cell 100 included in the intermediate parallel-laminated body 907. Accordingly, in the present embodiment, the voltage between the principal surface 11 and the conductive member 942 corresponds to a voltage obtained by the serial connection of the two parallel-laminated bodies 907. In the present embodiment, the voltage between the principal surface 11 and the conductive member 942 is two-thirds of the voltage between the principal surface 11 and the conductive member 941.

In the present embodiment, the number of the parallel-laminated bodies 907 involved in the serial connection between the principal surface 11 and the battery cell 900a is different from the number of the parallel-laminated bodies 907 involved in the serial connection between the principal surface 11 and the battery cell 900b. Accordingly, the battery 901 can supply the two types of voltages having the different magnitudes on the principal surface 11 side.

Each of the conductive member 941 and the conductive member 942 has a columnar shape, for example, but may have any other shapes including a prism shape, a truncated cone shape, a truncated pyramid shape, and the like. A diameter of each of the conductive member 941 and the conductive member 942 is constant, for example.

Each of the conductive member 941 and the conductive member 942 is formed by using the same material as that of the conductive member 41 and the conductive member 42.

As described above, the battery 901 can supply the voltages corresponding to the multiple combinations of the parallel-laminated bodies 907 from the single battery 901 by providing the conductive member 941 and the conductive member 942 in the through hole 920a and the through hole 920b. Thus, the battery 901 can enhance the capacity density and usability as with the battery 1 according to the Embodiment 1.

### Embodiment 10

Next, a description will be given of Embodiment 10. The following description will be focused on different features from those of the Embodiments 1 to 9 while omitting or simplifying explanations of features in common.

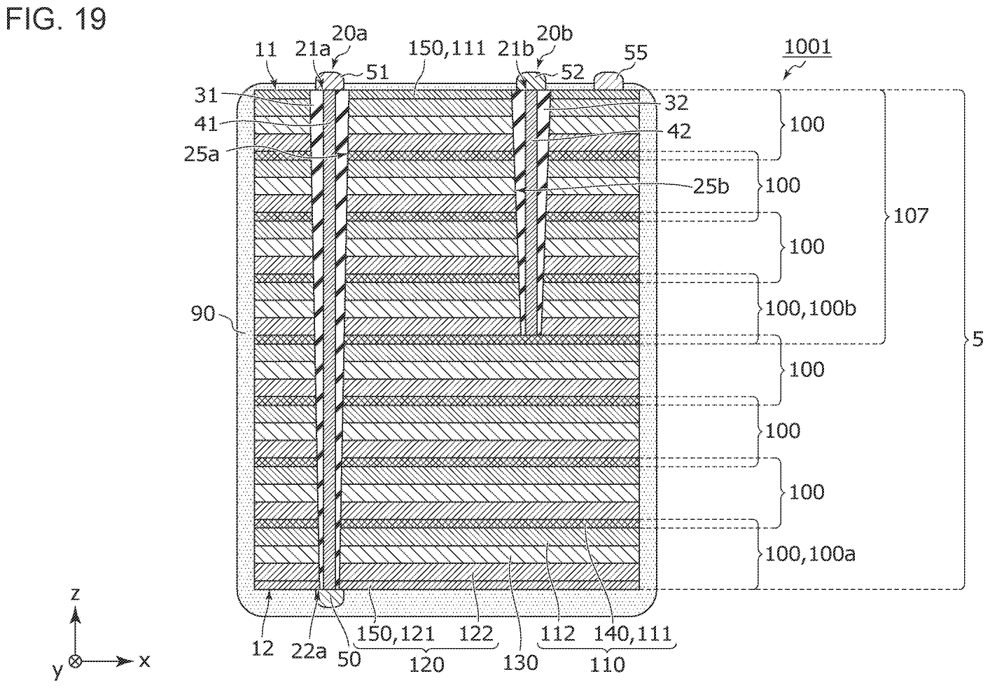

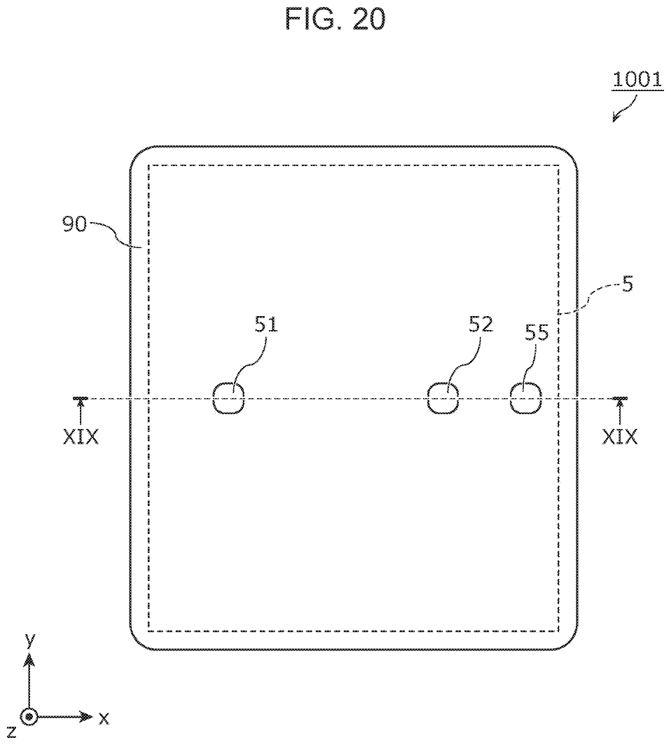

FIG. 19 is a sectional view of a battery 1001 according to the present embodiment. FIG. 20 is a top plan view of the battery 1001 according to the present embodiment. Here, FIG. 19 illustrates a section taken along the XIX-XIX line in FIG. 20. As illustrated in FIGS. 19 and 20, in comparison with the battery 1 according to the Embodiment 1, the battery 1001 is different in that the battery 1001 further includes a sealing member 90.

The sealing member 90 exposes at least a portion of each of the current collecting terminal 51, the current collecting terminal 52, and the current collecting terminal 55 and seals the power generation element 5 at the same time. The sealing member 90 is provided in such a way as not to expose the power generation element 5, the insulating member 31, the insulating member 32, the conductive member 41, the conductive member 42, and the connecting member 50.

The sealing member 90 is formed by using an insulating material having an electrical insulation property, for example. Publicly known materials for battery sealing members such as a sealant can be used as the insulating material. A resin material can be used as the insulating material, for example. Here, the insulating material may be an insulative and non-ion conductive material. For example, the insulating material may be at least one of epoxy resin, acrylic resin, polyimide resin, and silsesquioxane.

Here, the sealing member 90 may contain different insulating materials. For example, the sealing member 90 may have a multilayer structure. Respective layers in the multilayer structure may be formed by using different materials and have different properties.

The sealing member 90 may contain a granular metal oxide material. Such metal oxide materials usable therefor include silicon oxide, aluminum oxide, titanium oxide, zinc oxide, cerium oxide, iron oxide, tungsten oxide, zirconium oxide, calcium oxide, zeolite, glass, and the like. For example, the sealing member 90 may be formed by using a resin material in which particles made of such a metal oxide material are dispersed.

A grain size of the metal oxide material is less than or equal to an interval between the electrode current collector 111 and the counter electrode current collector 121. A shape of grains of the metal oxide material is a spherical shape, an oval spherical shape, a rod shape, or the like but is not limited to these shapes.

Provision of the sealing member 90 can improve reliability of the battery 1001 in various perspectives including mechanical strength, short-circuit prevention, moisture prevention, and so forth.

Although the example of further providing the battery 1 according to the Embodiment 1 with the sealing member 90 has been described herein, the batteries according to other embodiments may further include the sealing member 90 likewise.

### Embodiment 11

Next, a description will be given of Embodiment 11. The Embodiment 11 will describe a circuit board that includes the battery according to any of the above-described embodiments. The following description will be focused on different features from those of the Embodiments 1 to 10 while omitting or simplifying explanations of features in common.

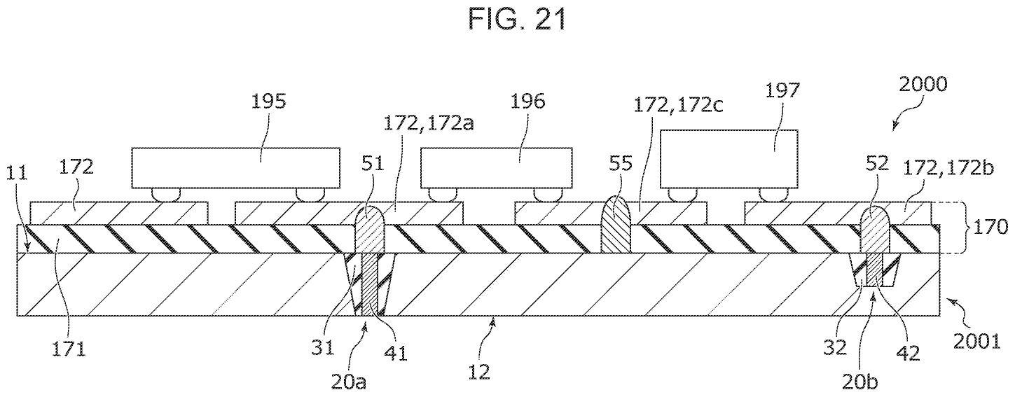

FIG. 21 is a sectional view of a circuit board 2000 according to the present embodiment. As illustrated in FIG. 21, the circuit board 2000 is a mounting board for mounting the electronic device 195, an electronic device 196, and an electronic device 197, for example. For example, each of the electronic device 195, the electronic device 196, and the electronic device 197 is any of a resistor, a capacitor, an inductor, a semiconductor chip, and the like. The number of the electronic devices to be mounted on the circuit board 2000 is not limited to a particular number.

The circuit board 2000 includes a battery 2001 and a circuit pattern layer 170.

The battery 2001 is any one of the batteries 1, 201, 301, 401, 401a, 501, 501a, 601, 701, 701a, 701b, 801, 901, and 1001 according to the above-described embodiments. In FIG. 21, illustration of a detailed structure of the battery 2001 is omitted for the sake of visibility and only the through hole 20a, the through hole 20b, the insulating member 31, the insulating member 32, the conductive member 41, the conductive member 42, the current collecting terminal 51, the current collecting terminal 52, and the current collecting terminal 55 are demonstrated therein. Meanwhile, although the through hole 20a, the through hole 20b, the insulating member 31, the insulating member 32, the conductive member 41, and the conductive member 42 of the battery 1 according to the Embodiment 1 are representatively illustrated in FIG. 21, the battery 2001 may be provided with the through holes, the insulating members, and the conductive members according to any of the embodiments other than the Embodiment 1.

The circuit pattern layer 170 is laminated on the battery 2001. The circuit pattern layer 170 is disposed on the principal surface 11 side of the power generation element included in the battery 2001. The circuit pattern layer 170 includes a wiring insulating layer 171 and circuit wiring 172.

The wiring insulating layer 171 is disposed on the principal surface 11. In the example illustrated in FIG. 21, a width (an area) of the wiring insulating layer 171 is equal to a width (an area) of the battery 2001. Instead, the width (the area) of the wiring insulating layer 171 may be smaller than or larger than the width (the area) of the battery 2001. The circuit wiring 172 is formed on a surface on the opposite side to the principal surface 11 side of the wiring insulating layer 171.

The wiring insulating layer 171 is formed from an insulating material, and a general board insulating member such as an insulating film or an insulating board can be used. Meanwhile, the wiring insulating layer 171 may be a coated layer of the insulating material coated on the battery 2001. Alternatively, the wiring insulating layer 171 may be a portion of the sealing member 90.

In the circuit board 2000, the current collecting terminal 51, the current collecting terminal 52, and the current collecting terminal 55 penetrate the wiring insulating layer 171 and project from the opposite side to the principal surface 11 of the wiring insulating layer 171.

The circuit wiring 172 is disposed on the opposite side to the principal surface 11 side of the wiring insulating layer 171. The circuit wiring 172 is a circuit pattern formed on the wiring insulating layer 171. The circuit wiring 172 is general printed board wiring, for example. The circuit wiring 172 may be a conductive pattern formed in accordance with a different method. The electronic device 195, the electronic device 196, and the electronic device 197 are connected to the circuit wiring 172. The circuit wiring 172 includes a first line 172a, a second line 172b, and a third line 172c. The first line 172a is an example of a portion of the circuit wiring 172. The second line 172b is an example of another portion of the circuit wiring 172.

The current collecting terminal 51, the current collecting terminal 52, and the current collecting terminal 55 are connected to the circuit wiring 172. Specifically, the current collecting terminal 51 is connected to the first line 172a. Meanwhile, the current collecting terminal 52 is connected to the second line 172b. In the meantime, the current collecting terminal 55 is connected to the third line 172c. Accordingly, the conductive member 41 is electrically connected to the first line 172a while interposing the current collecting terminal 51 therebetween. Meanwhile, the conductive member 42 is electrically connected to the second line 172b while interposing the current collecting terminal 52 therebetween. In the meantime, the principal surface 11 is electrically connected to the third line 172c while interposing the current collecting terminal 55 therebetween. The first line 172a, the second line 172b, and the third line 172c are located away from one another and are not in contact with one another.

In the circuit board 2000, each of the current collecting terminal 51 and the current collecting terminal 52 does not penetrate the circuit wiring 172 and a portion of each of the current collecting terminal 51 and the current collecting terminal 52 is buried in the circuit wiring 172. The current collecting terminal 55 penetrates the circuit wiring 172 and a tip end of the current collecting terminal 55 is exposed. Here, positional relationships of the current collecting terminal 51, the current collecting terminal 52, and the current collecting terminal 55 with the circuit wiring 172 are not limited as long as these terminals are connected to the circuit wiring 172. For example, the current collecting terminal 51 and the current collecting terminal 52 may penetrate the circuit wiring 172. On the other hand, the current collecting terminal 55 does not always have to penetrate the circuit wiring 172. Meanwhile, a tip end of at least one of the current collecting terminal 51, the current collecting terminal 52, and the current collecting terminal 55 may be in contact with a surface on the principal surface 11 side of the circuit wiring 172.

The circuit board 2000 is fabricated by forming the circuit pattern layer 170 and the battery 2001 separately and joining the circuit pattern layer 170 and the battery 2001 thus formed to each other, for example. Alternatively, the circuit board 2000 may be formed by laminating the wiring insulating layer 171 on the battery 2001 and then forming the pattern of the circuit wiring 172 on the laminated wiring insulating layer 171.

According to the above-described circuit board 2000, the electronic device 195, the electronic device 196, and the electronic device 197 can be mounted on the circuit pattern layer 170 that is formed on the battery 2001. Thus, the wiring board and the battery are integrated together, and downsizing and thin profiling of electronic equipment can be realized. Meanwhile, since the battery 2001 is one of the batteries according to the above-described embodiments, the battery 2001 can achieve a high capacity density and high usability at the same time. For example, the circuit board 2000 can supply multiple types of voltages to the electronic devices and the like.

Meanwhile, the electric power can be directly supplied from the battery 2001 to required locations on the circuit wiring 172. Thus, it is possible to reduce extension of the wiring and to suppress radiation noise from the wiring. Moreover, the current collectors in the battery 2001 can function as shield layers for noise suppression. As described above, it is possible to stabilize an operation of the electronic equipment by using the circuit board 2000 for the electronic equipment. The circuit board 2000 is used for radio-frequency equipment susceptible to the radiation noise, for example.

Each of the conductive member 41, the conductive member 42, and the principal surface 11 is electrically connected to the circuit wiring 172 while interposing each of the current collecting terminal 51, the current collecting terminal 52, and the current collecting terminal 55 therebetween. However, the present disclosure is not limited to this configuration. For example, conductive contacts that penetrate the wiring insulating layer 171 may be provided and the circuit wiring 172 may be electrically connected to the conductive member 41, the conductive member 42, and the principal surface 11 while interposing the conductive contacts therebetween.

### Manufacturing Method

Next, a description will be given of methods of manufacturing the batteries according to the respective embodiments mentioned above. Note that the manufacturing methods to be described below are mere examples and the methods of manufacturing the batteries of the above-described embodiments are not limited to the following examples. Meanwhile, the following description will be focused on manufacturing of the battery according to one of the above-mentioned embodiments. However, each of the manufacturing methods described below is applicable to the battery according to a different one of the embodiments as appropriate.

### First Example of Manufacturing Method

A first example of manufacturing the batteries according to the respective embodiments will be described to begin with.

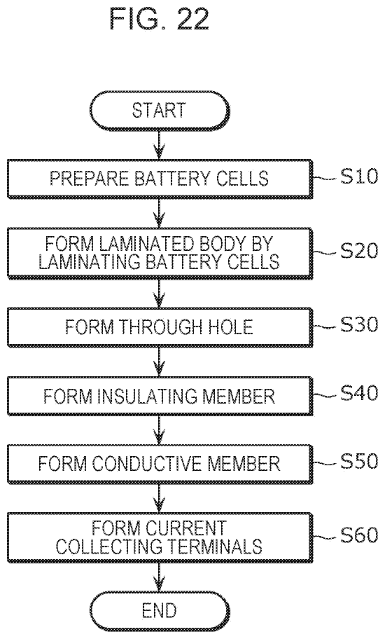

FIG. 22 is a flowchart illustrating the first example of the method for manufacturing the batteries according to the respective embodiments. The first example of the manufacturing method will be focused on manufacturing of the battery 1 according to the Embodiment 1.

As illustrated in FIG. 22, the battery cells are prepared to begin with (step S10). The prepared battery cells are any of the battery cells 100D, battery cells 100E, and the battery cells 100F illustrated in FIGS. 3A to 3C, for example. In the following description of the manufacturing method, the battery cells 100D, 100E, and the 100F may be collectively referred to as the battery cells 100 as appropriate.

Next, a laminated body is formed by laminating the battery cells 100 (step S20). To be more precise, the laminated body is formed by sequentially laminating the battery cells 100 such that the orders of arrangement of the electrode layer 110, the counter electrode layer 120, and the solid electrolyte layer 130 in the respective battery cells are aligned with one another. The power generation element 5 illustrated in FIG. 4 is formed by laminating an appropriate combination of the battery cells 100D, 100E, and 100F, for example. The power generation element 5 is an example of the laminated body.

Here, the side surfaces of the power generation element 5 may be planarized after laminating the battery cells 100. The power generation element 5 with the respective flat side surfaces can be formed by cutting the laminated body of the battery cells 100 in a lump, for example. A cutting process is carried out by using a blade, a laser, waterjet, and the like.

Next, the power generation element 5 is provided with at least one through hole that penetrates at least a portion of the battery cells 100 among the battery cells 100 in the direction of lamination (step S30). To be more precise, the power generation element 5 is provided with the through hole 20a that penetrates all of the battery cells 100 and the through hole 20b that penetrates a portion of the battery cells 100. For example, formation of the through hole 20a and the through hole 20b is carried out by cutting work by using a drill and the like. Alternatively, the through hole 20a and the through hole 20b may be formed by using a laser and the like.

Meanwhile, in the first example of the manufacturing method, the through hole 20a and the through hole 20b are formed after the formation of the laminated body (step S20). Accordingly, at least a portion of the battery cells 100 that the through holes pass through can be processed in a lump so that productivity of the battery 1 can be improved. In addition, it is not necessary to align the positions of the through holes unlike the case of providing the battery cells 100, which are yet to be laminated, with through holes corresponding to the through hole 20a and the through hole 20b. This feature is especially effective in the case of manufacturing a large-sized battery 1 that needs to improve the positioning accuracy due to an increase in area of the power generation element 5.

Next, the insulating member is formed in the at least one through hole thus formed (step S40). Specifically, the insulating member 31 to be disposed between the conductive member 41 and the inner wall 25a of the formed through hole 20a is formed. Moreover, the insulating member 32 to be disposed between the conductive member 42 and the inner wall 25b of the formed through hole 20b is formed.

For example, the insulating member 31 that covers the inner wall 25a of the through hole 20a provided in the power generation element 5 is formed. The insulating member 31 is formed inside the through hole 20a provided in the power generation element 5 while securing the space for forming the conductive member 41 therein. The insulating member 31 is formed by coating the insulating material to the inner wall 25a of the through hole 20a, for example. Instead, the insulating member 31 may be formed by filling the through hole 20a with the insulating material in such a way as to completely bury the through hole 20a, and providing the filled insulating material with a through hole for forming the conductive member 41, that is to say, a through hole having the same shape as that of the conductive member 41 to be formed therein. The insulating member 32 can also be formed in accordance with the same method of forming the insulating member 31. In other words, the formation of the insulating member 32 can be explained by replacing the through hole 20a, the inner wall 25a, the insulating member 31, and the conductive member 41 in the foregoing description with the through hole 20b, the inner wall 25b, the insulating member 32, and the conductive member 42, respectively. The same replacement may also take place in the following description of other manufacturing methods.

Next, the conductive member is formed in the at least one through hole thus formed (step S50). Specifically, the conductive member 41 being electrically connected to the battery cell 100a and extending to the opening position 21a of the through hole 20a while passing through the through hole 20a is formed inside the through hole 20a that is provided to the power generation element 5. Meanwhile, the conductive member 42 being electrically connected to the battery cell 100b and extending to the opening position 21b of the through hole 20b while passing through the through hole 20b is formed inside the through hole 20b that is provided to the power generation element 5. The conductive member 41 is formed by filling the space in the through hole 20a not provided with the insulating member 31 with a conductive material, for example. Alternatively, the conductive member 41 may be formed by inserting the conductive member 41 that is shaped by molding and the like in advance into the through hole 20a, for example. The conductive member 42 can also be formed in accordance with the same method applied to the conductive member 41. In addition, the connecting member 50 is formed at the position to be connected to the end portion on the principal surface 12 side of the conductive member 41 and to the principal surface 12 when necessary.

Here, the formation of the insulating member (step S40) and the formation of the conductive member (step S50) need not be carried out in the aforementioned order. For example, the formation of the conductive member (step S50) may be carried out before the formation of the insulating member (step S40). In this case, the insulating member 31 and the conductive member 41 are formed inside the through hole 20a by disposing the conductive member 41 inside the through hole 20a and filling the space between the conductive member 41 and the inner wall 25a of the through hole 20a with the insulating member, for example. The insulating member 32 and the conductive member 42 can also be formed in accordance with the same method applied to the insulating member 31 and the conductive member 41.

Alternatively, the formation of the insulating member (step S40) and the formation of the conductive member (step S50) may be carried out at the same time. In this case, the insulating member 31 and the conductive member 41 are formed inside the through hole 20a by inserting a composite member that integrates the insulating member 31 and the conductive member 41 together into the through hole 20a. The composite member is a member in which the insulating member 31 is formed around the columnar conductive member 41, for example. The insulating member 32 and the conductive member 42 can also be formed in accordance with the same method applied to the insulating member 31 and the conductive member 41.

Next, the current collecting terminal 51, the current collecting terminal 52, and the current collecting terminal 55 are formed (step S60). Specifically, the current collecting terminal 51 is formed at such a position that is connected to the end portion on the principal surface 11 side of the conductive member 41 and is not in contact with the principal surface 11. Meanwhile, the current collecting terminal 52 is formed at such a position that is connected to the end portion on the principal surface 11 side of the conductive member 42 and is not in contact with the principal surface 11. In the meantime, the current collecting terminal 55 is formed on the principal surface 11. The current collecting terminal 51, the current collecting terminal 52, and the current collecting terminal 55 are formed by disposing the conductive material at desired regions by printing, plating, soldering, and the like.

The battery 1 illustrated in FIG. 1 can be manufactured by carrying out the above-described steps.

Meanwhile, the side surface insulating layer 60 illustrated in FIG. 6 may be formed at a certain timing after the formation of the laminated body (step S20). The side surface insulating layer 60 is formed by coating the insulating material on the side surfaces and the like of the power generation element 5, for example. The side surface insulating layer 60 may be formed by dipping a portion of the power generation element 5 into the insulating material in liquid form, and then curing the insulating material adhering to the power generation element 5. The curing is carried out by drying, heating, light irradiation, and the like depending on the resin material used therein.

In the meantime, the sealing member 90 illustrated in FIGS. 19 and 20 may be formed after the formation of the current collecting terminal 51, the current collecting terminal 52, and the current collecting terminal 55 (step S60). The sealing member 90 is formed by coating the resin material having fluidity and then curing the resin material, for example. The coating is carried out in accordance with an ink jet method, a spray method, a screen printing method, a gravure printing method, and the like. The curing is carried out by drying, heating, light irradiation, and the like depending on the resin material used therein.

### Second Example of Manufacturing Method

Next, a second example of manufacturing the batteries according to the respective embodiments will be described. The following description will be focused on different features from those of the first example of the manufacturing method while omitting or simplifying explanations of features in common.

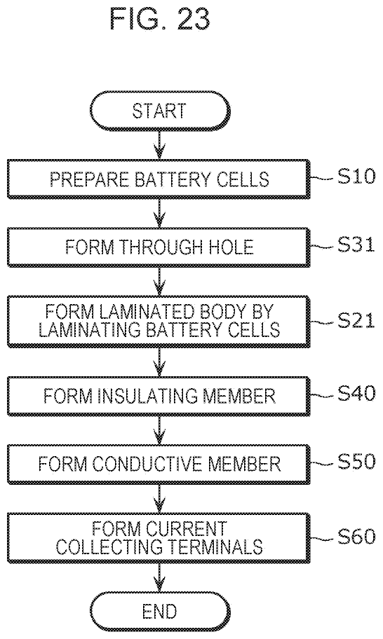

FIG. 23 is a flowchart illustrating the second example of the method for manufacturing the batteries according to the respective embodiments. The second example of the manufacturing method will be focused on manufacturing of the battery 601 according to the Embodiment 6. The second example of the manufacturing method has the different order of the respective steps from that of the first example of the manufacturing method.

As illustrated in FIG. 23, the battery cells are first prepared in accordance with the same method as that of the first example of the manufacturing method (step S10).

Next, the through hole is formed in at least a portion of the battery cells 100 among the battery cells 100 yet to be laminated (step S31). To be more precise, through holes having the shape corresponding to the through hole 620a in the respective battery cells 100 are formed in all of the battery cells 100 yet to be laminated. Moreover, through holes having the shape corresponding to the through hole 620b in the respective battery cells 100 are formed in a portion of the battery cells 100 yet to be laminated. As described above, the through holes having the shapes corresponding to the through hole 620a and the through hole 620b are formed in the respective battery cells 100, so that the through holes having the shapes corresponding to the through hole 620a and the through hole 620b can be formed easily. In the meantime, freedom of the shapes of the through hole 620a and the through hole 620b is increased. For example, in the case where inner walls have surfaces in the zigzag shapes as in the case of the through hole 620a and the through hole 620b, the through holes having the shapes corresponding to the through hole 620a and the through hole 620b can be formed easily. Meanwhile, in the case of forming the through hole in the portion of the battery cells 100 as in the case of the through hole 620b, it is possible to avoid the formation of the through holes in the battery cells 100 that do not need the formation of the through holes because the through holes are formed before laminating the battery cells 100. As a consequence, it is possible to reduce a loss in battery capacity attributable to the formation of such unnecessary through holes, for example. The method of forming the through holes can adopt the equivalent method in the first example of the manufacturing method.

Next, a laminated body is formed by laminating the battery cells 100 (step S21). In step S21, the battery cells 100 are laminated in such a way as to concatenate the through holes that are formed in at least the portion of the battery cells 100 among the battery cells 100. In this way, the power generation element 5 is formed and the through holes provided in at least the portion of the battery cells 100 are concatenated, and the through hole 620a and the through hole 620b are formed accordingly.

Next, the formation of the insulating member (step S40), the formation of the conductive member (step S50), and the formation of the current collecting terminal 51, the current collecting terminal 52, and the current collecting terminal 55 (step S60) is carried out in accordance with the same methods as those of the first example of the manufacturing method. Thus, it is possible to form the insulating member 31 and the conductive member 41 in a lump in the through hole 620a, respectively, and to form the insulating member 32 and the conductive member 42 in a lump in the through hole 620b, respectively, so that productivity can be improved.

The battery 601 illustrated in FIG. 13 can be manufactured by carrying out the above-described steps.

### Third Example of Manufacturing Method

Next, a third example of manufacturing the batteries according to the respective embodiments will be described. The following description will be focused on different features from those of the first and second examples of the manufacturing method while omitting or simplifying explanations of features in common.

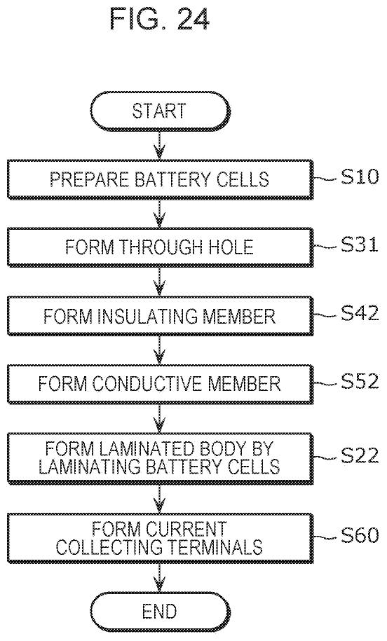

FIG. 24 is a flowchart illustrating the third example of the method for manufacturing the batteries according to the respective embodiments. The third example of the manufacturing method will be focused on the manufacturing of the battery 601 according to the Embodiment 6. The third example of the manufacturing method has the different order of the respective steps from those of the first and second examples of the manufacturing method.

As illustrated in FIG. 24, the battery cells are first prepared in accordance with the same method as that of the first example of the manufacturing method (step S10).

Next, the through hole is formed in at least a portion of the battery cells 100 among the battery cells 100 yet to be laminated in accordance with the same method as that of the second example of the manufacturing method (step S31).

Next, the insulating member is formed inside the through hole formed in at least the portion of the battery cells 100 among the battery cells 100 yet to be laminated (step S42). Specifically, the insulating member 31 is formed in the though holes having the shape corresponding to the through hole 620a, which are formed in all of the battery cells 100 yet to be laminated. Meanwhile, the insulating member 32 is formed in the though holes having the shape corresponding to the through hole 620b, which are formed in the portion of the battery cells 100 among the battery cells 100 yet to be laminated.

Next, the conductive member is formed inside the through hole formed in at least the portion of the battery cells 100 among the battery cells 100 yet to be laminated (step S52). Specifically, the conductive member 41 is formed in the though holes having the shape corresponding to the through hole 620a, which are formed in all of the battery cells 100 yet to be laminated. Meanwhile, the conductive member 42 is formed in the though holes having the shape corresponding to the through hole 620b, which are formed in the portion of the battery cells 100 among the battery cells 100 yet to be laminated.

The methods of forming the insulating member 31, the insulating member 32, the conductive member 41, and the conductive member 42 can adopt the equivalent methods in the first example of the manufacturing method.

As described above, the insulating member 31, the insulating member 32, the conductive member 41, and the conductive member 42 can be formed before laminating the battery cells 100. Accordingly, it is easy to carry out an operation such as insertion of the materials into the through holes, so that the insulating member 31, the insulating member 32, the conductive member 41, and the conductive member 42 can be formed easily and accurately.

Next, a laminated body is formed by laminating the battery cells 100 (step S22). In step S22, the battery cells 100 are laminated in such a way as to concatenate the through holes that are formed in at least the portion of the battery cells 100 among the battery cells 100. In this way, the power generation element 5 is formed and the through holes formed in at least the portion of the battery cells 100 among the battery cells 100 are concatenated, whereby the through hole 620a and the through hole 620b are formed. In the meantime, the battery cells 100 are laminated such that the insulating members 31, the insulating members 32, the conductive members 41, and the conductive members 42 formed in at least the portion of the battery cells 100 among the battery cells 100 are connected to one another, respectively.

Next, the current collecting terminal 51, the current collecting terminal 52, and the current collecting terminal 55 are formed in accordance with the same method as that of the first example of the manufacturing method (step S60).

The battery 601 illustrated in FIG. 13 can be manufactured by carrying out the above-described steps.

### Fourth Example of Manufacturing Method

Next, a fourth example of manufacturing the batteries according to the respective embodiments will be described. The following description will be focused on different features from those of the first to third examples of the manufacturing method while omitting or simplifying explanations of features in common.

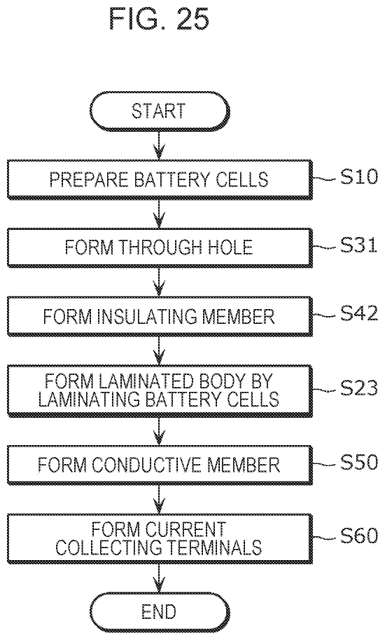

FIG. 25 is a flowchart illustrating the fourth example of the method for manufacturing the batteries according to the respective embodiments. The fourth example of the manufacturing method will be focused on the manufacturing of the battery 601 according to the Embodiment 6. The fourth example of the manufacturing method has the different order of the respective steps from those of the first to third examples of the manufacturing method.

As illustrated in FIG. 25, the battery cells are first prepared in accordance with the same method as that of the first example of the manufacturing method (step S10).

Next, the through hole is formed in at least a portion of the battery cells 100 among the battery cells 100 yet to be laminated in accordance with the same method as that of the second example of the manufacturing method (step S31).

Next, the insulating member is formed inside the through hole formed in at least the portion of the battery cells 100 among the battery cells 100 yet to be laminated in accordance with the same method as that of the third example of the manufacturing method (step S42). In this way, it is possible to form the insulating member 31 and the insulating member 32 easily and accurately, which are required to be formed accurately in order to improve reliability of the battery 601.

Next, a laminated body is formed by laminating the battery cells 100 (step S23). In step S23, the battery cells 100 are laminated in such a way as to concatenate the through holes that are formed in at least the portion of the battery cells 100 among the battery cells 100. In this way, the power generation element 5 is formed and the through holes formed in at least the portion of the battery cells 100 among the battery cells 100 are concatenated, whereby the through hole 620a and the through hole 620b are formed. In the meantime, the battery cells 100 are laminated such that the insulating members 31 and the insulating members 32 formed in at least the portion of the battery cells 100 among the battery cells 100 are connected to one another, respectively. Meanwhile, in the case where the through holes for forming the conductive members 41 and the conductive members 42 in the insulating members 31 and the insulating members 32 are formed, respectively, the battery cells 100 are laminated in such a way that the through holes in the insulating members 31 and the insulating members 32 are concatenated, respectively.

Here, in the formation of the insulating member (step S42), the insulating member 31 and the insulating member 32 may be formed by filling the through holes provided to at least the portion of the battery cells 100 among the battery cells 100 with the insulating material in such a way as to completely bury these through holes, and providing the filled insulating material with the through holes for forming the conductive member 41 and the conductive member 42. In this case, the formation of the through holes for providing the conductive member 41 and the conductive member 42 may be carried out before the formation of the laminated body (step S23) or after the formation of the laminated body (step S23) on the battery cells 100 in a lump.

Next, the formation of the conductive members (step S50) and the formation of the current collecting terminal 51, the current collecting terminal 52, and the current collecting terminal 55 (step S60) is carried out in accordance with the same methods as those of the first example of the manufacturing method.

The battery 601 illustrated in FIG. 13 can be manufactured by carrying out the above-described steps.

### Other Embodiments

The battery, the method for manufacturing the battery, and the circuit board according to one or more aspects have been described above based on the embodiments. However, the present disclosure is not limited to these embodiments. Various modifications that can be conceived of by those skilled in the art and are adopted to any of these embodiments as well as other aspects constructed by combining certain constituents out of the embodiments are also encompassed by the scope of the present disclosure as long as those modifications and modes do not depart from the gist of the present disclosure.

For example, the above-described embodiments depict the example in which the single current collector is shared by the battery cells located adjacent to each other as any of the intermediate layer current collector, the electrode current collector, and the counter electrode current collector. However, the current collector does not need to be shared. Here, two adjacent battery cells may be laminated together while joining two current collector to each other. The intermediate layer current collector may be formed by overlapping the counter electrode current collector with the electrode current collector, for example.

Meanwhile, in the above-described embodiments, the battery is provided with the insulating members, for example. However, the present disclosure is not limited to this configuration. The battery does not always have to be provided with the insulating members.

In the meantime, in any of the above-described embodiments, an external electrode may further be formed on any of the current collecting terminals by plating, printing, soldering, and the like, for example. The formation of the external electrode can further enhance mountability of the battery, for example.

Meanwhile, in the above-described embodiments, the insulating layer completely buries the space between the conductive member and the inner wall of the through hole, for example. However, the present disclosure is not limited to this configuration. The insulating member may cover the inner wall of the through hole while being located away from the conductive member. Alternatively, the insulating member may cover an outer peripheral surface of the conductive member while being located away from the inner wall of the through hole.

In the meantime, a relationship of connection among the battery cells in the power generation element is not limited to the examples described in the embodiments. For example, the battery cells may involve an arbitrary combination of the battery cells connected in series and the battery cells connected in parallel.

Meanwhile, the battery includes the current collecting terminals in the above-described embodiments, for example. However, the present disclosure is not limited to this configuration. The battery does not always have to include the current collecting terminals. For example, a current may be extracted by connecting terminals of an electronic device, contacts of a board, pads of the board, and the like to the conductive members and the principal surfaces of the power generation element.

In the meantime, the first battery cell to which the first conductive member is connected and the second battery cell to which the second conductive member is connected are not limited to the examples discussed in the above-described embodiments. The first battery cell and the second battery cell may be any battery cells as long as these battery cells are different from each other. For example, both the first battery cell and the second battery cell may be intermediate battery cells.

Meanwhile, the respective embodiments described above can implement a variety of modification, replacement, addition, omission, and the like within the scope of the appended claims and the equivalents thereof.

The present disclosure is applicable to a battery or a circuit board for electronic equipment, electric appliances, and electric vehicles, for example.

What is claimed is:

1. A battery comprising:
a power generation element including a plurality of battery cells each having an electrode layer, a counter electrode layer, and a solid electrolyte layer located between the electrode layer and the counter electrode layer, the plurality of battery cells being laminated;
a first conductive member; and
a second conductive member, wherein
at least a portion of the plurality of battery cells are electrically connected in parallel,
the parallel connection is carried out by an insulating layer and a connecting portion provided on a side surface of the power generation element,
at least a portion of the plurality of battery cells are electrically connected in series,
the power generation element is provided with at least one through hole that penetrates at least a portion of the plurality of battery cells in a direction of lamination and is open on at least any of a first principal surface and a second principal surface located on an opposite side to the first principal surface of the power generation element,
the first conductive member is electrically connected to a first battery cell among the plurality of battery cells, passes through the at least one through hole, and extends to an opening position of the at least one through hole located on a first surface being one of the first principal surface and the second principal surface,
the second conductive member is electrically connected to a second battery cell among the plurality of battery cells being different from the first battery cell, passes through the at least one through hole, and extends to an opening position of the at least one through hole located on a second surface being one of the first principal surface and the second principal surface, and
the first battery cell and the second battery cell are not connected in parallel.

2. The battery according to claim 1, wherein the at least one through hole includes:
a first through hole that the first conductive member passes through, the first through hole being open on the first surface; and
a second through hole that the second conductive member passes through, the second through hole being open on the second surface.

3. The battery according to claim 2, further comprising:
a first insulating member located between the first conductive member and an inner wall of the first through hole; and
a second insulating member located between the second conductive member and an inner wall of the second through hole.

4. The battery according to claim 1, wherein the at least one through hole is a single through hole that the first conductive member and the second conductive member pass through.

5. The battery according to claim 4, further comprising:
an insulating member disposed between the first conductive member and an inner wall of the single through hole, between the second conductive member and the inner wall of the single through hole, and between the first conductive member and the second conductive member.

6. The battery according to claim 1, wherein
one of a voltage at the first conductive member based on the first surface and a voltage at the second conductive member based on the second surface is a positive voltage, and
another one of the voltages is a negative voltage.

7. The battery according to claim 1, wherein
a portion of the battery cells including the first battery cell among the plurality of battery cells constitute a first cell laminated body in the power generation element,
a portion of the battery cells including the second battery cell among the plurality of battery cells constitute a second cell laminated body laminated on the first cell laminated body in the power generation element, and
the power generation element further includes an insulating layer located between the first cell laminated body and the second cell laminated body.

8. The battery according to claim 7, further comprising:
a third conductive member that electrically connects the first principal surface to the second principal surface, wherein
the first principal surface constitutes a portion of the first cell laminated body, and
the second principal surface constitutes a portion of the second cell laminated body.

9. The battery according to claim 1, wherein
a battery cell among the plurality of battery cells which is connected between the first surface and the first battery cell does not overlap a battery cell among the plurality of battery cells which is connected between the second surface and the second battery cell.

10. The battery according to claim 1, wherein
the first surface is the first principal surface,
the second principal surface constitutes a portion of the first battery cell, and
the first conductive member is electrically connected to the second principal surface and penetrates the power generation element while passing through the at least one through hole.

11. The battery according to claim 1, wherein
a quantity of the battery cells among the plurality of battery cells involved in serial connection between the first surface and the first battery cell is different from a quantity of the battery cells among the plurality of battery cells involved in serial connection between the second surface and the second battery cell.

12. The battery according to claim 1, wherein the first surface and the second surface are the first principal surface.

13. A method for manufacturing a battery comprising:
forming a laminated body by laminating a plurality of battery cells in such a way that at least a portion of the plurality of battery cells are connected in series;
forming at least one through hole in the laminated body by in such a way as to penetrate at least a portion among the plurality of battery cells in a direction of lamination and to be open on at least any of a first principal surface and a second principal surface located on an opposite side to the first principal surface of the laminated body;
forming a first conductive member inside the at least one through hole in such a way as to be electrically connected to a first battery cell among the plurality of battery cells, to pass through the at least one through hole, and to extend to an opening position of the at least one through hole located on any of the first principal surface and the second principal surface; and
forming a second conductive member inside the at least one through hole in such a way as to be electrically connected to a second battery cell among the plurality of battery cells being different from the first battery cell, to pass through the at least one through hole, and to extend to the opening position of the at least one through hole located on any of the first principal surface and the second principal surface; wherein
at least a portion of the plurality of battery cells are electrically connected in parallel,
the parallel connection is carried out by an insulating layer and a connecting portion provided on a side surface of the laminated body, and
the first battery cell and the second battery cell are not connected in parallel.

14. The method for manufacturing a battery according to claim 13, further comprising:
forming an insulating member to be disposed between the first conductive member and an inner wall of the at least one through hole as well as between the second conductive member and the inner wall of the at least one through hole.

15. The method for manufacturing a battery according to claim 13, wherein the forming at least one through hole is carried out after the forming a laminated body.

16. The method for manufacturing a battery according to claim 14, wherein
the forming at least one through hole includes forming a through hole corresponding to the at least one through hole in at least a portion of the plurality of battery cells yet to be laminated before the forming a laminated body, and
the method for manufacturing a battery carries out the forming an insulating member, the forming a first conductive member, and the forming a second conductive member after the forming a laminated body.

17. The method for manufacturing a battery according to claim 14, wherein
the forming at least one through hole includes forming a through hole corresponding to the at least one through hole in at least a portion of the plurality of battery cells yet to be laminated before the forming a laminated body, and
the method for manufacturing a battery carries out the forming an insulating member, the forming a first conductive member, and the forming a second conductive member before the forming a laminated body.

18. The method for manufacturing a battery according to claim 14, wherein
the forming at least one through hole includes forming a through hole corresponding to the at least one through hole in at least a portion of the plurality of battery cells yet to be laminated before the forming a laminated body, and
the method for manufacturing a battery carries out the forming an insulating member before the forming a laminated body, and carries out the forming a first conductive member and the forming a second conductive member after the forming a laminated body.

19. A circuit board comprising:
a power generation element including a plurality of battery cells each having an electrode layer, a counter electrode layer, and a solid electrolyte layer located between the electrode layer and the counter electrode layer, the plurality of battery cells being laminated;
a first conductive member;
a second conductive member; and
a circuit pattern layer being laminated on the power generation element and including circuit wiring, wherein
at least a portion of the plurality of battery cells are electrically connected in series,
the power generation element is provided with at least one through hole that penetrates at least a portion of the plurality of battery cells in a direction of lamination and is open on a first principal surface of the power generation element,
the first conductive member is electrically connected inside the at least one through hole to a first battery cell among the plurality of battery cells, passes through the at least one through hole, extends to an opening position of the at least one through hole located on the first principal surface, and is electrically connected to a portion of the circuit wiring,
the second conductive member is electrically connected inside the at least one through hole to a second battery cell among the plurality of battery cells being different from the first battery cell, passes through the at least one through hole, extends to the opening position of the at least one through hole located on the first principal surface, and is electrically connected to another portion of the circuit wiring, and
the circuit pattern layer is located on the first principal surface side of the power generation element.

20. The circuit board according to claim 19, wherein
at least a portion of the plurality of battery cells are electrically connected in parallel,
the parallel connection is carried out by an insulating layer and a connecting portion provided on a side surface of the power generation element, and
the first battery cell and the second battery cell are not connected in parallel.
